(19) United States
(12) Patent Application Publication
(10) Pub. No.: US 2002/0051501 A1
(43) Pub. Date: May 2, 2002

(54) Use of turbo-like codes for QAM modulation using independent I and Q decoding techniques and applications to xDSL systems

(76) Inventors: Victor Demjanenko, Pendleton, NY (US); Frederic J. Hirzel, Clinton Township, MI (US); Juan Alberto Torres, Orchard Park, NY (US)

Correspondence Address: David A. Blumenthal, FOLEY & LARDNER, Suite 3500, 2029 Century Park East, Los Angeles, CA, 90067-3021, US

(21) Appl. No.: 09/846,061

(22) Filed: Apr. 30, 2001

Related U.S. Application Data
(60) Provisional application No. 60/200,369, filed on Apr. 28, 2000.
(60) Provisional application No. 60/248,099, filed on Nov. 13, 2000.
(60) Provisional application No. 60/242,393, filed on Oct. 20, 2000.
(60) Provisional application No. 60/244,550, filed on Oct. 31, 2000.

(51) Int. Cl. H04L 27/36; H03D 1/00; H04L 27/06

(52) U.S. Cl. 375/298; 375/340

(57) ABSTRACT

A transmitter produces a modulated signal with forward error correction from an information bit stream in a QAM transmitter. The transmitter produces parity bit streams that correspond to an inputted information bit stream using first and second concatenated coders interconnected by an interleaver. Subsets of the first and second parity bit streams are selected in accordance with a puncturing pattern. A variety of novel puncturing patterns providing various coding rates for various constellations are disclosed. The transmitter combines the selected subsets of said first and second parity bit streams with said information bit stream. A QAM symbol stream is produced by mapping a first subset of the combined bit streams to an I dimension and mapping a second subset of the combined bit streams to a Q dimension. The QAM symbol stream is modulated to produce a modulated signal that is transmitted over a communication link. A complementary receiver is also disclosed. The puncturing pattern used in the transmitter may be adapted based on a performance metric determined in the receiver.

This non-provisional patent application claims the benefit under 35 U.S.C. Section 119(e) of U.S. Provisional Patent Application Ser. No. 60/200,369, filed on Apr. 28, 2000, Provisional Patent Application Ser. No. 60/248,099, filed on Nov. 13, 2000, Provisional Patent Application Ser. No. 60/242,393, filed on Oct. 20, 2000 and Provisional Patent Application Ser. No. 60/244,550, filed on Oct. 31, 2000, each of which is incorporated herein by references in its entirety.

### FIELD OF THE INVENTION

The present invention relates to a techniques for coding and decoding signals used in DSL data transmission over wired and wireless systems that use Turbo Codes (TC) and any other receiver soft-decision extraction technique, such as Low Density Parity Check Codes (LDCP) (these techniques are called Turbo-like Codes), with QAM constellations using independent I and Q as modulation for error correction. The QAM constellations covered in this application are from 2 QAM up to 16384 QAM. The same technique can be use for higher order modulations. In this application we present results using an S-type and helicoidal odd-even smile analytical interleaver. An embodiment of the invention pertains particularly to xDSL systems, as a representative of DMT wired-based systems. The same technique can be used for multicarrier wireless DMT systems that using only one transmitter can send multi-channel information. The low order constellation insures a minimum acceptable data rate for very low Signal to Noise ratios that is not possible with any other known error correcting technique. The preferred mapping used is Gray mapping because of its better performance vs. Natural or Ungerboeck mapping, however the techniques disclosed herein may use Natural or Ungerboeck mapping.

### BACKGROUND OF THE INVENTION

Turbo codes and other receiver soft-decision extraction techniques such as Low Density Parity Check Codes, are new and very powerful error control techniques, which allow communication very close to the channel capacity. These techniques are called as Turbo-like Codes. Low Density Parity Check Codes were introduced in 1962. Turbo codes were introduced in 1993.

A lot of research has been done in the application of Turbo-like Codes in deep space communications, mobile satellite/cellular communications, microwave links, paging, in OFDM and CDMA architectures. Turbo-like codes outperform all previously known coding schemes regardless of the targeted channel. The extra coding gain offered by these codes can be used either to save bandwidth or reduce power requirements in the link budget. Standards based in turbo codes have already been defined or are currently under investigation. For example:

Inmarsat's new multimedia service is based on turbo codes and 16 QAM that allows the user to communicate with existing Inmarsat 3 spot beam satellites from a notebook-sized terminal at 64 kbit/s.

The Third Generation Partnership Project (3 GPP) proposal for IMT-2000 includes turbo codes in the multiplexing and channel coding specification. The IMT-2000 represents the third generation mobile radio systems worldwide standard. The 3 GPP objective is to harmonize similar standards proposals from Europe, Japan, Korea and the United States.

NASA's next-generation deep-space transponder will support turbo codes and implementation of turbo decoders in the Deep Space Network is planned by 2003.

The new standard of the Consultative Committee for Space Data Systems (CCSDS) in based on turbo codes. The new standard outperforms with 1.5 to 2.8 dB the old CCSDS standard based on concatenated convolutional code and Reed-Solomon code.

The new European Digital Video Broadcasting (DVB) standard also adopted turbo codes for the return channel over satellite applications.

xDSL modems are designed to operate between a Central Office CO (or a similar point of presence) and a customer premises CPE. As such they use existing telephone network wiring between the CO and the CPE. There are several modems in this class which function in generally similar manners. Typically these modems transmit their signals above the voice band. As such, they are dependent on adequate frequency response above voice band. The modem may use a set of transmitters and receivers each at different frequencies. Alternatively, a transmitting modem may use the Inverse Discrete Fourier Transform (IDFT) that sends a signal in different subcarriers at the same time. A corresponding receiver uses the Discrete Fourier Transform (DFT) to detect the signal in the different subcarriers.

The International Telecommunication Union (ITU) has developed Recommendations G.992.1 and G.992.2 for the use of ADSL modems in the telephone network. G.992.1 allows the use of Trellis Code Modulation in the encoder of the transmitter to improve the performance of the ADSL modems. Trellis Code Modulation encodes the two least significant information bits using a convolutional encoder that provides an extra parity bit for Forward Error Correction. The extra parity bit produces an expansion of 0.5 bits per dimension in the DMT/QAM modulator. This Forward Error Correction provides an extra coding gain of around 3 dB with respect to the un-coded DMT/QAM system.

### SUMMARY OF THE INVENTION

Embodiments of the present invention pertain to the use of Turbo Codes and any other receiver soft-decision extraction technique such as Low Density Parity Check Codes (these techniques are collectively referred to herein as Turbo-like Codes), for DMT systems with QAM modulation in a manner that reduces. computing requirements by treating the QAM signal as two AM modulations (one in the I dimension and one in the Q dimension) and using the probabilities of the I dimension values as an input (the probabilities of the Q dimension are not needed) to the Turbo-like Code. For non-square constellations (8 QAM, 32 QAM, 128 QAM, etc . . . ), we show a method of rectangular constellations with spherical noise; a method of creating non-separable I and Q constellations by combining constituent separable I and Q constellations, as presented in Provisional Patent Application Ser. No. 09/248,099, filed on Nov. 13, 2000, that also reduces the computational complexity by the order of the square root of the number of constellation points (O(N^{½})); other methods with lower computational saving such as the diagonal regions method presented in the Provisional Patent Application Ser. No. 09/242,393, filed on Oct. 20, 2000 and Provisional Patent Application Ser. No. 09/244,550, filed on Oct. 31, 2000 can also be used.

Further embodiments of the invention improve the Turbo code, and other receiver soft-decision extraction techniques, by mapping the modulated signal in a manner providing different protection to the information bits and the parity bits as a function of the channel used and the performance needed. For Additive White Gaussian Noise (AWGN), more protection should be put in the information bits for applications with a target BER higher than 10⁻⁸, and more protection is preferable put in the parity bits for applications with a target BER lower than 10⁻⁸. More protection to the parity bits than to the information bits reduces the floor error of the Turbo code below 10⁻⁹. For Impulsive Noise (IN) channels and high puncturing, the parity bits should be more protected than the information bits in all cases, obtaining an extra protection on the order of 25 dB.

Further embodiments of the invention employ novel puncturing patterns for each order of a QAM modulated signal, and a preferred puncturing pattern for each order is identified. The high puncturing used in the Turbo Code makes the Turbo Code and the Low Density Parity Check Code very similar in theoretical fundamentals and practical results.

Embodiments disclosed herein represent the first use of Turbo-like Codes for high order modulations techniques, up to 16384 QAM. Preferred embodiments achieve a target BER very close to the channel capacity for the respective spectral efficiency response. The schemes proposed here, are more power efficient than the trellis coded modulation schemes used traditionally with V.32.bis or V.34 standards. The higher the constellation, the more improvements that this technique provides (i.e. for 16 QAM the probabilities to compute in a classical turbo code are 16 points, with this technique the probabilities to compute are 4, so if we use 10 iterations, the computing saving is more than 40 times; for 128 QAM the computing saving is 10*1,042/186=60 times, using a method of creating non-separable I and Q constellations by combining constituent separable I and Q constellations).

Embodiments disclosed herein apply this technique to DMT xDSL modems as representative species of a wired-based system, where constellations up to 32,768 QAM are possible, and typically constellations of 1024 QAM are used. In the case of the G.992.1, this technique allows the system to work at 400 kbps with E_{b}/N_{O} below 2 dB (assuming 4 QAM and spectral efficiency of 1 bit/s/Hz 4 ksymbols/s and 100 tones). These embodiments use S-type interleavers and analytical helicoidal odd-even interleavers. The attached computer program code listing appendix presents the c code of simulation program, a program for the S-type interleaver, and a program for the analytical interleaver.

### BRIEF DESCRIPTION OF THE SEVERAL VIEWS OF THE DRAWING

FIG. 1 shows the System Architecture for variable Symbol rates

FIG. 2 shows the BER curves for the rate 2/4 16 QAM scheme with N=512 bits and N=32768 bits S-type

FIG. 3 shows a Coding Scheme

FIG. 4 shows a SRC Scheme

FIG. 5 shows a 4 QAM constellation

FIG. 6 shows a 2 AM constellation

FIG. 7 shows the BER for Rate 2/6 4 QAM, N=1024 bits S-type AWGN Channel

FIG. 8 shows the BER for Rate 2/4 4 QAM, N=1024 bits S-type AWGN Channel

FIG. 9 shows a 8 QAM constellation

FIG. 10 shows a 4 AM constellation

FIG. 11 shows the BER for Rate 2/6 8 QAM, N=1024 bits S-type AWGN Channel

FIG. 12 shows the BER for Rate 4/6 8 QAM, N=1024 bits S-type AWGN Channel

FIG. 13 shows a 16 QAM constellation

FIG. 14 shows the BER for Rate 1/2 16 QAM, N=272 bits (odd-even) AWGN Channel

FIG. 15 shows the BER for Rate 1/2 16 QAM, N=256 bits S-type AWGN Channel

FIG. 16 shows the BER for Rate 1/2 16 QAM, N=512 bits S-type AWGN Channel

FIG. 17 shows the BER for Rate 1/2 16 QAM, N=768 bits S-type AWGN Channel

FIG. 18 shows the. BER for Rate 1/2 16 QAM, N=1024 bits S-type AWGN Channel

FIG. 19 shows the BER for Rate 3/4 16 QAM, N=4,096 bits S-type AWGN Channel

FIG. 20 shows a 32 QAM constellation

FIG. 21 shows an 8 AM constellation with Gray Mapping

FIG. 22 shows the BER for Rate 3/5 32 QAM, N=6,144 bits S-type AWGN Channel

FIG. 23 shows a 64 QAM constellation

FIG. 24 shows a BER for Rate 3/6 64 QAM, N=4,096 bits S-type AWGN Channel

FIG. 25 shows the BER for Rate 4/6 64 QAM, N=4,096 bits S-type AWGN Channel Gray Mapping

FIG. 26 shows an 8 AM constellation with Natural Mapping

FIG. 27 shows the BER for Rate 4/6 64 QAM, N=4,096 bits S-type AWGN Channel Natural Mapping

FIG. 28 shows a 64 QAM constellation: First Partition Level based on u₁=1

FIG. 29 shows a 64 QAM constellation: Second Partition Level based on u₁=1, u₂=1

FIG. 30 shows a 64 QAM constellation: Third Partition Level based on u₁=1, u₂=1, u₃=1

FIG. 31 shows a 64 QAM constellation: Fourth Partition Level based on u₁=1, u₂=1, u₃=1, u₄=1

FIG. 32 shows a 64 QAM constellation: Fifth Partition Level based on u₁=1, u₂=1, u₃=1, u₄=1, u₅=1

FIG. 33 shows a 64 QAM constellation: LLR(u₁)

FIG. 34 shows a 64 QAM constellation: LLR(u₂)

FIG. 35 shows a 64 QAM constellation: LLR(u₃)

FIG. 36 shows a 64 QAM constellation: LLR(u₄)

FIG. 37 shows a 64 QAM constellation: LLR(u₅)

FIG. 38 shows a 64 QAM constellation: LLR(u₆)

FIG. 39 shows the BER for Rate 4/6 64 QAM, N=4,096 bits S-type AWGN Channel TCM with four bits coded

FIG. 40 shows a 64 QAM constellation with four point subsets

FIG. 41 shows a First Partition of the 64 QAM constellation

FIG. 42 shows a Second Partition of the 64 QAM constellation

FIG. 43 shows a Third Partition of the 64 QAM constellation

FIG. 44 shows a Fourth Partition of the 64 QAM constellation

FIG. 45 shows the BER for Rate 4/6 64 QAM, N=2,048 bits S-type AWGN Channel TCM with two bits coded

FIG. 46 shows the BER for Rate 5/6 64 QAM N=5,120 bits AWGN Channel

FIG. 47 shows a 128 QAM constellation

FIG. 48 shows a 16 AM constellation with Gray Mapping

FIG. 49 shows the BER for Rate 5/7 128 QAM N=5,120 bits AWGN Channel

FIG. 50 shows a 256 QAM constellation

FIG. 51 shows the BER for Rate 5/8 256 QAM N=5,120 bits AWGN Channel

FIG. 52 shows the BER for Rate 6/8 256 QAM N=6,144 bits AWGN Channel

FIG. 53 shows a 512 QAM constellation

FIG. 54 shows the BER for Rate 6/9 512 QAM N=6,144 bits AWGN Channel

FIG. 55 shows a 1024 QAM constellation

FIG. 56 shows the BER for Rate 7/10 1024 QAM N=2,044 bits AWGN Channel

FIG. 57 shows the BER for Rate 12/14 16384 QAM N=31,200 bits AWGN Channel

FIG. 58 shows a AWGN Channel model

FIG. 59 shows the BER for Rate 2/4 4 QAM N=2,048 bits S-type interleaver AWGN Channel

FIG. 60 shows the BER for Rate 2/4 16 QAM N=2,048 bits S-type interleaver AWGN Channel

FIG. 61 shows the BER for Rate 3/4 16 QAM N=2,046 bits S-type interleaver AWGN Channel

FIG. 62 shows the BER for Rate 4/6 64 QAM N=2,048 bits S-type interleaver AWGN Channel

FIG. 63 shows the BER for Rate 5/8 256 QAM N=2,050 bits S-type interleaver AWGN Channel

FIG. 64 shows the BER for Rate 6/8 256 QAM N=2,046 bits S-type interleaver AWGN Channel

FIG. 65 shows the BER for Rate 7/10 1024 QAM N=2,044 bits S-type interleaver AWGN Channel

FIG. 66 shows the BER for Rate 2/4 4 QAM N=2,100 bits Analytical odd-even smile interleaver AWGN Channel

FIG. 67 shows the BER for Rate 2/4 16 QAM N=2,100 bits Analytical odd-even smile interleaver AWGN Channel

FIG. 68 shows the BER for Rate 3/4 16 QAM N=2,100 bits Analytical odd-even smile interleaver AWGN Channel

FIG. 69 shows the BER for Rate 4/6 64 QAM N=2,100 bits Analytical odd-even smile interleaver AWGN Channel

FIG. 70 shows the BER for Rate 5/8 256 QAM N=2,100 bits Analytical odd-even smile interleaver AWGN Channel

FIG. 71 shows the BER for Rate 6/8 256 QAM N=2,100 bits Analytical odd-even smile interleaver AWGN Channel

FIG. 72 shows the BER for Rate 7/10 1024 QAM N=2,100 bits Analytical odd-even smile interleaver AWGN Channel

FIG. 73 shows a 16 QAM constellation with indication of x1, x2, x3, x4 and y1, y2, y3, y4

FIG. 74 shows the performance of the 6/4 rate 64 QAM for the case that the parity bits are more protected and for the case that the parity bits are least protected

FIG. 75 shows a detailed explanation of the encoding and puncturing patterns in a case where all the information bits are encoded.

FIG. 76 shows a detail explanation of the encoding and punctured procedures in a case where a subset of information bits are encoded.

FIG. 77 shows a process in a transmitter in accordance with embodiments of the invention, and

FIG. 78 shows a process in a receiver in accordance with embodiments of the invention.

### DETAILED DESCRIPTION OF THE INVENTION

We herby incorporate by reference the following references, which are representative of the conventional knowledge in the field of the invention:

1. R. G. Gallager, “Low Density Parity-Check Codes”, IRE Trans. on Information Theory, pp. 21-28, 01/62.

2. C. Berrou, V. Glavieux and P. Thitimajshima, “Near Shannon limit error-correcting coding and decoding: turbo-codes”, ICC 1993, Geneva, Switzerland, pp. 1064-1070, May 1993.

3. H. Feldman and D. V. Ramana, “An introduction to Inmarsat's New Mobile Multimedia Service”, The Sixth International Mobile Satellite Conference, Ottawa, pp. 226-229, June 1999.

4. P. Chaudhury, W. Mohr and S. Onoe, “The 3GPP Proposal for IMT-2000”, IEEE Communications Magazine, vol. 37, no 12, pp.72-81. December 1999.

5. 3 GPP Standard “Multiplexing and channel coding: TS 25.212”

6. C. D. Edwards, C. T. Stelzried, L. J. Deutsch and L. Swanson, “NASAS's deep-Space Telecommunications Road Map” TMO Progress Report 42-136, JPL, Pasadena, Calif. USA. PP. 1-20 February 1999.

7. R. Pyndiah, A. Picard and A. Glavieux “Performance of Block Turbo Coded 16 QAM and 64 QAM modulations” Procedings of Globecom 95 pp.1039-1043.

8. Rauschmayer, Dennis J. “ADSL/VDSL Principles”, Macmillan Technical Publishing, 1999.

9. ITU G.992.1 “ADSL Transceivers”, ITU, 1999.

10. ITU G.992.2 “Splitterless ADSL Transceivers”. ITU 1999.

11. ITU I.432 “B-ISDN user-network interface-physical layer specification”, ITU, 1993.

12. Benedetto, Divsalar, Montorsi and F. Pollara, “Serial Concatenation of Interleaved Codes: Performance Analysis, Design, and Iterative Decoding”, The Telecommunications and Data Acquisition Progress Report 42-126, Jet Propulsion Laboratory, Pasadena, Calif., pp. 1-26, Aug. 15, 1996.

13. Benedetto, Divsalar, Montorsi and F. Pollara, “A Soft-Output Maximum A Posteriori (MAP) Module to decode parallel and Serial Concatenated Codes”, The Telecommunications and Data Acquisition Progress Report 42-127, Jet Propulsion Laboratory, Pasadena, Calif., pp. 1-20, Nov. 15, 1996.

14. L. R. Bahl, J. Cocke, F. Jelinek, and J. Raviv, “Optimal Decoding of Linear Codes for Minimizing Symbol Error Rate,” IEEE Transactions on Information Theory, pp. 284-287, March 1974.

15. Divsalar and F. Pollara, “Turbo Codes for PCS Applications”, Proceedings of ICC′95, Seattle, Wash., pp. 54-59, June 1995.

16. D. Divsalar and F. Pollara, “Multiple Turbo Codes”, Proceedings of IEEE MILCOM95, San Diego, Calif., Nov. 5-8, 1995.

17. D. Divsalar and F. Pollara, “Soft-Output Decoding Algorithms in iterative Decoding of Turbo Codes,” The Telecommunications and Data Acquisition Progress Report 42-124, Jet Propulsion Laboratory, Pasadena, Calif., pp. 63-87, Feb. 15, 1995.

18. Juan Alberto Torres, Frederic Hirzel and Victor Demjanenko, “Forward Error Correcting System With Encoders Configured in Parallel and/or Series”, International Patent Application Ser. No. PCT/US99/17369 filed on Jul. 30, 1999.

1. Introduction

Error correction can be used in communication systems to improve the amount of data that can be accurately communicated through a communication channel. Digital Subscriber Line (XDSL) technology is an example of communication using error correction. In xDSL, a transmitter and a receiver communicate over a copper twisted pair using Discrete Multi-Tone (DMT) modulation. In particular, ADSL (Asymmetric Digital Subscriber Line) provides multiple carriers in the frequency band between 20 kHz and 1.1 MHz, at intervals of 4.1325 kHz. Each carrier is modulated using quadrature amplitude modulation (QAM), in which a data value is represented by the phase and magnitude of the carrier. A given phase/magnitude combination is referred to as a “symbol”, and the set of symbols that can be transmitted on a carrier is referred to as a “constellation.” Typically a constellation contains 2ⁿ symbols; in other words, each symbol represents n bits of data. An ADSL channel is theoretically capable of a 15 bit constellation (2¹⁵ discrete symbols). However, in practice, noise on the line will cause the magnitude and phase of transmitted symbols to vary slightly, making it uncertain which symbol a received phase/magnitude combination corresponds to. This typically requires the use of a constellation that provides more space between symbols so that variations in phase and magnitude create less uncertainty. As a result, a given carrier will typically use a constellation of less than 15 bits.

A type of error correction that is used in xDSL and other communication systems is called Forward Error Correction (FEC). Forward error correction involves transmitting one or more error correction bits, typically referred to as “parity bits,” in conjunction with information bits, so that the information bits represented in the signal can be determined solely from the received signal itself using the parity bits, thereby eliminating the need for retransmission. One simple conventional form of forward error coding involves providing a parity bit that represents the least significant bit of a sum of all information bits. Upon receiving the bit string, if the least significant bit of the sum of the information bits matches the parity bit, the received bits are assumed to be correct.

In a more complex forward error coding system referred to as trellis coding, some input bits are coded by a convolutional coder that generates a parity bit for each group of n input bits, and the resulting group of n+1 output bits are used by QAM modulation to produce a signal for a digital to analog converter. The addition of the parity bit effectively doubles the number of symbols in the constellation, and the value of the parity bit effectively places a given symbol in one of two subsets of the constellation, each of which contains every other symbol of the full constellation. As a result, all symbols of the constellation are available for use, but each individual symbol is discriminated within a subset of the constellation in which the symbols are twice as far apart as they would be in the full constellation.

Presently some xDSL modems use a forward error correction method known as Trellis Code Modulation. Trellis coded modulation (TCM) proposed by Ungerboeck in 1982 is now a well-established technique in digital communications. Since its first appearance, TCM has generated a continually growing interest, concerning its theoretical foundations as well as its numerous applications, spanning high-rate digital transmission over voice circuits, digital microwave radio relay links, and satellite communications.

Turbo-like Codes represent a more recent development in the coding research field (1993), which have generated a large interest in the coding community. Turbo Codes are Parallel Concatenated Convolutional Codes (PCCC) whose encoder is formed by two (or more) constituent systematic encoders joined through one or more interleavers. The input information bits feed the first encoder and, after having been scrambled by the interleaver, they enter the second encoder.

This document describes the performance of Turbo-like Codes used with square and non-square high order QAM modulation/demodulation schemes, from 4 QAM up to 16384 QAM. For higher order modulation the same procedure is applicable. This document also describes the application of this modulation schemes to xDSL modems presented in the ITU Recommendations G.992.1 and G.992.2. The use of squared and non-squared QAM constellations with novel puncturing patterns simplifies the design of the equalizer, and for this reason it is possible to utilize squared and non-squared QAM constellations with independent I and Q dimensions using blind equalizers. LDPC codes and other receiver soft-decision extraction techniques may be employed in a similar manner. The different puncturing patterns allow the system to work with low signal-to-noise signals (in the order of 1.25 dB) at the expense of reduced data rates. The Turbo-like Coding and modulation schemes disclosed herein are designed to accommodate a variable symbol rate, which could be adapted to a particular channel characteristic.

The performance of the coding and the modulation schemes disclosed herein are estimated through computer simulations, for different interleaver sizes. Bit probabilities are estimated from the received QAM symbol. Trade offs between power and bandwidth efficiency are also addressed.

1.1 Objectives

The objectives of using higher order modulations and Turbo-like Codes with independent I and Q are:

1. To define a flexible architecture to allow variable symbol rates function of the channel quality.

2. To estimate the performance of 4 QAM, 8 QAM, 16 QAM, 32 QAM, 64 QAM, 128 QAM, 256 QAM 512 QAM, 1024 QAM and 16384 QAM schemes for different interleaver sizes and Additive Gaussian noise (AWGN) and Impulse noise channel (IN).

3. To find the mapping technique to limit the constellation expansion to at most 0.5 bit/dimension.

4. To evaluate the performance for higher order modulation schemes in an AWGN channel and in an Impulse Noise Channel.

1.2 System Parameters

The system parameters are summarized in Table 1.

TABLE 1
System Parameters

| Parameter | Value |
|---|---|
| Target bit error rate (BER) | 10⁻⁴, 10⁻⁵, 10⁻⁶, and 10⁻⁷ |
| Target Eb/No | As low as possible |
| Interleaver block sizes | variable to 14 DMT symbols for |
| | a latency of 10 ms. |
| Modulation | QAM |
| Coding rate | From 1/3 and up |
| Maximum Symbol Rate | 1,024 ksym/s |
| Minimum Symbol Rate | 128 ksym/s |
| Symbol Rate Step | 4 ksym/s |
| Maximum Information Rate | 6,144 kbit/s |
| Minimum Information Rate | 160 kbit/s |
| Information Rate Step | 32 kbit/s |
| Channel | AWGN and IN |

2. System Architecture.

2.1 Introduction

The coding and modulation schemes of the embodiments disclosed herein are designed to accommodate variable symbol rates using the same encoder and decoder structure. Therefore, depending on the channel quality, the same data rate can be transmitted in a variable bandwidth or a different data rate can be transmitted, using the same structure but different puncturing patterns and mapping.

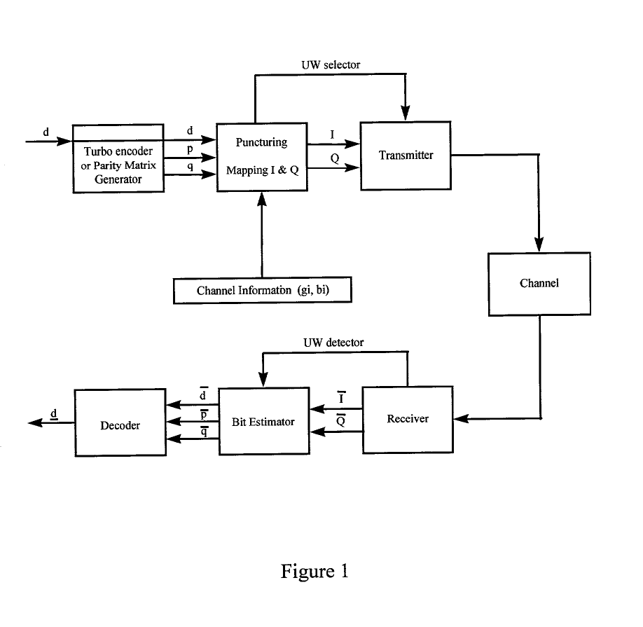

FIG. 1 illustrates functional architectures of a transmitter and a receiver in a communication system. At the transmitter, incoming information bits, d, are encoded by a turbo-like coder such as a rate 1/3 systematic encoder or linear parity bit generator matrix H. The turbo-like encoder outputs the information bits d and a parity bit p and parity bit q corresponding to each information bit. The puncturing block performs a puncturing function that determines the actual coding rate of the parity generator matrix H. The puncturing function is a simple deletion of some parity bits from the p and q streams which results in creation of subsets of the p and q bit streams. No puncturing is applied to the information bits d. A mapping function then combines the information bit stream with the subsets of the parity bit streams selected by the puncturing pattern and produces a QAM symbol stream by mapping a first subset of the combined bit streams to an I dimension and mapping a second subset of the combined bit streams to a Q dimension. Each puncturing pattern and mapping is identified using a unique word (UW). The puncturing pattern and mapping may be varied adaptively. For example, transmission may initially employ the most powerful coding scheme that can be used in the available bandwidth. As a function of the Channel State Information (with the values of gi and bi for each tone for the case of a G.992.1 or G.992.2 modem), the puncturing and mapping can be adapted to reduce the transmitted signal band width to a value that allows communication at the desired BER. The receiver is provided with an identification of the puncturing pattern and mapping.

At the receiver, after synchronization with the transmitter, a particular configuration of the bit estimator block corresponding to the puncturing pattern and mapping of the transmitter is established. The function of the bit estimator block is to compute the log-likelihood ratios (LLR) for each bit of the received QAM symbol in the Turbo-like Code. The outputs from this block are punctured streams of the estimate \overline{d}, \overline{p} and \overline{q} bits that are provided to a decoder. The decoder does not need to know anything about the transmitter mapping or modulation scheme. A maximum a posteriori (MAP) algorithm is used in the decoder to produce decoded bits d. In the case of LDPC the output d is the decoded bit d or an error flag indicating that the decoding process has an error.

2.2 Power vs. Bandwidth.

The architecture of FIG. 1 is flexible enough to select the most bandwidth efficient modulation given the available signal-to-noise ratio available for a particular channel. An example is shown in Table 2 for an information data rate of 2,048 kbps. The most powerful coding scheme that could be used is the rate 2/6 4 QAM. This scheme can achieve a BER of 10⁻⁶ at approximately E_{b}/N_{O}=1.2 dB and requires a symbol rate of 3,072 ksym/s. If the transmission occurs over a less noisy channel, them the bandwidth can be reduced by using higher spectral efficiency schemes. The minimum symbol rate that can be achieved is 292 ksym/s.

TABLE 2
Trade Off Power for Bandwidth for 2,048 kbit/s Information Data Rate

| Spectral | Coding Rate | | |
|---|---|---|---|
| efficiency η | and | Symbol Rate | E_{b}/N₀ |
| [bits/s/Hz] | Modulation | [ksym/s] | [dB] |
| 2/3 | 2/6 and 4 QAM | 3072 | 1.2 |
| 1 | 2/4 and 4 QAM | 2048 | 2.1 |
| 2 | 2/4 and 16 QAM | 1024 | 3.9 |
| 3 | 3/4 and 16 QAM | 682 | 6.0 |
| 4 | 4/6 and 64 QAM | 512 | 8.8 |
| 5 | 5/8 and 256 QAM | 408 | 11.5 |
| 6 | 6/8 and 256 QAM | 342 | 13.8 |
| 7 | 7/10 and 1024 QAM | 292 | 16.4 |

The turbo decoder has to operate at a maximum speed of 6,144 kbit/s. Speeds of 20,048 kbps can be achieved with the current FPGA technology

2.3 Optimization for Specific Applications

Another advantage of this architecture is that the system is re-configurable in order to achieve the Quality of Service requested by a particular application. For example, the LDPC code or the turbo code modem could be configured to operate in two modes:

Mode A: minimum transfer delay for delay sensitive applications.

In this mode, if a maximum transfer delay is defined, the block for the parity matrix size or the interleaver size could be changed in function of the data rate (to an integer number multiple of DMT symbols).

Mode B: maximum coding gain for data transfer applications.

In this mode, a fixed block parity matrix size or an interleaver size (i.e. 65,536 bits) could be used to achieve the best performance. A significant coding gain of almost 2 dB could be achieved at a BER of 10⁻⁶ if the larger interleaver is used.

2.4 Why are Turbo-like Codes Different?

The performance of Turbo-like Codes depends on the delay that is allowed in the turbo-like encoder. In the case of Turbo Codes, the elementary decoders rely heavily on the interleaving/de-interleaving process to de-correlate their soft outputs. The larger the interleaver, the better the de-correlation that can be achieved, the larger the parity check matrix and the better the performance of the LDPC codes.

The sensitivity of the Turbo-like Codes to the correlation between data bits can also be noticed in higher order modulation schemes when two or more data bits are estimated from the same receiver symbol. Different mapping techniques are investigated for a spectral efficiency of four information bits per symbol using 64 QAM. Simulation results shows that Gray mapping performs better than Natural mapping, which in turn is better than the Ungerboeck set partitioning. A fourth case when two bits where sent un-coded also performed badly because of a smaller interleaver size.

The complexity of the bit estimator block in FIG. 1 increases with the constellation size because more bits need to be estimated per symbol. The equivalent of this in a trellis coded modulation scheme with un-coded bits is that more parallel paths are added to the trellis, therefore there is an increased computational effort in the branch metric estimator.

2.5 Capacity Bound

The minimum E_{b}/N_{O} values to achieve the Shannon bound, 4 QAM, 8 QAM, 16 QAM, 32 QAM, 64 QAM, 128 QAM, 256 QAM, 512 QAM and 1024 QAM bounds for spectral efficiencies form 2/3 up to 7 bits/s/Hz respectively are as in Table 3 for a BER=10⁻⁵.

TABLE 3
Shannon and QAM bounds.

| Spectral | | 4 | 8 | 16 | 32 | 64 | 128 | 256 | 512 | 1024 |
|---|---|---|---|---|---|---|---|---|---|---|
| efficiency | Shannon | QAM | QAM | QAM | QAM | QAM | QAM | QAM | QAM | QAM |
| η | bound | bound | bound | bound | bound | bound | bound | bound | bound | bound |
| [bit/s/Hz] | [dB] | [dB] | [dB] | [dB] | [dB] | [dB] | [dB] | [dB] | [dB] | [dB] |
| 2/3 | −0.5 | 0.3 | 0 | −0.4 | −0.4 | −0.4 | −0.4 | −0.4 | −0.4 | −0.4 |
| 1 | 0 | 1.0 | 0.9 | 0.1 | 0.1 | 0.1 | 0.1 | 0.1 | 0.1 | 0.1 |
| 2 | 1.75 | ∞ | 2.2 | 2.1 | 2.09 | 2.09 | 2.09 | 2.09 | 2.09 | 2.09 |
| 3 | 3.7 | — | ∞ | 4.6 | 4.3 | 4.3 | 4.3 | 4.3 | 4.3 | 4.3 |
| 4 | 5.6 | — | — | ∞ | 6.6 | 6.6 | 6.6 | 6.6 | 6.6 | 6.6 |
| 5 | 7.9 | — | — | — | ∞ | 9.1 | 9.0 | 9.0 | 9.0 | 9.0 |
| 6 | 10.3 | — | — | — | — | ∞ | 11.8 | 11.7 | 11.7 | 11.7 |
| 7 | 12.6 | — | — | — | — | — | ∞ | 14.5 | 14.5 | 14.5 |

The conversion for Eₛ/N_{O} to E_{b}/N_{O} is performed using the following relation

E_{b}/N_{O}[dB]=Eₛ/N_{O}[dB]−10log₁₀(η)[dB] (1)

where η is the number of information bits per symbol.

The required C/N_{O} given a certain E_{b}/N_{O} can be found using the following relation:

C/N_{O}[dB−Hz]=E_{b}/N_{O}[dB]+10 log₁₀(R_{b})[dB−Hz] (2)

where R_{b} is the information bit rate.

For a D-dimension modulation the following formulae are used:

$$SNR = \frac{E [ \vert {a}_{k}^{2} \vert ]}{E [ \vert {w}_{k}^{2} \vert ]} = \frac{E [ \vert {a}_{k}^{2} \vert ]}{D {σ}_{N}^{2}} = \frac{{E}_{av}}{D {σ}_{N}^{2}} \qquad ( 3 )$$

$$SNR = \frac{{E}_{s}}{D \frac{{N}_{0}}{2}} = \frac{η {E}_{b}}{D \frac{{N}_{0}}{2}} \qquad ( 4 )$$

where σ²_{N} is the noise variance in each of the D dimension and η is the number of information bits per symbol. From the above relations:

$${σ}_{N}^{2} = {{E}_{av} ( \frac{2 η {E}_{b}}{{N}_{0}} )}^{- 1} \qquad ( 5 )$$

3. Coding and Modulation for 2/3 bit/s/Hz Spectral Efficiency

The only option investigated in this section combines a rate 2/6 coding scheme with 4 QAM.

3.1 Coding

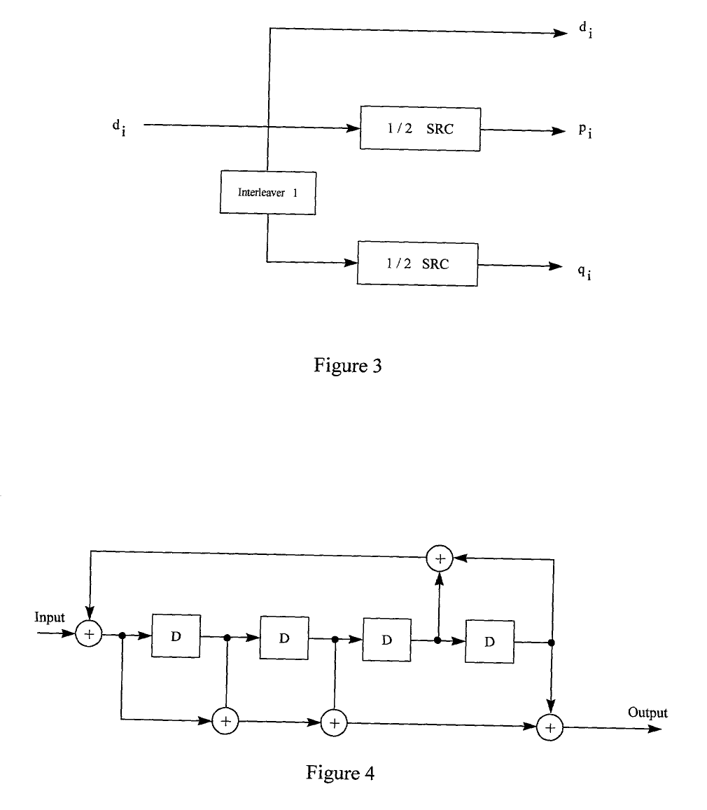

A preferred embodiment uses a coding scheme as shown in FIG. 3. The encoder is formed by two 1/2 systematic recursive constituent Concatenated Convolutional Encoders (CCE) that receive two inputs every information input bit cycle, adding one parity bit per dimension. We propose the convolution encoder format (g1,g2)=(23o,35o) joined through an interleaver and which can be generalized to a N constituent systematic encoders with N-1 interleavers.

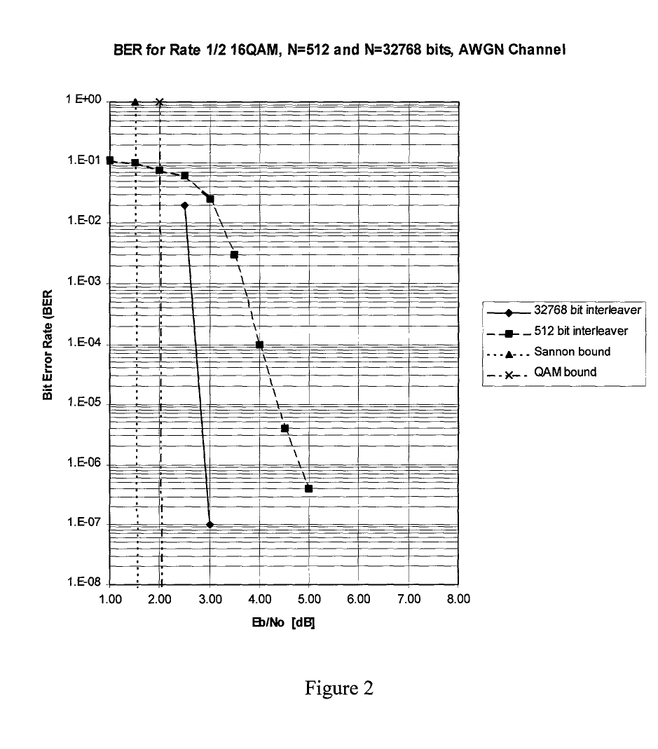

FIG. 4 shows a preferred convolutional encoder. g1 and g2 are the values in octal of the forward and feedback lines. In FIG. 2, the upper side the first line is feedback (value 1), the second line is also a feedback (value 2) and the fifth line as well (value 16). The feedback lines sum to a value of 19 in decimal or 23 in octal, and is represented as 23o. In FIG. 2, the lower side the first line is forward line (value 1), the same thing happen with the third (value 4), forth (value 8) and fifth (value 16), this makes the total forward line to a value of 29 in decimal or 35 in octal, and is represented as 35o.

3.2 Puncturing

In order to obtain a code rate of 2/6, no puncturing is applied. The transmission pattern is given in

Table 4.

TABLE 4
Transmission pattern for Rate 2/6 4 QAM.

| | | |
|---|---|---|
| Information bit (d) | d₁ | d₂ |
| parity bit (p) | p1 | p2 |
| parity bit (q) | q1 | q2 |

| | | | |
|---|---|---|---|
| 2 AM symbol (I) | (u₁) = (d₁) | (u₁) = (d₂) | (u₁) = (q1) |
| 2 AM symbol (Q) | (u₂) = (p1) | (u₂) = (q2) | (u₂) = (p2) |
| 4 QAM symbol (I, Q) | (I, Q) = | (I, Q) = | (I, Q) = |
| | (u₁, u₂) = | (u₁, u₂) = | (u₁, u₂) = |
| | (d₁, p1) | (d₂, q2) | (q1, p2) |

3.3 Modulation

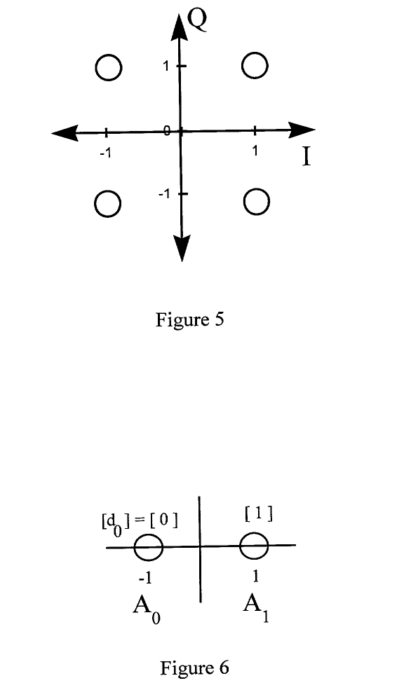

A 4 QAM scheme is shown in FIG. 5. At time k, the symbol u^{k}=(u₁^{k}) is sent through the channel and the point r^{k} in two dimensional space is received.

For a 4 QAM constellation with points at −A and A, The Eₐᵥ is:

$${E}_{av} = \frac{4 ( {A}^{2} + {A}^{2} )}{4} = 2 {A}^{2} \qquad ( 6 )$$

For a rate 2/6 code and 4 QAM, the noise variance is:

$${σ}_{N}^{2} = {E}_{av} ( \frac{2 η {E}_{b}}{{N}_{0}} ) = 2 {{A}^{2} ( \frac{2 \times \frac{2}{3} \times {E}_{b}}{{N}_{0}} )}^{- 1} = \frac{3}{2} {{A}^{2} ( \frac{{E}_{b}}{{N}_{0}} )}^{- 1} \qquad ( 7 )$$

It is assumed that the time k, u₁^{k} modulates the I component and u₂^{k} modulates the Q component for a 4 QAM scheme

The symbol u^{k} symbol has the following mapping: u^{k}=(u₁^{k}, u₂^{k})=(dⁱ, qⁱ); u^{k+1}=(u₁^{k+1}, u₂^{k+1})=(dⁱ⁺¹, qⁱ⁺¹); u^{k+2}=(u₁^{k+2}, u₂^{k+2}) =(qⁱ⁺¹, pⁱ⁺²)

Considering two independent Gaussian noises with identical variance σ²_{N}, the LLR can be determined independently for each I and Q.

At the receiver, the I and Q signals are treated independently in order to take advantage of the simpler formulae for the 2 bit-LLR values.

In order to estimate the performance of this scheme, a 2 AM modulation is used, as it is shown in FIG. 6, instead of 4 QAM modulation.

The 4 QAM scheme will achieve a similar performance in terms of bit error rate (BER) at twice the spectral efficiency, assuming an ideal demodulator.

For a rate 2/6 code and a 2 AM scheme as shown in FIG. 6, the noise variance is:

Eₐᵥ_{_{—}}_{I}=(1+1)A²/2=A² (8)

$${σ}_{N}^{2} = {E}_{av} ( \frac{2 η {E}_{b}}{{N}_{0}} ) = {{A}^{2} ( \frac{2 ⅇ \frac{2}{6} \times {E}_{b}}{{N}_{0}} )}^{- 1} = \frac{3}{2} {{A}^{2} ( \frac{{E}_{b}}{{N}_{0}} )}^{- 1} \qquad ( 9 )$$

That is the same that the 4 QAM of equation (7)

3.4 Bit Probabilities

For an AWGN channel the following expressions need to be evaluated:

$$\begin{matrix}\begin{matrix}LLR ( {u}_{1}^{k} ) = log ( \frac{{\sum }_{i = 1}^{1} exp [ - \frac{1}{2 {σ}_{N}^{2}} {( {I}^{k} - {a}_{1 i}^{k} )}^{2} ]}{{\sum }_{i = 1}^{1} exp [ - \frac{1}{2 {σ}_{N}^{2}} {( {I}^{k} - {a}_{0 j}^{k} )}^{2} ]} ) \\ = log ( \frac{exp [ - \frac{1}{2 {σ}_{N}^{2}} {( {I}^{k} - {A}_{1} )}^{2} ]}{exp [ - \frac{1}{2 {σ}_{N}^{2}} {( {I}^{k} - {a}_{0 j}^{k} )}^{2} ]} )\end{matrix} & ( 10 ) \\ \begin{matrix}LLR ( {u}_{2}^{k} ) = log ( \frac{{\sum }_{i = 1}^{1} exp [ - \frac{1}{2 {σ}_{N}^{2}} {( {Q}^{k} - {a}_{1 i}^{k} )}^{2} ]}{{\sum }_{i = 1}^{1} exp [ - \frac{1}{2 {σ}_{N}^{2}} {( {I}^{k} - {a}_{0 j}^{k} )}^{2} ]} ) \\ = log ( \frac{exp [ - \frac{1}{2 {σ}_{N}^{2}} {( {I}^{k} - {B}_{1} )}^{2} ]}{exp [ - \frac{1}{2 {σ}_{N}^{2}} {( {Q}^{k} - {B}_{0} )}^{2} ]} )\end{matrix} & ( 11 )\end{matrix}$$

The above LLRs are used as inputs to the turbo encoder. There is no need to compute the 4 LLRs for all symbols because I and Q signals are treated independently. Also the simulations for the 2 bit-LLR values are reduced to one term each.

3.5 Simulations Results

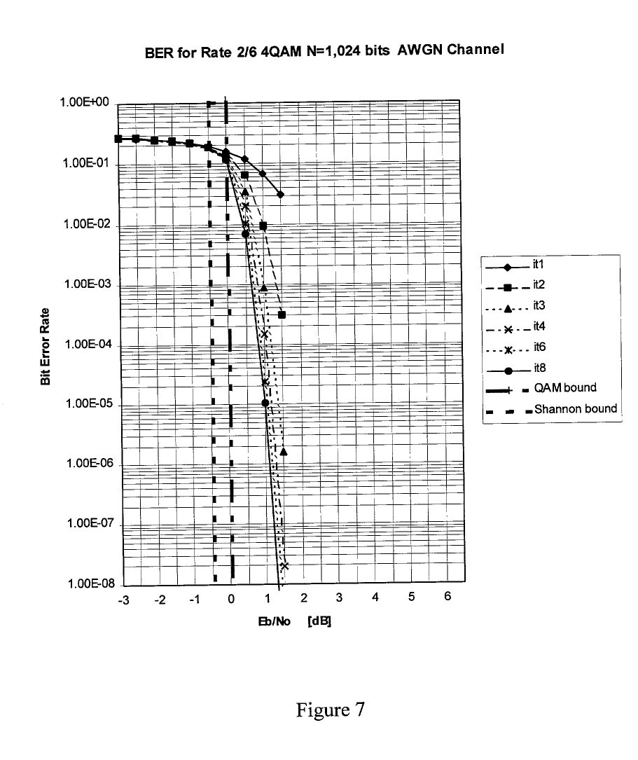

FIG. 7 shows the performance of a turbo code which 1024 bit interleavers using S-type interleaver.

The target BER of 10⁻⁷ for a 1,024 information bit interleaver can be achieve at E_{b}/N_{O}=1.25 dB

4. Coding and Modulation for 1 bit/s/Hz Spectral Efficiency

Two options are investigated in this section. The first scheme combines a rate 2/4 coding scheme with 4 QAM. The second scheme investigated combines 2/6 coding scheme with 8 QAM.

4.1 Option 1: Rate 2/4 Turbo Code and 4 QAM

4.1.1 Coding

The coding scheme is shown in FIG. 3.

The two systematic recursive codes (SRC) used are identical and are defined in FIG. 4. The code is described by the generating polynomials 35o and 23o.

4.1.2 Puncturing

In order to obtain a code rate of 2/4, every other bit of the parity bits p and q from FIG. 3 are punctured. The puncturing pattern is given in Table 5.

TABLE 5
Puncturing and Mapping for Rate 2/4 4 QAM.

| | | |
|---|---|---|
| Information bit (d) | d₁ | d₂ |
| parity bit (p) | p₁ | — |
| parity bit (q) | — | q₂ |
| 2 AM symbol (I) | (u₁) = (d₁) | (u₁) = (d₂) |
| 2 AM symbol (Q) | (u₂) = (p₁) | (u₂) = (q₂) |
| 4 QAM symbol (I,Q) | (I,Q) = (u₁, u₂) = (d₁, p₁) | (I,Q) = (u₁, u₂) = (q₂) |

4.1.3 Modulation

A 4 QAM scheme is shown in FIG. 5. At time k, the symbol u^{k}=(u₁^{k}, u₂^{k}) is sent through the channel and the point r^{k} in two dimensional space is received.

For a 4 QAM constellation with points at −A and A, The Eₐᵥ is:

$${E}_{av} = \frac{4 ( {A}^{2} + {A}^{2} )}{4} = 2 {A}^{2} \qquad ( 12 )$$

For a rate 2/4 code and 4 QAM, the noise variance is:

$${σ}_{N}^{2} = {E}_{av} ( \frac{2 η {E}_{b}}{{N}_{0}} ) = 2 {{A}^{2} ( \frac{2 \times 1 \times {E}_{b}}{{N}_{0}} )}^{- 1} = {{A}^{2} ( \frac{{E}_{b}}{{N}_{0}} )}^{- 1} \qquad ( 13 )$$

It is assumed that the time k, u₁^{k} modulates the I component and u₂^{k} modulates the Q component for a 4 QAM scheme.

The symbol u^{k} symbol has the following mapping: u^{k}=(u₁^{k}, u₂^{k})=(dⁱ, pⁱ); u^{k+1}=(u₁^{k+1}, u₂^{k+1})=(dⁱ⁺¹, qⁱ⁺¹).

Considering two independent Gaussian noises with identical variance σ²_{N}, the LLR can be determined independently for each I and Q.

At the receiver, the I and Q signal are treated independently in order to take advantage of the simpler formulae for the 2 bit-LLR values.

In order to estimate the performance of this scheme, rate 1/2 turbo codes a 2 AM modulation is used, as it is shown in FIG. 6, instead of 4 QAM modulation.

The 4 QAM scheme will achieve a similar performance in terms of bit error rate (BER) at twice the spectral efficiency, assuming an ideal demodulator.

For a rate 1/2 code and a 2 AM scheme as shown in FIG. 6, the noise variance is:

Eₐᵥ_{_{—}}_{I}=(1+1)A²/2=A² (14)

$${σ}_{N}^{2} = {E}_{av} ( \frac{2 η {E}_{b}}{{N}_{0}} ) = {{A}^{2} ( \frac{2 \times 0.5 \times {E}_{b}}{{N}_{0}} )}^{- 1} = {{A}^{2} ( \frac{{E}_{b}}{{N}_{0}} )}^{- 1} \qquad ( 15 )$$

That is the same that the 4 QAM of equation (13)

4.1.4 Bit Probabilities.

For an AWGN channel the following expressions need to be evaluated.

$$\begin{matrix}\begin{matrix}LLR ( {u}_{1}^{k} ) = log ( \frac{{\sum }_{i = 1}^{1} exp [ - \frac{1}{2 {σ}_{N}^{2}} {( {I}^{k} - {a}_{1 i}^{k} )}^{2} ]}{{\sum }_{i = 1}^{1} exp [ - \frac{1}{2 {σ}_{N}^{2}} {( {I}^{k} - {a}_{0 j}^{k} )}^{2} ]} ) \\ = log ( \frac{exp [ - \frac{1}{2 {σ}_{N}^{2}} {( {I}^{k} - {A}_{1} )}^{2} ]}{exp [ - \frac{1}{2 {σ}_{N}^{2}} {( {I}^{k} - {a}_{0 j}^{k} )}^{2} ]} )\end{matrix} & ( 16 ) \\ \begin{matrix}LLR ( {u}_{2}^{k} ) = log ( \frac{{\sum }_{i = 1}^{1} exp [ - \frac{1}{2 {σ}_{N}^{2}} {( {I}^{k} - {a}_{1 i}^{k} )}^{2} ]}{{\sum }_{i = 1}^{1} exp [ - \frac{1}{2 {σ}_{N}^{2}} {( {I}^{k} - {a}_{0 j}^{k} )}^{2} ]} ) \\ = log ( \frac{exp [ - \frac{1}{2 {σ}_{N}^{2}} {( {Q}^{k} - {B}_{1} )}^{2} ]}{exp [ - \frac{1}{2 {σ}_{N}^{2}} {( {I}^{k} - {B}_{0} )}^{2} ]} )\end{matrix} & ( 17 )\end{matrix}$$

The above LLRs are used as inputs to the turbo encoder. There is no need to compute the 4 LLRs for all symbols because I and Q signals are treated independently. Also the simulations for the 2 bit-LLR values are reduced to one term each. Due to the puncturing, with one in two parity bits being transmitted, the expected performance will be lower when compared with the non-punctured scheme.

For an Impulse Noise channel, for a determined period of time (the duration of the impulse) the E_{b}/N_{O} ratio changes to a worse value, and the errors occurs. The Reference Level of E_{b}/N_{O} is set to the value of E_{b}/N_{O} needed by the un-coded QAM constellation to reach the value of BER of 10⁻⁷.

4.1.5 Simulations Results

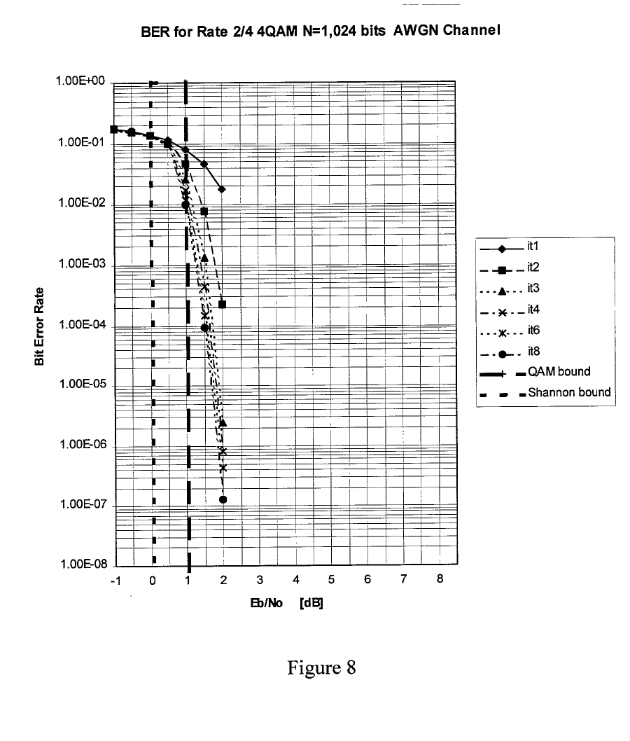

FIG. 8 shows the performance of a turbo code which 1024 bit interleavers using S-type interleaver.

The target BER of 10⁻⁷ for a 1,024 information bit interleaver can be achieve at E_{b}/N_{O}=2.1 dB

4.2 Option 1: Rate 1/3 Turbo Code and 8 QAM

4.2.1 Coding

The coding scheme is shown in FIG. 3.

The two systematic recursive codes (SRC) used are identical and are defined in FIG. 4. The code is described by the generating polynomials 35o and 23o.

4.2.2 Puncturing

No puncturing is applying in this case. The pattern is given in Table 6.

TABLE 6
Pattern and Mapping for Rate 1/3 8 QAM.

| | |
|---|---|
| Information bit (d) | d₁ |
| parity bit (p) | p1 |
| parity bit (q) | q1 |
| 4 AM symbol (I) | (u₁, u₂) = (d₁, p1) |
| 2 AM symbol (Q) | (u₃) = (q1) |
| 8 QAM symbol (I, Q) | (I, Q) = (d₁, p1, q1) |

4.2.3 Modulation

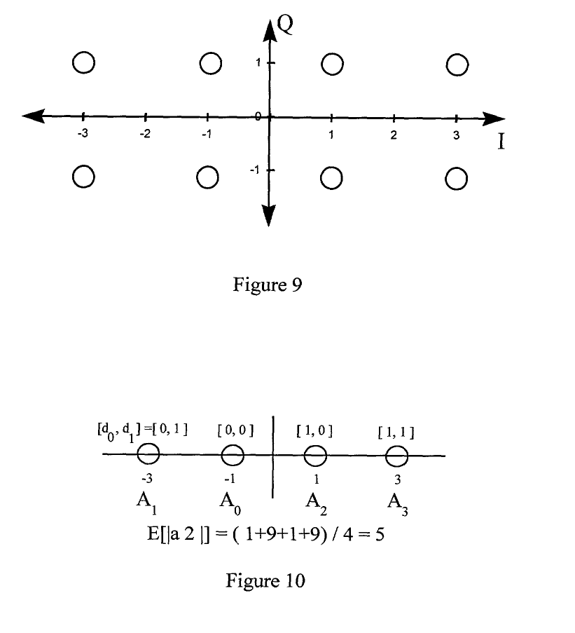

The 8 QAM scheme used is shown in FIG. 9. At time k, the symbol u^{k}=(u₁^{k}, u₂^{k}, u₃^{k}) is sent through the channel and the point r^{k} in two dimensional space is received.

For an 8 QAM costellation with points at −3A, −A, A and 3A, in the I dimension and −A, and A in the Q dimension

$$\begin{matrix}The {E}_{av \_ I} is \text{:} & \\ {E}_{av \_ I} = \frac{( 1 + 9 + 1 + 9 ) {A}^{2}}{4} = 5 {A}^{2} & ( 18 ) \\ The {E}_{av \_ Q} is \text{:} & \\ {E}_{av \_ Q} = \frac{( 1 + 1 ) {A}^{2}}{2} = {A}^{2} & ( 19 )\end{matrix}$$

Because the noise has to be spherical, the total value of Eₐᵥ will be the addition of these two values, so:

Eₐᵥ=Eₐᵥ_{_{—}}I+Eₐᵥ_{_{—}}Q=6A² (20)

The value of the noise variance has to be the same in both dimensions and its value is:

$${σ}_{N}^{2} = {E}_{av} ( \frac{2 η {E}_{b}}{{N}_{0}} ) = 6 {{A}^{2} ( \frac{2 \times 1 \times {E}_{b}}{{N}_{0}} )}^{- 1} = 3 {{A}^{2} ( \frac{{E}_{b}}{{N}_{0}} )}^{- 1} \qquad ( 21 )$$

It is assumed that the time k, u₁^{k} and u₂^{k} modulates the I component and u₃^{k} modulates the Q component for an 8 QAM scheme.

The symbol u^{k} has the following mapping: u^{k}=(u₁^{k}, u₂^{k}, u₃^{k})=(dⁱ, pⁱ, qⁱ). The parity bits are mapped to the least protected bits of the QAM symbol. Note that k denotes the symbol time index and information bit time index.

Considering two independent Gaussian noises with identical variance σ²_{N}, the LLR can be determined independently for each I and Q.

At the receiver, the I and Q signals are treated independently in order to take advantage of the simpler formulae for the LLR values. The mapping of the information bit is made to the most protected bit in each dimension (u₁^{k} for the I signal and u₃^{k} for the Q signal in FIG. 9).

In order to estimate the performance of this scheme, rate 1/3 turbo codes and 4 AM modulation (as it is shown in FIG. 10) is used in the I dimension, and a 2 AM modulation is used for the Q dimension, (as it is shown in FIG. 6), instead of 8 QAM modulation.

4.2.4 Bit Probabilities

For an AWGN channel the following expressions need to be evaluated:

$$\begin{matrix}\begin{matrix}LLR {(}_{{u}_{1}}^{k} ) = log ( \frac{{\sum }_{i = 1}^{2} exp [ - \frac{1}{2 {σ}_{N}^{2}} {( {I}^{k} - {a}_{1 , j}^{k} )}^{2} ]}{{\sum }_{i = 1}^{2} exp [ - \frac{1}{2 {σ}_{N}^{2}} {( {I}^{k} - {a}_{0 , j}^{k} )}^{2} ]} ) \\ = log ( \frac{exp [ - \frac{1}{2 {σ}_{N}^{2}} {( {I}^{k} - {A}_{2} )}^{2} ] + exp [ - \frac{1}{2 {σ}_{N}^{2}} {( {I}^{k} - {A}_{3} )}^{2} ]}{exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{1} )}^{2} ]} )\end{matrix} & ( 22 ) \\ \begin{matrix}LLR {(}_{{u}_{2}}^{k} ) = log ( \frac{{\sum }_{i = 1}^{2} exp [ - \frac{1}{2 {σ}_{N}^{2}} {( {I}^{k} - {a}_{1 , j}^{k} )}^{2} ]}{{\sum }_{i = 1}^{2} exp [ - \frac{1}{2 {σ}_{N}^{2}} {( {I}^{k} - {a}_{0 , j}^{k} )}^{2} ]} ) \\ = log ( \frac{exp [ - \frac{1}{2 {σ}_{N}^{2}} {( {I}^{k} - {A}_{1} )}^{2} ] + exp [ - \frac{1}{2 {σ}_{N}^{2}} {( {I}^{k} - {A}_{3} )}^{2} ]}{exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{2} )}^{2} ]} )\end{matrix} & ( 23 ) \\ \begin{matrix}LLR {(}_{{u}_{3}}^{k} ) = log ( \frac{{\sum }_{i = 1}^{1} exp [ - \frac{1}{2 {σ}_{N}^{2}} {( {Q}^{k} - {a}_{1 , j}^{k} )}^{2} ]}{{\sum }_{i = 1}^{1} exp [ - \frac{1}{2 {σ}_{N}^{2}} {( {Q}^{k} - {a}_{0 , j}^{k} )}^{2} ]} ) \\ = log ( \frac{exp [ - \frac{1}{2 {σ}_{N}^{2}} {( {Q}^{k} - {B}_{1} )}^{2} ]}{exp [ - \frac{1}{2 {σ}_{N}^{2}} {( {Q}^{k} - {B}_{0} )}^{2} ]} )\end{matrix} & ( 24 )\end{matrix}$$

The above LLRs are used as inputs to the turbo encoder. There is no need to compute the 8 LLRs for all symbols because I and Q signals are treated independently. Also the simulations for the LLR values are reduced to two terms for the 4 AM modulation and one term for the 2 AM modulation. Due to the puncturing, the expected performance will be lower when compared with the non-punctured scheme.

4.2.5 Simulations Results

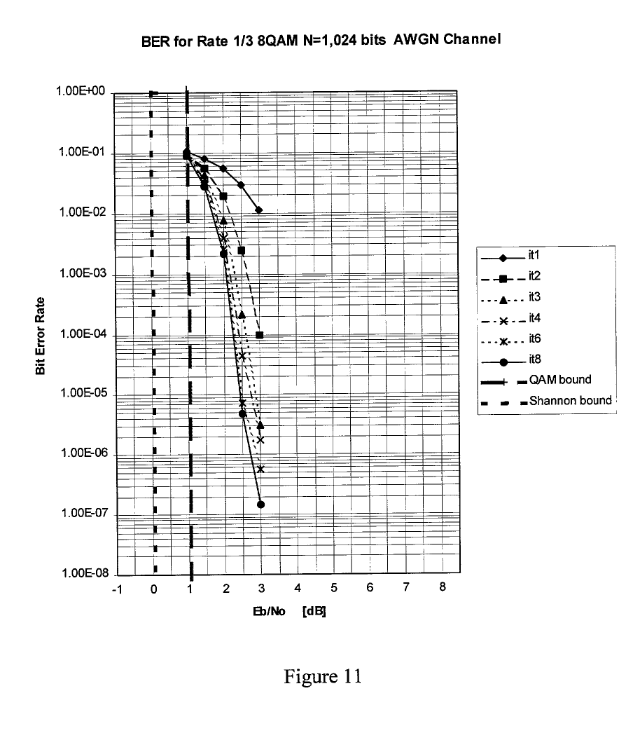

FIG. 11 shows the performance of a turbo code, which used 1024 bit interleavers using S-type interleaver.

The target BER of 10⁻⁷ can be achieve at E_{b}/N_{O}=3.1 dB.

5. Coding and Modulation for 2 bit/s/Hz Spectral Efficiency

Two options are investigated in this section. The first scheme combines a rate 4/6 coding scheme with 8 QAM. The second scheme investigated combines 1/2 coding scheme with 16 QAM. These schemes have the advantage of a very efficient implementation without any significant compromise in performance.

5.1 Option 1: Rate 4/6 Turbo Code and 8 QAM

5.1.1 Coding

The coding scheme is shown in FIG. 3.

The two systematic recursive codes (SRC) used are identical and are defined in FIG. 4. The code is described by the generating polynomials 35o and 23o. 5.1.2 Puncturing

In accordance with an embodiment of the invention, the puncturing pattern given in Table 7 is used in order to obtain a rate 4/6 code.

TABLE 7
Puncturing and Mapping for Rate 4/6 8 QAM.

| | | | | |
|---|---|---|---|---|
| Information bit (d) | d₁ | d₂ | d₃ | d₄ |
| parity bit (p) | p1 | — | — | — |
| parity bit (q) | — | — | q3 | — |

| | | |
|---|---|---|
| 4 AM symbol (I) | (u₁, u₂) = | (u₁, u₂) = |
| | (d₁, p1) | (d₃, q3) |
| 2 AM symbol (Q) | (u₃) = (d₂) | (u₃) = (d₄) |
| 8 QAM symbol (I, Q) | (I, Q) = | (I, Q) = |
| | (d₁, p1, d₂) | (d₃, q3, d₄) |

5.1.3 Modulation

The 8 QAM scheme used is shown in FIG. 9. At time k, the symbol u^{k}=(u₁^{k}, u₂^{k}, u₃^{k}) is sent through the channel and the point r^{k} in two dimensional space is received.

For an 8 QAM costellation with points at −3A, −A, A and 3A, in the I dimension and −A, and A in the Q dimension

The Eₐᵥ_{_{—}}I is:

$$\begin{matrix}{E}_{av\_I} = \frac{( 1 + 9 + 1 + 9 ) {A}^{2}}{4} = 5 {A}^{2} & ( 25 ) \\ The {E}_{av\_Q} is \text{:} {E}_{av\_Q} = \frac{( 1 + 1 ) {A}^{2}}{2} = {A}^{2} & ( 26 )\end{matrix}$$

Because the noise has to be spherical, the total value of Eₐᵥ will be the addition of these two values, so:

Eₐᵥ=Eₐᵥ_{_{—}}I+Eₐᵥ_{_{—}}Q=6A² (27)

The value of the noise variance has to be the same in both dimensions and its value is:

$${σ}_{N}^{2} = {E}_{av} ( \frac{2 η {E}_{b}}{{N}_{0}} ) = 6 {{A}^{2} ( \frac{2 \times 2 \times {E}_{b}}{{N}_{0}} )}^{- 1} = \frac{3}{2} {{A}^{2} ( \frac{{E}_{b}}{{N}_{0}} )}^{- 1} \qquad ( 28 )$$

It is assumed that the time k, u₁^{k} and u₂^{k} modulates the I component and u₃^{k} modulates the Q component for an 8 QAM scheme.

The symbol u^{k} has the following mapping: u^{k}=(u₁^{k}, u₂^{k}, u₃^{k})=(d¹, p¹, d¹⁺¹). The parity bits are mapped to the least protected bits of the QAM symbol. Note that k denotes the symbol time index and information bit time index.

Considering two independent Gaussian noises with identical variance σ²_{N}, the LLR can be determined independently for each I and Q.

At the receiver, the I and Q signals are treated independently in order to take advantage of the simpler formulae for the LLR values. The mapping of the information bit is made to the most protected bit in each dimension (u₁^{k} for the I signal and u₃^{k} for the Q signal in FIG. 9).

In order to estimate the performance of this scheme, rate 4/6 turbo codes and 4 AM modulation (as it is shown in FIG. 10) is used in the I dimension, and a 2 AM modulation is used for the Q dimension, (as it is shown in FIG. 6), instead of 8 QAM modulation.

5.1.4 Bit Probabilities

For an AWGN channel the following expressions need to be evaluated:

$$\begin{matrix}\begin{matrix}LLR {(}_{{u}_{1}}^{k} ) = log ( \frac{{\sum }_{i = 1}^{2} exp [ - \frac{1}{2 {σ}_{N}^{2}} {( {I}^{k} - {a}_{1 , j}^{k} )}^{2} ]}{{\sum }_{i = 1}^{2} exp [ - \frac{1}{2 {σ}_{N}^{2}} {( {I}^{k} - {a}_{0 , j}^{k} )}^{2} ]} ) \\ = log ( \frac{exp [ - \frac{1}{2 {σ}_{N}^{2}} {( {I}^{k} - {A}_{2} )}^{2} ] + exp [ - \frac{1}{2 {σ}_{N}^{2}} {( {I}^{k} - {A}_{3} )}^{2} ]}{exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{1} )}^{2} ]} )\end{matrix} & ( 29 ) \\ \begin{matrix}LLR {(}_{{u}_{2}}^{k} ) = log ( \frac{{\sum }_{i = 1}^{2} exp [ - \frac{1}{2 {σ}_{N}^{2}} {( {I}^{k} - {a}_{1 , j}^{k} )}^{2} ]}{{\sum }_{i = 1}^{2} exp [ - \frac{1}{2 {σ}_{N}^{2}} {( {I}^{k} - {a}_{0 , j}^{k} )}^{2} ]} ) \\ = log ( \frac{exp [ - \frac{1}{2 {σ}_{N}^{2}} {( {I}^{k} - {A}_{1} )}^{2} ] + exp [ - \frac{1}{2 {σ}_{N}^{2}} {( {I}^{k} - {A}_{3} )}^{2} ]}{exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{2} )}^{2} ]} )\end{matrix} & ( 30 ) \\ \begin{matrix}LLR {(}_{{u}_{3}}^{k} ) = log ( \frac{{\sum }_{i = 1}^{1} exp [ - \frac{1}{2 {σ}_{N}^{2}} {( {Q}^{k} - {a}_{1 , j}^{k} )}^{2} ]}{{\sum }_{i = 1}^{1} exp [ - \frac{1}{2 {σ}_{N}^{2}} {( {Q}^{k} - {a}_{0 , j}^{k} )}^{2} ]} ) \\ = log ( \frac{exp [ - \frac{1}{2 {σ}_{N}^{2}} {( {Q}^{k} - {B}_{1} )}^{2} ]}{exp [ - \frac{1}{2 {σ}_{N}^{2}} {( {Q}^{k} - {B}_{0} )}^{2} ]} )\end{matrix} & ( 31 )\end{matrix}$$

The above LLRs are used as inputs to the turbo encoder. There is no need to compute the 8 LLRs for all symbols because I and Q signals are treated independently. Also the simulations for the LLR values are reduced to two terms for the 4 AM modulation and one term for the 2 AM modulation. Due to the puncturing, the expected performance will be lower when compared with the non-punctured scheme.

5.1.5 Simulations Results

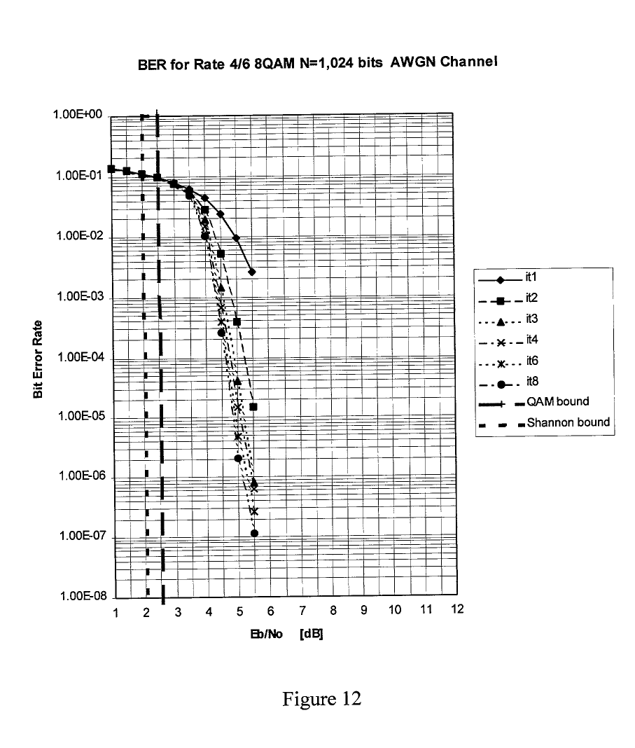

FIG. 12 shows the performance of a turbo code, which used 1024 bit interleavers using S-type interleaver.

The target BER of 10⁻⁷ can be achieve at E_{b}/N_{O}=5.5 dB.

5.2 Option 2: Rate 1/2 Turbo Code and 16 QAM

5.2.1 Coding

The coding scheme is shown in FIG. 3.

The two systematic recursive codes (SRC) used are identical and are defined in FIG. 4. The code is described by the generating polynomials 35o and 23o.

5.2.2 Puncturing

In order to obtain a rate 1/2 code, every other bit of the parity bits p and q from FIG. 3 are punctured. The puncturing pattern is given in Table 8. This is the traditional puncturing pattern using alternating parity bits in each cycle.

TABLE 8
Puncturing and Mapping for Rate 1/2 16 QAM.

| | | |
|---|---|---|
| Information bit (d) | d₁ | d₂ |
| parity bit (p) | p1 | — |
| parity bit (q) | — | q2 |

| | |
|---|---|
| 4 AM symbol (I) | (u₁, u₂) = (d₁, p1) |
| 4 AM symbol (Q) | (u₃, u₄) = (d₂, q2) |
| 16 QAM symbol (I, Q) | (I, Q) = (u₁, u₂, u₃, u₄) = (d₁, p1, d₂, q2) |

5.2.3 Modulation

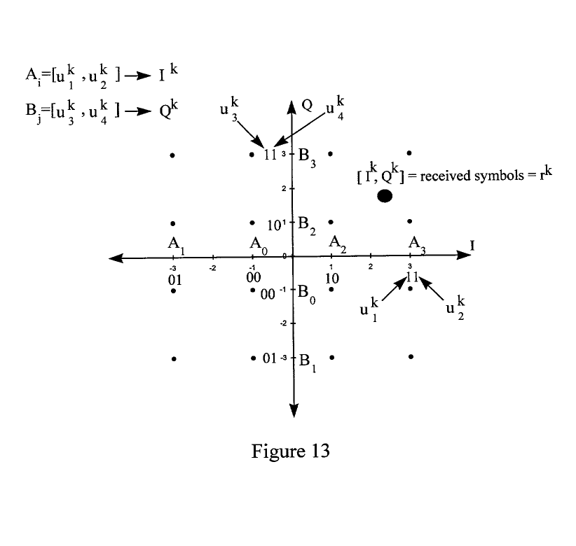

A 16 QAM scheme is shown in FIG. 13. At time k, the symbol u^{k}=(u₁^{k}, u₂^{k}, u₃^{k}, u₄^{k}) is sent through the channel and the point r^{k} in two dimensional space is received.

For a 16 QAM constellation with points at −3A, −A,A and 3A, The Eₐᵥ is:

$${E}_{av} = \frac{4 ( {A}^{2} + {A}^{2} ) + 8 ( {A}^{2} + 9 {A}^{2} ) + 4 ( 9 {A}^{2} + 9 {A}^{2} )}{16} = 10 {A}^{2} \qquad ( 32 )$$

For a rate 1/2 code and 16 QAM, the noise variance in each dimension is:

$${σ}_{N}^{2} = {E}_{av} ( \frac{2 η {E}_{b}}{{N}_{0}} ) = 10 {{A}^{2} ( \frac{2 \times 2 \times {E}_{b}}{{N}_{0}} )}^{- 1} = 2.5 {{A}^{2} ( \frac{{E}_{b}}{{N}_{0}} )}^{- 1} \qquad ( 33 )$$

It is assumed that the time k, u₁^{k} and u₂^{k} modulates the I component and u₃^{k} and u₄^{k} modulates the Q component for a 16 QAM scheme.

The symbol u^{k} symbol has the following mapping: u^{k}=(u₁^{k}, u₂^{k}, u₃^{k}, u₄^{k})=(dⁱ, pⁱ, dⁱ⁺ⁱ, qⁱ⁺ⁱ). The parity bits are mapped to the least protected bits of the QAM symbol. Note that k denotes the symbol time index and i the information bit time index. This means a puncturing of one in two parity bits.

Considering two independent Gaussian noises with identical variance σ²_{N}, the LLR can be determined independently for each I and Q.

At the receiver, the I and Q signals are treated independently in order to take advantage of the simpler formulae for the 4 bit-LLR values. The mapping of the information bit is made to the most protected bit in each dimension (u₁^{k} for the I signal and u₃^{k} for the Q signal in FIG. 13).

In order to estimate the performance of this scheme, rate 1/2 turbo code and 4 AM modulation is used (as it is shown in FIG. 10), instead of 16 QAM modulation.

The 16 QAM scheme will achieve a similar performance in terms of bit error rate (BER) at twice the spectral efficiency, assuming an ideal demodulator.

For a rate 1/2 code and a 4 AM scheme as shown in FIG. 6, the noise variance is:

Eₐᵥ_{_{—}}_{I}=(1+9)A²/2=5A² (34)

$${σ}_{N}^{2} = {E}_{av} ( \frac{2 η {E}_{b}}{{N}_{0}} ) = 5 {{A}^{2} ( \frac{2 \times 1 \times {E}_{b}}{{N}_{0}} )}^{- 1} = 2.5 {{A}^{2} ( \frac{{E}_{b}}{{N}_{0}} )}^{- 1} \qquad ( 35 )$$

5.2.4 Bit Probabilities

For an AWGN channel the following expressions need to be evaluated:

$$\begin{matrix}\begin{matrix}LLR {(}_{{u}_{1}}^{k} ) = log ( \frac{{\sum }_{i = 1}^{2} exp [ - \frac{1}{2 {σ}_{N}^{2}} {( {I}^{k} - {a}_{1 , j}^{k} )}^{2} ]}{{\sum }_{i = 1}^{2} exp [ - \frac{1}{2 {σ}_{N}^{2}} {( {I}^{k} - {a}_{0 , j}^{k} )}^{2} ]} ) \\ = log ( \frac{exp [ - \frac{1}{2 {σ}_{N}^{2}} {( {I}^{k} - {A}_{2} )}^{2} ] + exp [ - \frac{1}{2 {σ}_{N}^{2}} {( {I}^{k} - {A}_{3} )}^{2} ]}{exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{1} )}^{2} ]} )\end{matrix} & ( 36 ) \\ \begin{matrix}LLR {(}_{{u}_{2}}^{k} ) = log ( \frac{{\sum }_{i = 1}^{2} exp [ - \frac{1}{2 {σ}_{N}^{2}} {( {I}^{k} - {a}_{1 , j}^{k} )}^{2} ]}{{\sum }_{i = 1}^{2} exp [ - \frac{1}{2 {σ}_{N}^{2}} {( {I}^{k} - {a}_{0 , j}^{k} )}^{2} ]} ) \\ = log ( \frac{exp [ - \frac{1}{2 {σ}_{N}^{2}} {( {I}^{k} - {A}_{1} )}^{2} ] + exp [ - \frac{1}{2 {σ}_{N}^{2}} {( {I}^{k} - {A}_{3} )}^{2} ]}{exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{2} )}^{2} ]} )\end{matrix} & ( 37 ) \\ \begin{matrix}LLR {(}_{{u}_{3}}^{k} ) = log ( \frac{{\sum }_{i = 1}^{2} exp [ - \frac{1}{2 {σ}_{N}^{2}} {( {Q}^{k} - {a}_{1 , j}^{k} )}^{2} ]}{{\sum }_{i = 1}^{2} exp [ - \frac{1}{2 {σ}_{N}^{2}} {( {Q}^{k} - {a}_{0 , j}^{k} )}^{2} ]} ) \\ = log ( \frac{exp [ - \frac{1}{2 {σ}_{N}^{2}} {( {Q}^{k} - {B}_{2} )}^{2} ] + exp [ - \frac{1}{2 {σ}_{N}^{2}} {( {Q}^{k} - {B}_{3} )}^{2} ]}{exp [ - \frac{1}{2 {σ}_{N}^{2}} {( {Q}^{k} - {B}_{0} )}^{2} ] + exp [ - \frac{1}{2 {σ}_{N}^{2}} {( {Q}^{k} - {B}_{1} )}^{2} ]} )\end{matrix} & ( 38 ) \\ \begin{matrix}LLR {(}_{{u}_{4}}^{k} ) = log ( \frac{{\sum }_{i = 1}^{2} exp [ - \frac{1}{2 {σ}_{N}^{2}} {( {Q}^{k} - {a}_{1 , j}^{k} )}^{2} ]}{{\sum }_{i = 1}^{2} exp [ - \frac{1}{2 {σ}_{N}^{2}} {( {Q}^{k} - {a}_{0 , j}^{k} )}^{2} ]} ) \\ = log ( \frac{exp [ - \frac{1}{2 {σ}_{N}^{2}} {( {Q}^{k} - {B}_{1} )}^{2} ] + exp [ - \frac{1}{2 {σ}_{N}^{2}} {( {Q}^{k} - {B}_{3} )}^{2} ]}{exp [ - \frac{1}{2 {σ}_{N}^{2}} {( {Q}^{k} - {B}_{0} )}^{2} ] + exp [ - \frac{1}{2 {σ}_{N}^{2}} {( {Q}^{k} - {B}_{2} )}^{2} ]} )\end{matrix} & ( 39 )\end{matrix}$$

The above LLRs are used as inputs to the turbo encoder. There is no need to computer the 16 LLR for all symbols because O and Q signals are treated independently. Also the simulations for the 4 bit-LLR values are reduced to 2 terms each. Due to the puncturing, with one in two parity bits being transmitted, the expected performance will be lower when compared with the non punctured scheme.

5.2.5 Simulations Results

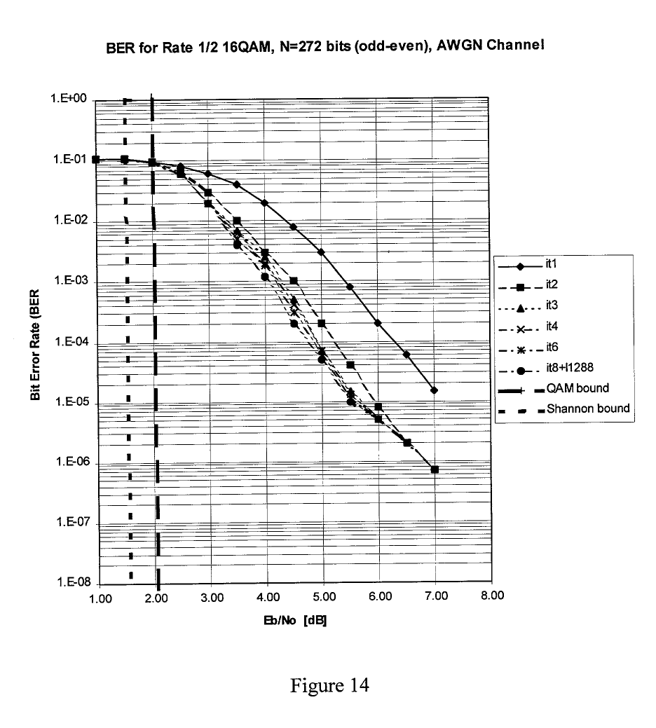

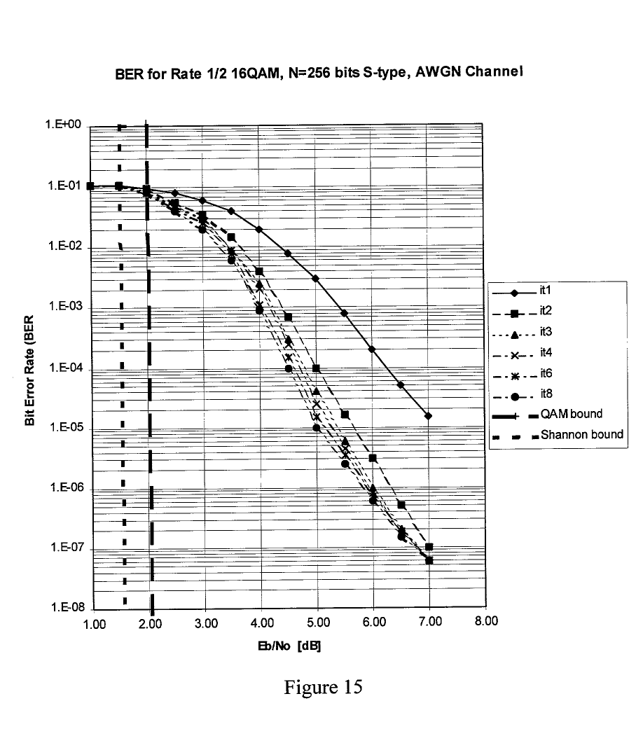

FIG. 14 shows the performance of a turbo code that uses the odd-even block helical interleaver of 272 bits. FIG. 15 shows the performance of a turbo code that uses the S-type interleaver for 256 bits.

The S-type interleaver performs better than the odd-even block helical interleaver with approximately 1 dB at a BER=10⁻⁶ in this case. Therefore, the rest of the simulations used the S-type interleaver.

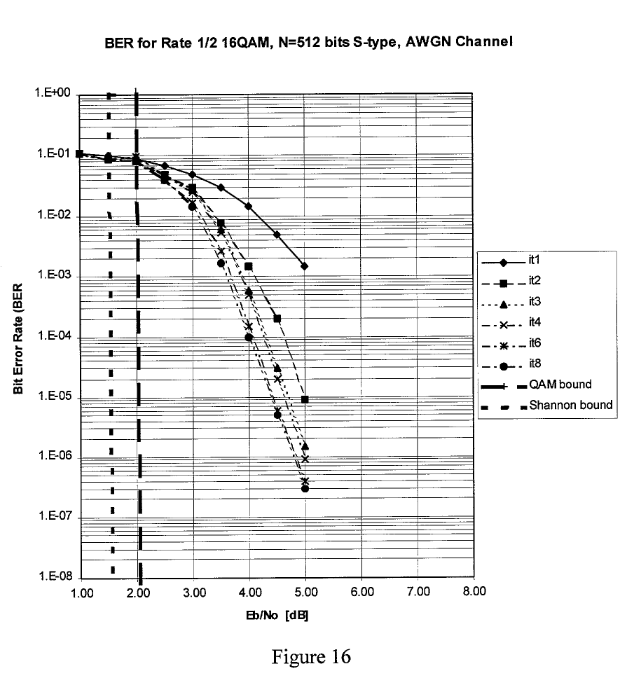

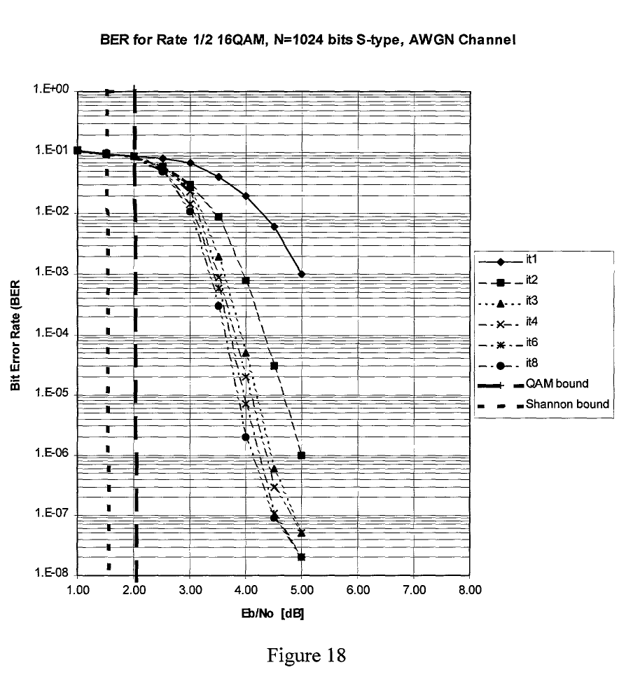

FIGS. 16 to 18 show the simulation results for 512, 768 and 1024 bit interleavers using S-type interleaver.

A search for the best S-type interleavers was performed. For each interleaver size, the maximum S-factor was found and four different interleavers were generated using a random seed. Four simulations were generated for a target BER of 10⁻⁵. The best result decided the preferred interleaver, complete simulations were started for BERs down to 10⁻⁷.

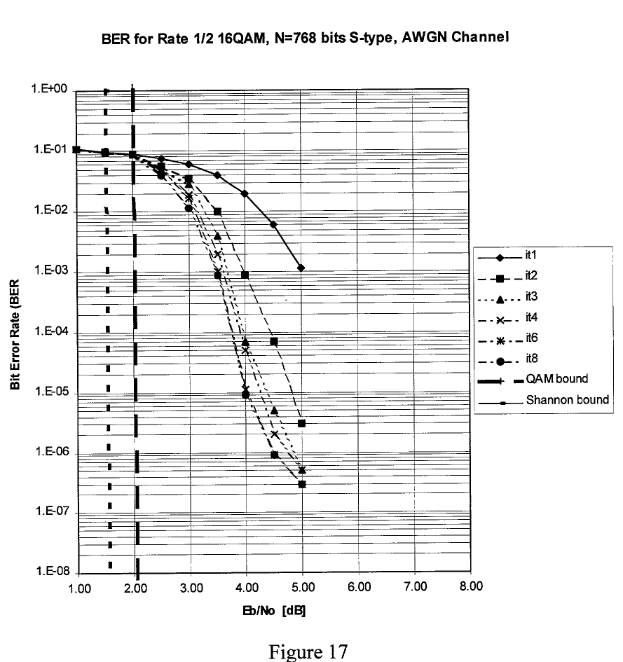

In the case of N=768, a further interleaver search is required in order to avoid the flattening of the BER curve which started to show below 10⁻⁶ in FIG. 17.

5.2.6 Recommended Solution

The rate 1/2 16 QAM scheme described in this chapter achieves the target BER at less than 1.5 dB from capacity. The implementation in hardware is feasible and it can be used at very high data rates.

The target BER of 10⁻⁷ can be achieve at the following values of E_{b}/N_{O}=6.8 dB for N=256 information bits and E_{b}/N_{O}=is 4.5 dB for N=1024 information bits.

6. Coding and Modulation for 3 bit/s/Hz Spectral Efficiency

Three options are investigated in this section. The first scheme combines a rate 3/4 coding scheme with 16 QAM The second scheme combines a rate 3/5 coding scheme with 32 QAM and the third scheme combines a rates 3/6 Coding scheme with 64 QAM

6.1 Option 1 Rate 3/4 Turbo Code and 16 QAM

6.1.1 Coding

The coding used in this scheme is shown in FIG. 3. The two systematic recursive codes (SRC) used are identical and is defined in FIG. 4. The code is described by the generating polynomials 35o and 23o.

6.1.2 Puncturing

In accordance with an embodiment of the invention, in order to obtain a rate 3/4 code, the puncturing pattern used is given in Table 9.

TABLE 9
Puncturing and Mapping for Rate 3/4 16 QAM

| | | | | | | |
|---|---|---|---|---|---|---|
| Information bit (d) | d₁ | d₂ | d₃ | d₄ | d₅ | d₆ |
| parity bit (p) | — | p2 | — | — | — | — |
| parity bit (q) | — | — | — | — | q5 | — |

| | | |
|---|---|---|
| 4 AM symbol (I) | (d₁, d₂) | (d₄, d₅) |
| 4 AM symbol (Q) | (d₃, p2) | (d₆, q5) |
| 16 QAM symbol | (I, Q) = (d₁, d₂, d₃, p2) | (I, Q) = (d₄, d₅, d₆, q5) |
| (I, Q) | | |

6.1.3 Modulation

A 16 QAM scheme is shown in FIG. 13. It is assumed that at time k u₁^{k} and u₂^{k} modulates the I component and U₃^{k} and u₄^{k} modulates the Q component of a 16 QAM scheme.

In order to estimate the performance of this scheme, rate 3/4 turbo codes and 4 AM modulation are used.

For a rate 3/4 code and 16 QAM, the noise variance in each dimension is:

$${σ}_{N}^{2} = {{E}_{av} ( \frac{2 η {E}_{b}}{{N}_{0}} )}^{- 1} = 10 {{A}^{2} ( \frac{2 \times 3 \times {E}_{b}}{{N}_{0}} )}^{- 1} = \frac{10}{6} {{A}^{2} ( \frac{{E}_{b}}{{N}_{0}} )}^{- 1} \qquad ( 40 )$$

The puncturing and mapping scheme is shown in Table 9 for 6 consecutive information bits that are encoded into 8 coded bits, therefore two 16 QAM symbols.

For the 4 AM scheme as shown in FIG. 13, the noise variance is:

$${σ}_{N}^{2} = {E}_{av} ( \frac{2 η {E}_{b}}{{N}_{0}} ) = 10 {{A}^{2} ( \frac{2 \times 1.5 \times {E}_{b}}{{N}_{0}} )}^{- 1} = \frac{10}{3} {{A}^{2} ( \frac{{E}_{b}}{{N}_{0}} )}^{- 1} \qquad ( 41 )$$

6.1.4 Bit Probabilities

For each received symbol, the bit probabilities are computed as described in equations (36) to (39).

6.1.5 Simulation Results

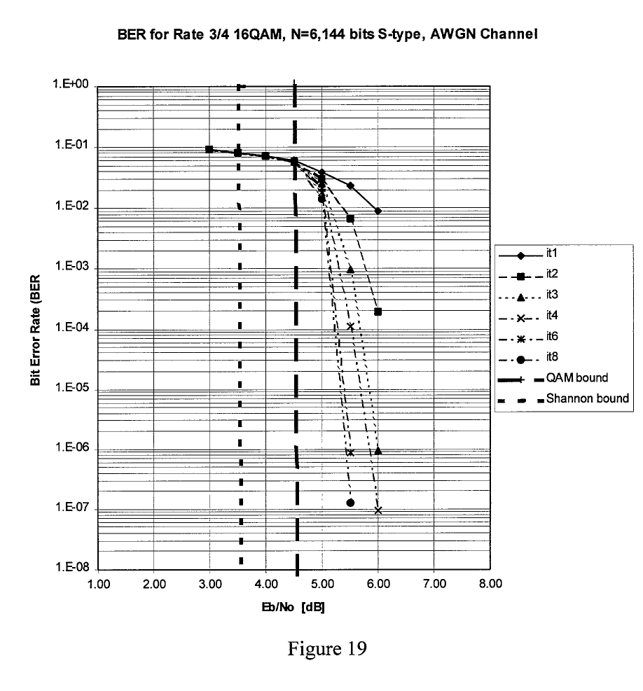

FIG. 19 shows the simulation results for 6,144 information bits with S-type interleaver.

A BER of 10⁻⁷ can be achieved after 8 iterations at E_{b}/N_{O}=5.55 dB for N =6,144 information bits.

6.2 Option 2 Rate 3/5 Turbo code and 32 QAM

6.2.1 Coding

The coding scheme is shown in FIG. 3. The two systematic recursive codes (SRC) used are identical and are defined in FIG. 4. The code is described by the generating polynomials 35o and 23o.

6.2.2 Puncturing

In accordance with an embodiment of the invention, in order to obtain a rate 3/5 code, the puncturing pattern used is given in Table 10.

TABLE 10
Puncturing and Mapping for Rate 3/5 32 QAM

| | | | | | | |
|---|---|---|---|---|---|---|
| Information bit | d₁ | d₂ | d₃ | d₄ | d₅ | d₆ |
| (d) | | | | | | |
| parity bit (p) | p1 | — | — | p4 | — | — |
| parity bit (q) | — | q2 | — | — | q5 | — |

| | | |
|---|---|---|
| 8 AM symbol | (d₁, d₃, p1) | (d₄, d₆, q5) |
| (I) | | |
| 4 AM symbol | (d₂, q2) | (d₅, p4) |
| (Q) | | |
| 32 QAM sym- | (I, Q) = (d₁, d₃, p1, d₂, q2) | (I, Q) = (d₄, d₆, q5, d₅, p4) |
| bol (I, Q) | | |

6.2.3 Modulation

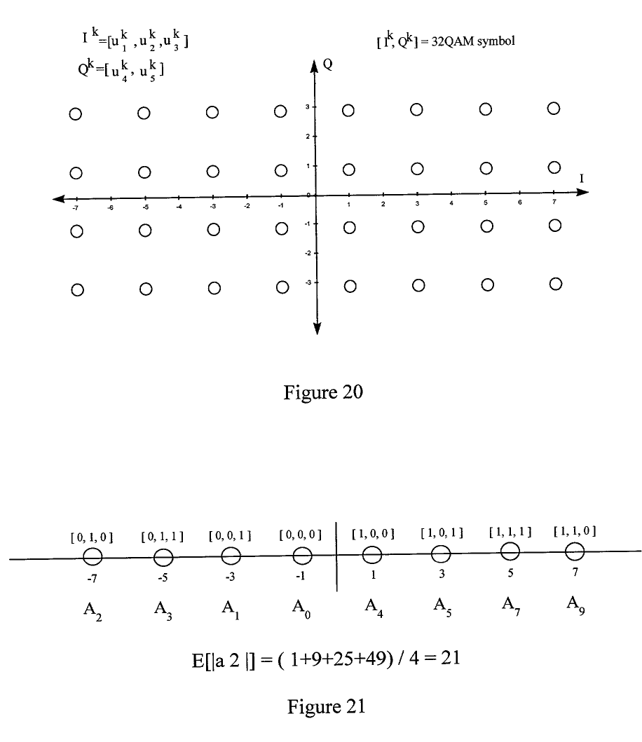

The asymmetrical 32 QAM modulation scheme considered is shown in FIG. 20. At time k, the symbol u^{k}=(u₁^{k}, u₂^{k}, u₃^{k}, u₄^{k}, u₅^{k}), is sent through the channel and the point r^{k} in two dimensional space is received.

It is assumed that at time k u₁^{k}, u₂^{k} and u₃^{k} modulates the I component and u₄^{k} and u₅^{k} modulates the Q component of the 32 QAM scheme.

In the I dimension, two information bits and one parity bit are transmitted using Gray mapping and 8 AM as shown in FIG. 21.

The Eₐᵥ_{_{—}}I is:

$$\begin{matrix}{E}_{av\_I} = \frac{( 1 + 9 + 25 + 49 ) {A}^{2}}{4} = 21 {A}^{2} & ( 42 ) \\ The {E}_{av\_Q} is \text{:} {E}_{av\_Q} = \frac{( 1 + 9 ) {A}^{2}}{2} = 5 {A}^{2} & ( 43 )\end{matrix}$$

Because the noise has to be spherical, the total value of Eₐᵥ will be the addition of these two values, so:

Eₐᵥ=Eₐᵥ_{_{—}}_{I}+Eₐᵥ_{_{—}}_{Q}=26 A² (44)

The value of the noise variance has to be the same in both dimensions and its value is:

$${σ}_{N}^{2} = {E}_{av} ( \frac{2 η {E}_{b}}{{N}_{0}} ) = 26 {{A}^{2} ( \frac{2 \times 3 \times {E}_{b}}{{N}_{0}} )}^{- 1} = \frac{26}{6} {{A}^{2} ( \frac{{E}_{b}}{{N}_{0}} )}^{- 1} \qquad ( 45 )$$

The puncturing and mapping scheme is shown in Table 10 for 6 consecutive information bits that are encoded into 10 coded bits, therefore two 32 QAM symbols.

6.2.4 Bit Probabilities

For an AWGN channel, the following expressions need to be evaluated for the I dimension:

$$\begin{matrix}\begin{matrix}LLR {(}_{{u}_{1}}^{k} ) = log ( \frac{{\sum }_{i = 1}^{4} exp [ - \frac{1}{2 {σ}_{N}^{2}} {( {I}^{k} - {a}_{1 , j}^{k} )}^{2} ]}{{\sum }_{i = 1}^{4} exp [ - \frac{1}{2 {σ}_{N}^{2}} {( {I}^{k} - {a}_{0 , j}^{k} )}^{2} ]} ) \\ = log ( \frac{\begin{matrix}exp [ - \frac{1}{2 {σ}_{N}^{2}} {( {I}^{k} - {A}_{4} )}^{2} ] + exp [ - \frac{1}{2 {σ}_{N}^{2}} {( {I}^{k} - {A}_{5} )}^{2} ] + \\ exp [ - \frac{1}{2 {σ}_{N}^{2}} {( {I}^{k} - {A}_{6} )}^{2} ] + exp [ - \frac{1}{2 {σ}_{N}^{2}} {( {I}^{k} - {A}_{7} )}^{2} ]\end{matrix}}{\begin{matrix}exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{1} )}^{2} ] + \\ exp [ - \frac{1}{2 {σ}_{N}^{2}} {( {I}^{k} - {A}_{2} )}^{2} ] + exp [ \frac{1}{2 {σ}_{N}^{2}} {( {I}^{k} - {A}_{3} )}^{2} ]\end{matrix}} )\end{matrix} & ( 46 ) \\ \begin{matrix}LLR {(}_{{u}_{2}}^{k} ) = log ( \frac{{\sum }_{i = 1}^{4} exp [ - \frac{1}{2 {σ}_{N}^{2}} {( {I}^{k} - {a}_{1 , j}^{k} )}^{2} ]}{{\sum }_{i = 1}^{4} exp [ - \frac{1}{2 {σ}_{N}^{2}} {( {I}^{k} - {a}_{0 , j}^{k} )}^{2} ]} ) \\ = log ( \frac{\begin{matrix}exp [ - \frac{1}{2 {σ}_{N}^{2}} {( {I}^{k} - {A}_{2} )}^{2} ] + exp [ - \frac{1}{2 {σ}_{N}^{2}} {( {I}^{k} - {A}_{3} )}^{2} ] + \\ exp [ - \frac{1}{2 {σ}_{N}^{2}} {( {I}^{k} - {A}_{6} )}^{2} ] + exp [ - \frac{1}{2 {σ}_{N}^{2}} {( {I}^{k} - {A}_{7} )}^{2} ]\end{matrix}}{\begin{matrix}exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{1} )}^{2} ] + \\ exp [ - \frac{1}{2 {σ}_{N}^{2}} {( {I}^{k} - {A}_{4} )}^{2} ] + exp [ \frac{1}{2 {σ}_{N}^{2}} {( {I}^{k} - {A}_{5} )}^{2} ]\end{matrix}} )\end{matrix} & ( 47 ) \\ \begin{matrix}LLR {(}_{{u}_{3}}^{k} ) = log ( \frac{{\sum }_{i = 1}^{4} exp [ - \frac{1}{2 {σ}_{N}^{2}} {( {I}^{k} - {a}_{1 , j}^{k} )}^{2} ]}{{\sum }_{i = 1}^{4} exp [ - \frac{1}{2 {σ}_{N}^{2}} {( {I}^{k} - {a}_{0 , j}^{k} )}^{2} ]} ) \\ = log ( \frac{\begin{matrix}exp [ - \frac{1}{2 {σ}_{N}^{2}} {( {I}^{k} - {A}_{1} )}^{2} ] + exp [ - \frac{1}{2 {σ}_{N}^{2}} {( {I}^{k} - {A}_{5} )}^{2} ] + \\ exp [ - \frac{1}{2 {σ}_{N}^{2}} {( {I}^{k} - {A}_{3} )}^{2} ] + exp [ - \frac{1}{2 {σ}_{n}^{2}} {( {I}^{k} - {A}_{7} )}^{2} ]\end{matrix}}{\begin{matrix}exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{4} )}^{2} ] + \\ exp [ - \frac{1}{2 {σ}_{N}^{2}} {( {I}^{k} - {A}_{2} )}^{2} ] + exp [ \frac{1}{2 {σ}_{N}^{2}} {( {I}^{k} - {A}_{6} )}^{2} ]\end{matrix}} )\end{matrix} & ( 48 )\end{matrix}$$

For the Q dimension, only LLR(u₄^{k}) and LLR(u₅^{k}) are required to be evaluated:

$$\begin{matrix}\begin{matrix}LLR {(}_{{u}_{4}}^{k} ) = log ( \frac{{\sum }_{i = 1}^{2} exp [ - \frac{1}{2 {σ}_{N}^{2}} {( {I}^{k} - {a}_{1 , j}^{k} )}^{2} ]}{{\sum }_{i = 1}^{2} exp [ - \frac{1}{2 {σ}_{N}^{2}} {( {I}^{k} - {a}_{0 , j}^{k} )}^{2} ]} ) \\ = log ( \frac{exp [ - \frac{1}{2 {σ}_{N}^{2}} {( {I}^{k} - {A}_{2} )}^{2} ] + exp [ - \frac{1}{2 {σ}_{N}^{2}} {( {I}^{k} - {A}_{3} )}^{2} ]}{exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{1} )}^{2} ]} )\end{matrix} & ( 49 ) \\ \begin{matrix}LLR {(}_{{u}_{5}}^{k} ) = log ( \frac{{\sum }_{i = 1}^{2} exp [ - \frac{1}{2 {σ}_{N}^{2}} {( {I}^{k} - {a}_{1 , j}^{k} )}^{2} ]}{{\sum }_{i = 1}^{2} exp [ - \frac{1}{2 {σ}_{N}^{2}} {( {I}^{k} - {a}_{0 , j}^{k} )}^{2} ]} ) \\ = log ( \frac{exp [ - \frac{1}{2 {σ}_{N}^{2}} {( {I}^{k} - {A}_{1} )}^{2} ] + exp [ - \frac{1}{2 {σ}_{N}^{2}} {( {I}^{k} - {A}_{3} )}^{2} ]}{exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{2} )}^{2} ]} )\end{matrix} & ( 50 )\end{matrix}$$

6.2.5 Simulation Results

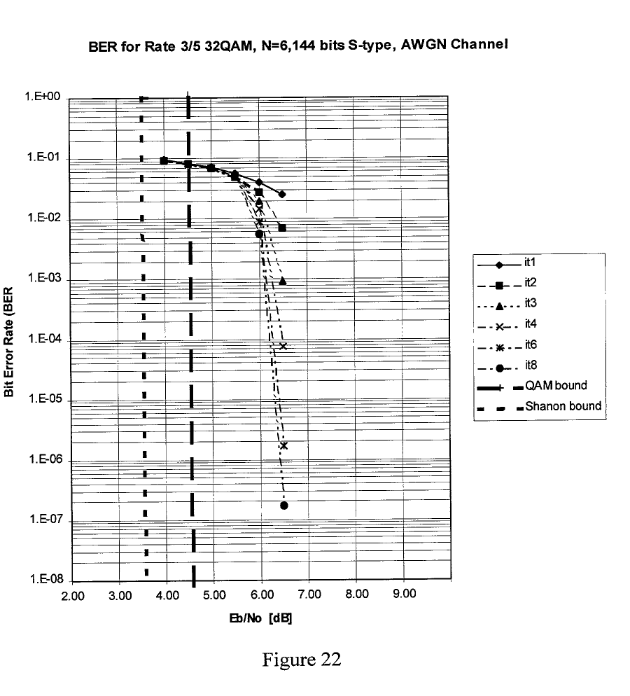

FIG. 22 shows the simulation results for 6,144 information bits with S-type interleaver.

A BER of 10⁻⁶ can be achieved after 8 iterations at E_{b}/N_{O}=6.5 dB for N=4,096 information bits

6.3 Option 2 Rate 3/6 Turbo code and 64 QAM

6.3 .1 Coding

The coding scheme is shown in FIG. 3. The two systematic recursive codes (SRC) used are identical and are defined in FIG. 4. The code is described by the generating polynomials 35o and 23o.

6.3.2 Puncturing

In order to obtain a rate 3/6 code, the puncturing pattern used is given in Table 11. This is the traditional puncturing pattern using alternating parity bits in each cycle.

TABLE 11
Puncturing and Mapping for Rate 3/6 64 QAM

| | | | | | | |
|---|---|---|---|---|---|---|
| Information bit (d) | d₁ | d₂ | d₃ | d₄ | d₅ | d₆ |
| parity bit (p) | p1 | — | p3 | — | p5 | — |
| parity bit (q) | — | q2 | — | q4 | — | q6 |

| | | |
|---|---|---|
| 8 AM symbol (I) | (d₁, d₂, p1) | (d₄, d₅, q4) |
| 8 AM symbol (Q) | (d₃, p3, q2) | (d₆, p5, q6) |
| 64 QAM symbol (I, Q) | (I, Q) = | (I, Q) = |
| | (d₁, d₂, p1, d₃, p3, q2) | (d₄, d₅, q4, d₆, p5, q6) |

6.3.3 Modulation

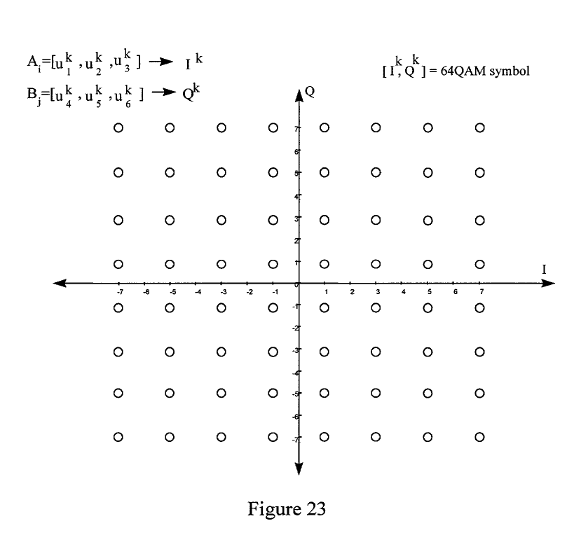

Let us consider 64 QAM modulation scheme as it is shown in FIG. 23. At time k, the symbol u^{k}=(u₁^{k}, u₂^{k}, u₃^{k}, u₄^{k}, u₅^{k}, u₆^{k}), is sent through the channel and the point r^{k} in two dimensional space is received.

It is assumed that at time k u₁^{k}, u₂^{k} and u₃^{k} modulates the I component and u₄^{k}, u₅^{k} and u₆^{k} modulates the Q component of a 64 QAM scheme.

For 64 QAM constellations with points at −7A, −5A, −3A, −A, A, 3A, 5A, 7A The Eₐᵥ is:

Eₐᵥ=(8(49+25+9+1)+8(25+49+49+9+49+1)+8(25+9+25+1) +8(9+1))A²/64=42 A² (51)

For a rate 3/6 code and 64 QAM, the noise variance in each dimension is:

$${σ}_{N}^{2} = {{E}_{av} ( \frac{2 η {E}_{b}}{{N}_{0}} )}^{- 1} = 42 {{A}^{2} ( \frac{2 \times 3 \times {E}_{b}}{{N}_{0}} )}^{- 1} = 7 {{A}^{2} ( \frac{{E}_{b}}{{N}_{0}} )}^{- 1} \qquad ( 52 )$$

In order to estimate the performance of this scheme, when rate 3/6 turbo codes and 8 AM modulation is used, as shown in FIG. 21.

The 64 QAM scheme will achieve a similar performance in terms of bit error rate (BER) at twice the spectral efficiency, assuming an ideal modulator.

For the 8 AM scheme shown in FIG. 21, the noise variance is

$${σ}_{N}^{2} = E [ \vert {a}_{k}^{2} \vert ] {( \frac{2 η {E}_{b}}{{N}_{0}} )}^{- 1} = 21 {{A}^{2} ( \frac{2 \times 1.5 \times {E}_{b}}{{N}_{0}} )}^{- 1} = 7 {{A}^{2} ( \frac{{E}_{b}}{{N}_{0}} )}^{- 1} \qquad ( 53 )$$

This is identical to the variance for the 64 QAM scheme.

The puncturing and mapping scheme is shown in Table 11 for 6 consecutive information bits that are encoded into 12 coded bits, therefore two 64 QAM symbols.

6.3.4 Bit Probabilities

For an AWGN channel, the following expressions need to be evaluated for the I dimension:

$$\begin{matrix}\begin{matrix}LLR {(}_{{u}_{1}}^{k} ) = log ( \frac{{\sum }_{i = 1}^{4} exp [ - \frac{1}{2 {σ}_{N}^{2}} {( {I}^{k} - {a}_{1 , j}^{k} )}^{2} ]}{{\sum }_{i = 1}^{4} exp [ - \frac{1}{2 {σ}_{N}^{2}} {( {I}^{k} - {a}_{0 , j}^{k} )}^{2} ]} ) \\ = log ( \frac{\begin{matrix}exp [ - \frac{1}{2 {σ}_{N}^{2}} {( {I}^{k} - {A}_{4} )}^{2} ] + exp [ - \frac{1}{2 {σ}_{N}^{2}} {( {I}^{k} - {A}_{5} )}^{2} ] + \\ exp [ - \frac{1}{2 {σ}_{N}^{2}} {( {I}^{k} - {A}_{6} )}^{2} ] + exp [ - \frac{1}{2 {σ}_{N}^{2}} {( {I}^{k} - {A}_{7} )}^{2} ]\end{matrix}}{\begin{matrix}exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{1} )}^{2} ] + \\ exp [ - \frac{1}{2 {σ}_{N}^{2}} {( {I}^{k} - {A}_{2} )}^{2} ] + exp [ \frac{1}{2 {σ}_{N}^{2}} {( {I}^{k} - {A}_{3} )}^{2} ]\end{matrix}} )\end{matrix} & ( 54 ) \\ \begin{matrix}LLR {(}_{{u}_{2}}^{k} ) = log ( \frac{{\sum }_{i = 1}^{4} exp [ - \frac{1}{2 {σ}_{N}^{2}} {( {I}^{k} - {a}_{1 , j}^{k} )}^{2} ]}{{\sum }_{i = 1}^{4} exp [ - \frac{1}{2 {σ}_{N}^{2}} {( {I}^{k} - {a}_{0 , j}^{k} )}^{2} ]} ) \\ = log ( \frac{\begin{matrix}exp [ - \frac{1}{2 {σ}_{N}^{2}} {( {I}^{k} - {A}_{2} )}^{2} ] + exp [ - \frac{1}{2 {σ}_{N}^{2}} {( {I}^{k} - {A}_{3} )}^{2} ] + \\ exp [ - \frac{1}{2 {σ}_{N}^{2}} {( {I}^{k} - {A}_{6} )}^{2} ] + exp [ - \frac{1}{2 {σ}_{N}^{2}} {( {I}^{k} - {A}_{7} )}^{2} ]\end{matrix}}{\begin{matrix}exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{1} )}^{2} ] + \\ exp [ - \frac{1}{2 {σ}_{N}^{2}} {( {I}^{k} - {A}_{4} )}^{2} ] + exp [ \frac{1}{2 {σ}_{N}^{2}} {( {I}^{k} - {A}_{5} )}^{2} ]\end{matrix}} )\end{matrix} & ( 55 ) \\ \begin{matrix}LLR {(}_{{u}_{3}}^{k} ) = log ( \frac{{\sum }_{i = 1}^{4} exp [ - \frac{1}{2 {σ}_{N}^{2}} {( {I}^{k} - {a}_{1 , j}^{k} )}^{2} ]}{{\sum }_{i = 1}^{4} exp [ - \frac{1}{2 {σ}_{N}^{2}} {( {I}^{k} - {a}_{0 , j}^{k} )}^{2} ]} ) \\ = log ( \frac{\begin{matrix}exp [ - \frac{1}{2 {σ}_{N}^{2}} {( {I}^{k} - {A}_{1} )}^{2} ] + exp [ - \frac{1}{2 {σ}_{N}^{2}} {( {I}^{k} - {A}_{5} )}^{2} ] + \\ exp [ - \frac{1}{2 {σ}_{N}^{2}} {( {I}^{k} - {A}_{3} )}^{2} ] + exp [ - \frac{1}{2 {σ}_{N}^{2}} {( {I}^{k} - {A}_{7} )}^{2} ]\end{matrix}}{\begin{matrix}exp [ - \frac{1}{2 {σ}_{N}^{2}} {( {I}^{k} - {A}_{0} )}^{2} ] + exp [ - \frac{1}{2 {σ}_{N}^{2}} {( {I}^{k} - {A}_{4} )}^{2} ] + \\ exp [ - \frac{1}{2 {σ}_{N}^{2}} {( {I}^{k} - {A}_{2} )}^{2} ] + exp [ \frac{1}{2 {σ}_{N}^{2}} {( {I}^{k} - {A}_{6} )}^{2} ]\end{matrix}} )\end{matrix} & ( 56 )\end{matrix}$$

An identical computation effort is required for the Q dimension the I^{k} being replaced with the Q^{k} demodulated value in order to evaluate LLR(u₄^{k}), LLR(u₅^{k}) and LLR(u₆^{k}).

6.3.5 Simulation Results

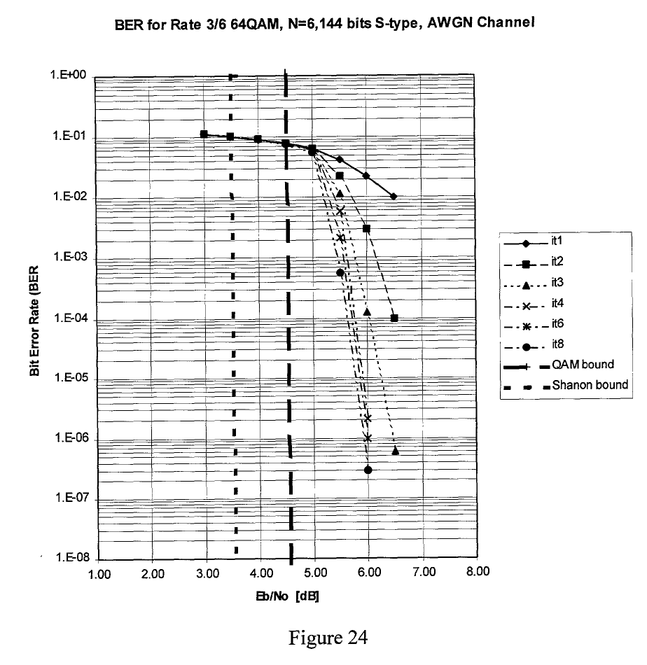

FIG. 24 shows the simulation results for 6,144 information bits with S-type interleaver. A BER of 10⁻⁷ can be achieved after 8 iterations at E_{b}/N_{O}=6.1 dB for N=4,096 information bits. This result is 0.3 dB worse than the performance of the rate 3/4 16 QAM scheme.

6.4 Recommended Solution

Comparing FIGS. 19, 22 and 24, the recommended solution for 3 bits/Hz spectral efficiency is the rate 3/4 turbo code 16 QAM Scheme.

This scheme achieves a target BER of 10⁻⁷ at E_{b}/N_{O}=5.8 dB for N=6,144 information bits.

7. Coding and Modulation for 4 bit/s/Hz Spectral Efficiency

This section investigated four schemes for transmission of 4 information bits in a 64 QAM symbol. The mapping used for 64 QAM constellation has a very significant impact on the performance of these schemes. The first scheme uses independent I and Q mapping, and also uses Gray mapping in each dimension. The second scheme uses independent I and Q mapping, but natural mapping in each dimension. The third scheme used a conventional trellis coded modulation approach based on Ungerboeck set partitioning of the 64 QAM set. This partitioning technique splits the constellation in sub-constellations with increased Euclidian distance. In these schemes all the information bits are coded. The fourth scheme used the same conventional trellis coded modulation approach based on Ungerboeck set partitioning of the 64 QAM set. However, only two information bits are encoded by a rate 1/2 code. The four coded bits select a sub-partition of four points. The other two information bits, which are sent uncoded, identify the transmitted point.

7.1 Option 1 —Rate 4/6 64 QAM with independent I and Q and with Gray Mapping

7.1.1 Coding

The coding scheme is shown in FIG. 3. The two systematic recursive codes (SRC) used are identical and are defined in FIG. 4. The code is described by the generating polynomials 35o and 23o.

7.1.2 Puncturing

In accordance with an embodiment of the invention, in order to obtain a rate 4/6 code, the puncturing pattern used is shown in Table 12.

TABLE 12
Puncturing and Mapping for Rate 4/6 64 QAM Option 1

| | | | | |
|---|---|---|---|---|
| Information bit (d) | d₁ | d₂ | d₃ | d₄ |
| parity bit (p) | p1 | — | — | — |
| parity bit (q) | — | — | q3 | — |

| | |
|---|---|
| 8 AM symbol (I) | (d₁, d₂, p1) |
| 8 AM symbol (Q) | (d₃, d₄, q3) |
| 64 QAM symbol (I, Q) | (I, Q) = (d₁, d₂, p1, d₃, d₄, q3) |

7.1.3 Modulation

A 64 QAM scheme is shown in FIG. 23. Gray mapping was used in each dimension as shown in FIG. 21.

Four information bits are required to be sent using a 64 QAM constellation.

For a rate 4/6 code and 64 QAM, the noise variance in each dimension is

For a rate 4/6 code and 64 QAM, the noise variance in each dimension is

$${σ}_{N}^{2} = {{E}_{av} ( \frac{2 η {E}_{b}}{{N}_{0}} )}^{- 1} = 42 {{A}^{2} ( \frac{2 \times 4 \times {E}_{b}}{{N}_{0}} )}^{- 1} = 5.25 {{A}^{2} ( \frac{{E}_{b}}{{N}_{0}} )}^{- 1} \qquad ( 57 )$$

Gray mapping was used in each dimension as shown in FIG. 21.

The puncturing and mapping scheme is shown in Table 12 for 4 consecutive information bits that are encoded into 6 coded bits, therefore one 64 QAM symbol.

The turbo encoder with the puncturing presented in Table 12 is a rate 4/6 turbo code which in conjunction with 64 QAM gives a spectral efficiency of 4 bits/s/Hz.

Considering two independent Gaussian noises with identical variance σ²_{N}, the LLR can be determined independently for each I and Q.

It is assumed that at time u₁^{k}, u₂^{k} and u₃^{k} modulates the I component and u₄^{k}, u₅^{k} and u₆^{k} modulates the Q component of the 64 QAM scheme.

At the receiver, the I and Q signals are treated independently in order to take advantage of the simpler formulae for the LLR values.

7.1.4 Bit Probabilities

From each received symbol, the bit probabilities are computed as described in equations (46) (47) and (48) for I dimension. An identical computation effort is required for the Q dimension, the I^{k} being replaced with the Q^{k} demodulated value in order to evaluate LLR(u₄^{k}), LLR(u₅^{k}) and LLR(u₆^{k}).

7.1.5 Simulation Results

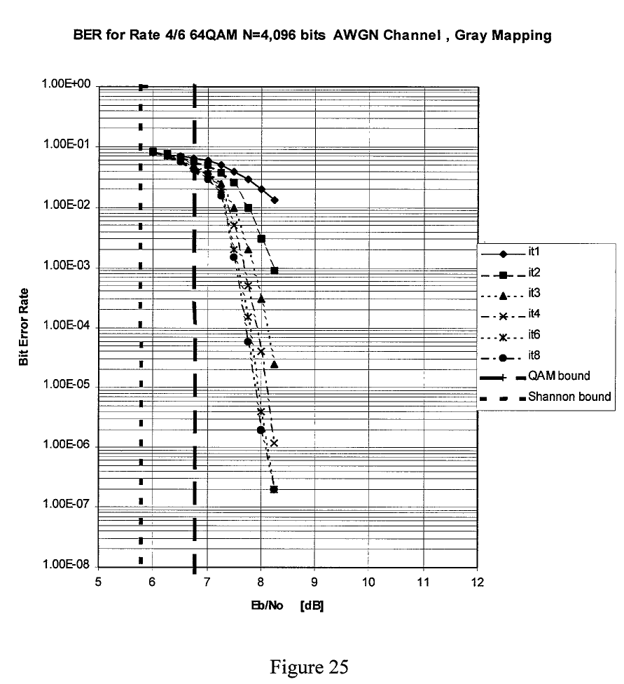

FIG. 25 shows the simulation results for 4,096 information bits with S-type interleaver.

A search for the best S-type interleaver was performed. For each interleaver size, the maximum S-factor was found and four different interleavers were generated using a random seed. Four simulations were generated for a target BER of 10⁻⁵. The best result decided the preferred interleaver. Using the preferred interleaver, complete simulations were started for BERs down to 10⁻⁷.

A BER of 10⁻⁷ can be achieved after 8 iterations at E_{b}/N_{O}=8.3 dB.

7.2 Option 2 —Rate 4/6 64 QAM with independent I and Q and Natural Mapping

7.2.1 Coding

The proposed coding scheme is shown in FIG. 3. The two systematic recursive codes (SRC) used are identical and are defined in FIG. 4. The code is described by the generating polynomials 35o and 23o.

7.2.2 Puncturing

In accordance with an embodiment of the invention, in order to obtain a rate 4/6 code, the puncturing pattern used is shown in Table 13.

TABLE 13
Puncturing and Mapping for Rate 4/6 64 QAM Option 2

| | | | | |
|---|---|---|---|---|
| Information bit (d) | d₁ | d₂ | d₃ | d₄ |
| parity bit (p) | p1 | — | — | — |
| parity bit (q) | — | — | q3 | — |

| | |
|---|---|
| 8 AM symbol (I) | (d₁, d₂, p1) |
| 8 AM symbol (Q) | (d₃, d₄, q3) |
| 64 QAM symbol (I, Q) | (I, Q) = (d₁, d₂, p1, d₃, d₄, q3) |

7.2.3 Modulation

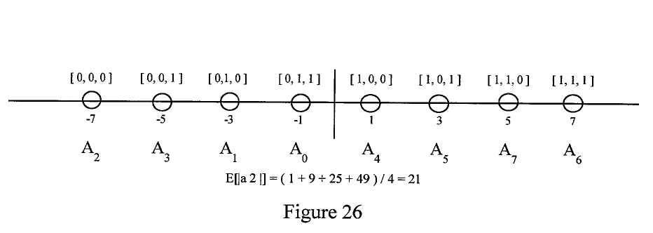

A 64 QAM scheme is shown in FIG. 23. Natural mapping was used in each dimension as shown in FIG. 26. Four information bits are required to be sent using a 64 QAM constellation. This is equivalent to a rate 2/3 coding scheme.

For a rate 4/6 code and 64 QAM, the noise variance in each dimension is

$${σ}_{N}^{2} = {{E}_{av} ( \frac{2 η {E}_{b}}{{N}_{0}} )}^{- 1} = 42 {{A}^{2} ( \frac{2 \times 4 \times {E}_{b}}{{N}_{0}} )}^{- 1} = 5.25 {{A}^{2} ( \frac{{E}_{b}}{{N}_{0}} )}^{- 1} \qquad ( 58 )$$

Gray mapping is used in each dimension as shown in FIG. 21.

The puncturing and mapping scheme is shown in Table 13 for 4 consecutive information bits that are encoded into 6 coded bits, therefore one 64 QAM symbol.

The turbo encoder with the puncturing presented in Table 13 is a rate 4/6 turbo code which in conjunction with 64 QAM gives a spectral efficiency of 4 bits/s/Hz.

Considering two independent Gaussian noises with identical variance σ²_{N}, the LLR can be determined independently for each I and Q.

It is assumed that at time k u₁^{k}, u₂^{k}, and u₃^{k} modulates the I component and u₄^{k}, u₅^{k} and u₆^{k} modulates the Q component of the 64 QAM scheme.

At the receiver, the I and Q signals are treated independently in order to take advantage of the simpler formulae for the LLR values.

7.2.4 Bit Probabilities

From each received symbol, the bit probabilities are computed as described in equations (46) (47) and (48) for I dimension. An identical computation effort is required for the Q dimension, the I^{k} being replaced with the Q^{k} demodulated value in order to evaluate LLR(u₄^{k}), LLR(u₅^{k}) and LLR(u₆^{k}).

7.2.5 Simulation Results

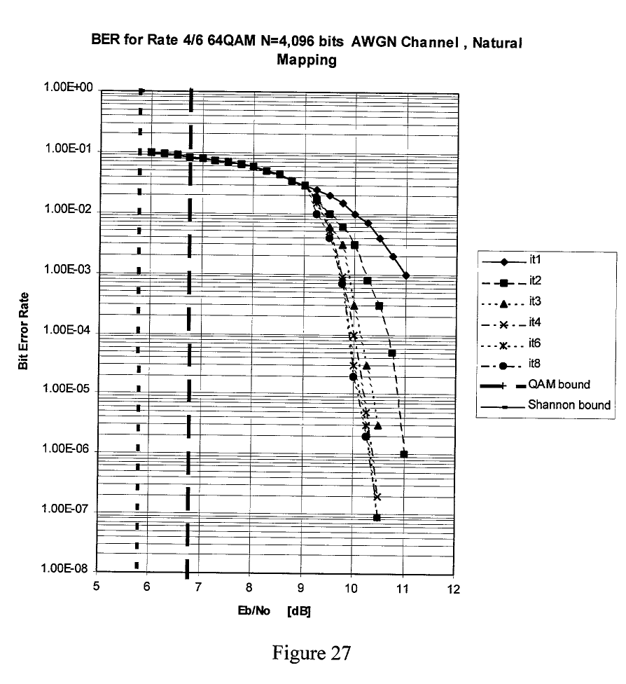

FIG. 27 shows the simulation results for 4,096 information bits with S-type interleaver.

A search for the best S-type interleaver was performed. For each interleaver size, the maximum S-factor was found and four different interlevers were generated using a random seed. Four simulations were generated for a target BER of 10⁻⁵. The best result decided the preferred interleaver. Using the preferred interleaver, complete simulations were started for BERs down to 10⁻⁷.

A BER of 10⁻⁷ can be achieved after 8 iterations at E_{b}/N_{O}=10.5 dB.

7.3 Option 3 —Trellis Coded Modulation with 4 bits Coded

7.3.1 Coding

In this scheme, all four information bits are coded by a rate 4/6 code. Only two parity bits are transmitted. The six bits produced select a point in the 64 QAM constellation. The coding scheme is shown in FIG. 3. The two systematic recursive codes (SRC) used are identical and are defined in FIG. 4. The code is described by the generating polynomials 35o and 23o.

7.3.2 Puncturing

In accordance with an embodiment of the invention, in order to obtain a rate 2/3 code, the puncturing pattern used is shown in Table 14.

TABLE 14
Puncturing and Mapping for Rate 4/6 64 QAM Option 3

| | | | | |
|---|---|---|---|---|
| Information bit (d) | d₁ | d₂ | d₃ | d₄ |
| parity bit (p) p1 | — | — | — | |
| parity bit (q) | — | — | q3 | — |

| | |
|---|---|
| 64 QAM symbol (I, Q) | (I, Q) = (d₁, d₂, d₃, d₄, p1, q3) |

7.3.3 Modulation

A trellis coded modulation scheme is employed. The six bits divide the 64 QAM constellation based on increased Euclidean distance.

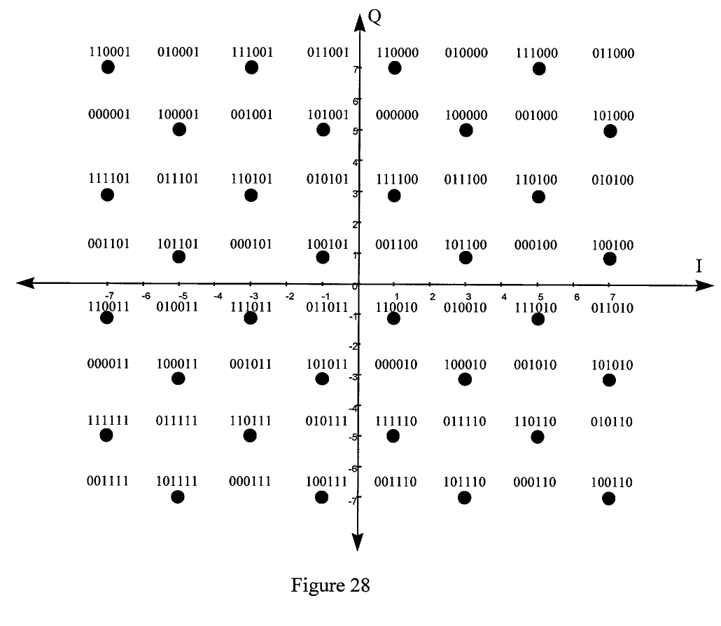

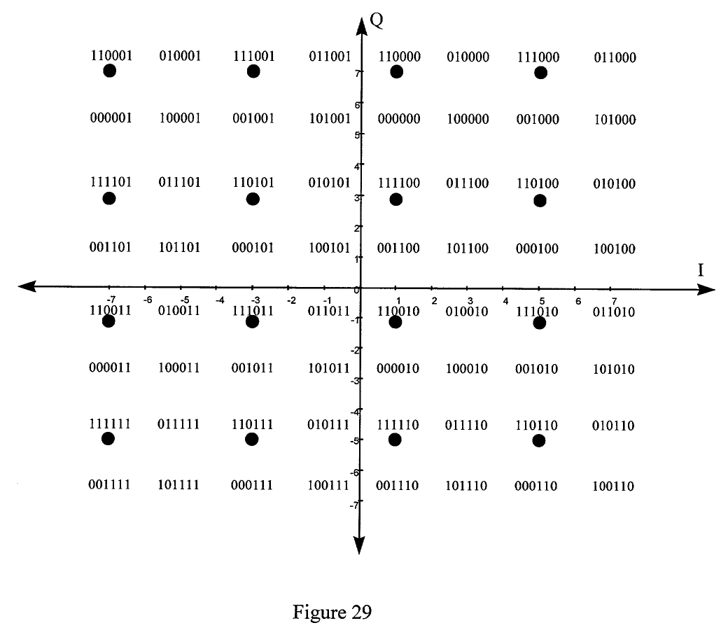

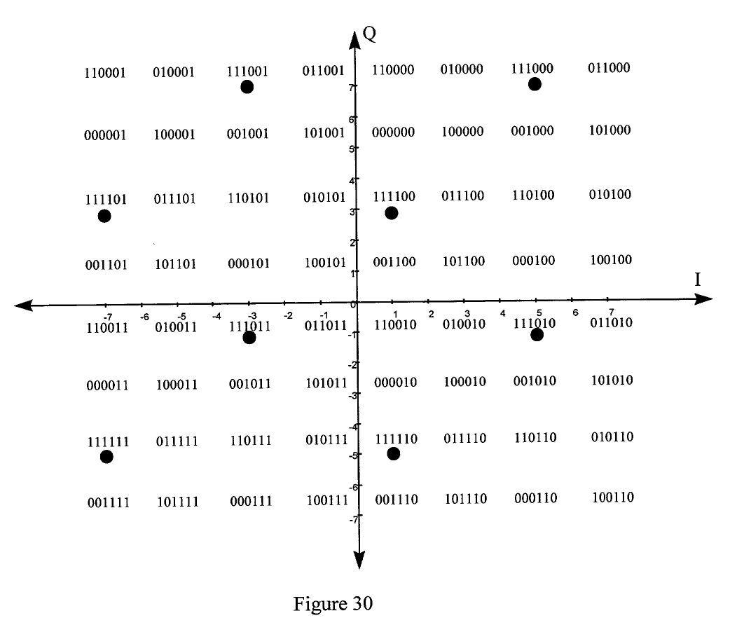

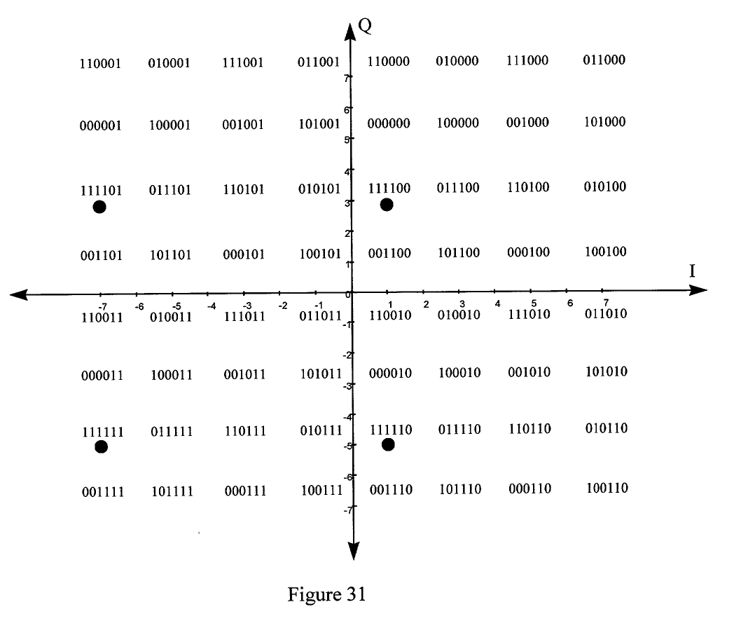

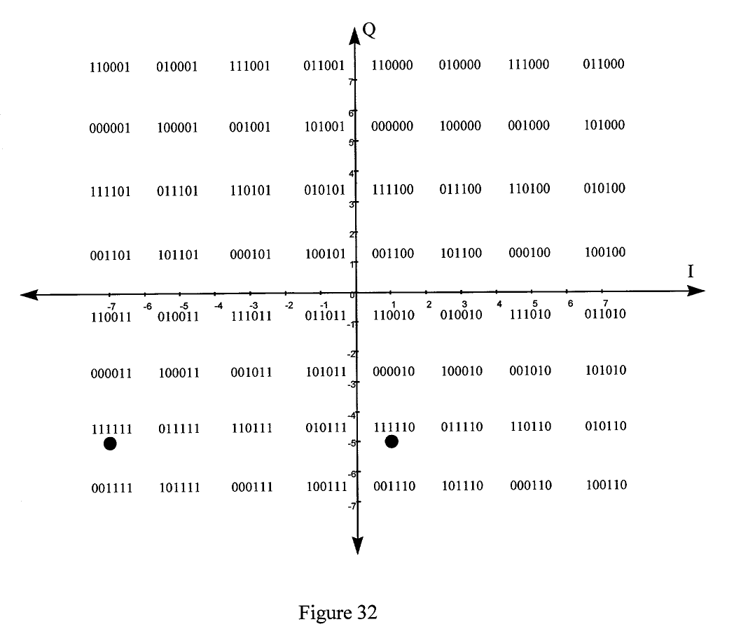

The 64QM constellation is partitioned in subsets as shown in FIGS. 28 to 32.

The puncturing and mapping scheme is shown in Table 14 for 4 consecutive information bits that are encoded into 6 coded bits, therefore one 64 QAM symbol.

7.3.4 Bit Probabilities

For an AWGN channel, the following expressions need to be evaluated for each received symbol before the turbo decoding process can start.

$$\begin{matrix}LLR {(}_{{u}_{1}}^{k} ) = log ( \frac{{\sum }_{{u}_{1}^{k} = 1} exp ( - \frac{1}{2 {σ}_{N}^{2}} ‖ {R}^{k} - {P}_{i} ‖ )}{{\sum }_{{u}_{1}^{k} = 0} exp ( - \frac{1}{2 {σ}_{N}^{2}} ‖ {R}^{k} - {P}_{j} ‖ )} ) & ( 59 ) \\ LLR {(}_{{u}_{2}}^{k} ) = log ( \frac{{\sum }_{{u}_{2}^{k} = 1} exp ( - \frac{1}{2 {σ}_{N}^{2}} ‖ {R}^{k} - {P}_{i} ‖ )}{{\sum }_{{u}_{2}^{k} = 0} exp ( - \frac{1}{2 {σ}_{N}^{2}} ‖ {R}^{k} - {P}_{j} ‖ )} ) & ( 60 ) \\ LLR {(}_{{u}_{3}}^{k} ) = log ( \frac{{\sum }_{{u}_{3}^{k} = 1} exp ( - \frac{1}{2 {σ}_{N}^{2}} ‖ {R}^{k} - {P}_{i} ‖ )}{{\sum }_{{u}_{3}^{k} = 0} exp ( - \frac{1}{2 {σ}_{N}^{2}} ‖ {R}^{k} - {P}_{j} ‖ )} ) & ( 61 ) \\ LLR {(}_{{u}_{4}}^{k} ) = log ( \frac{{\sum }_{{u}_{4}^{k} = 1} exp ( - \frac{1}{2 {σ}_{N}^{2}} ‖ {R}^{k} - {P}_{i} ‖ )}{{\sum }_{{u}_{4}^{k} = 0} exp ( - \frac{1}{2 {σ}_{N}^{2}} ‖ {R}^{k} - {P}_{j} ‖ )} ) & ( 62 ) \\ LLR {(}_{{u}_{5}}^{k} ) = log ( \frac{{\sum }_{{u}_{5}^{k} = 1} exp ( - \frac{1}{2 {σ}_{N}^{2}} ‖ {R}^{k} - {P}_{i} ‖ )}{{\sum }_{{u}_{5}^{k} = 0} exp ( - \frac{1}{2 {σ}_{N}^{2}} ‖ {R}^{k} - {P}_{j} ‖ )} ) & ( 63 ) \\ LLR {(}_{{u}_{6}}^{k} ) = log ( \frac{{\sum }_{{u}_{6}^{k} = 1} exp ( - \frac{1}{2 {σ}_{N}^{2}} ‖ {R}^{k} - {P}_{i} ‖ )}{{\sum }_{{u}_{6}^{k} = 0} exp ( - \frac{1}{2 {σ}_{N}^{2}} ‖ {R}^{k} - {P}_{j} ‖ )} ) & ( 51 )\end{matrix}$$

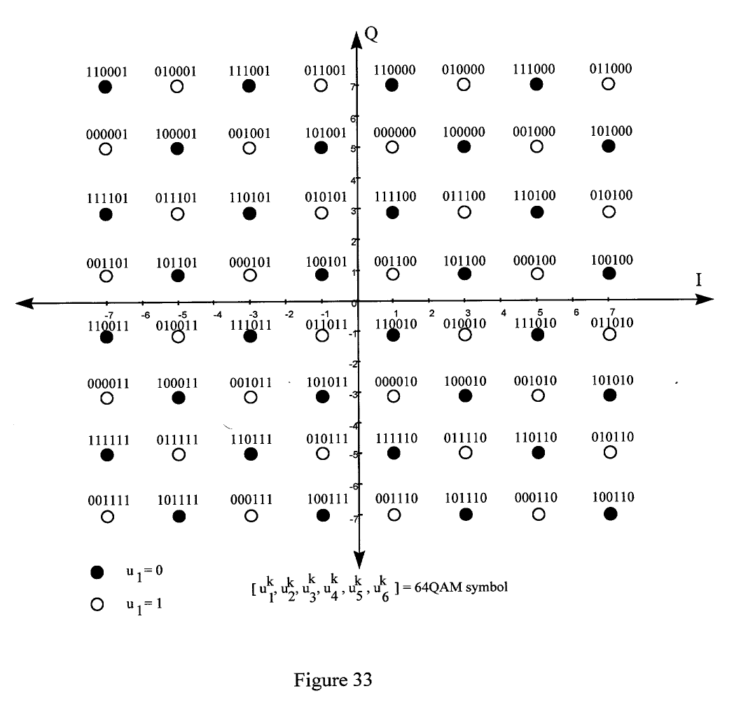

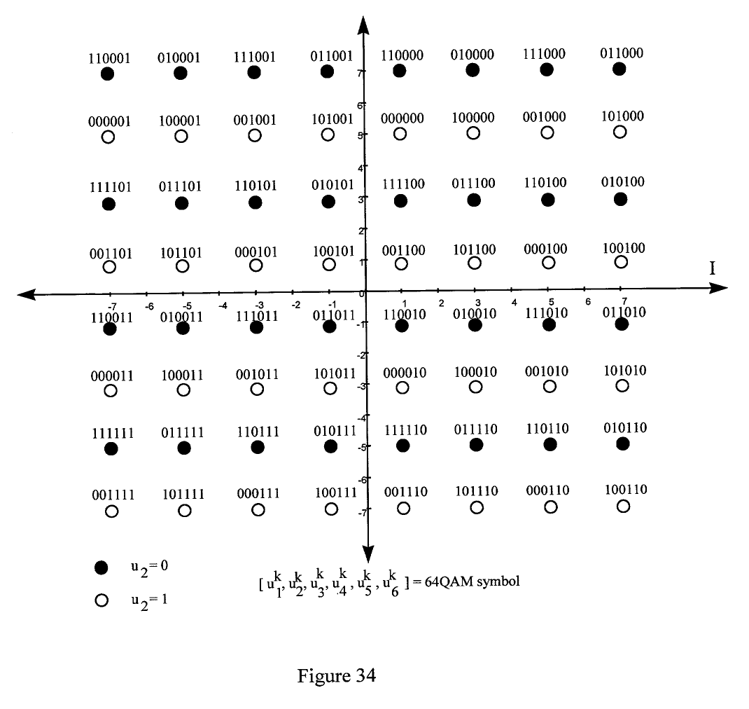

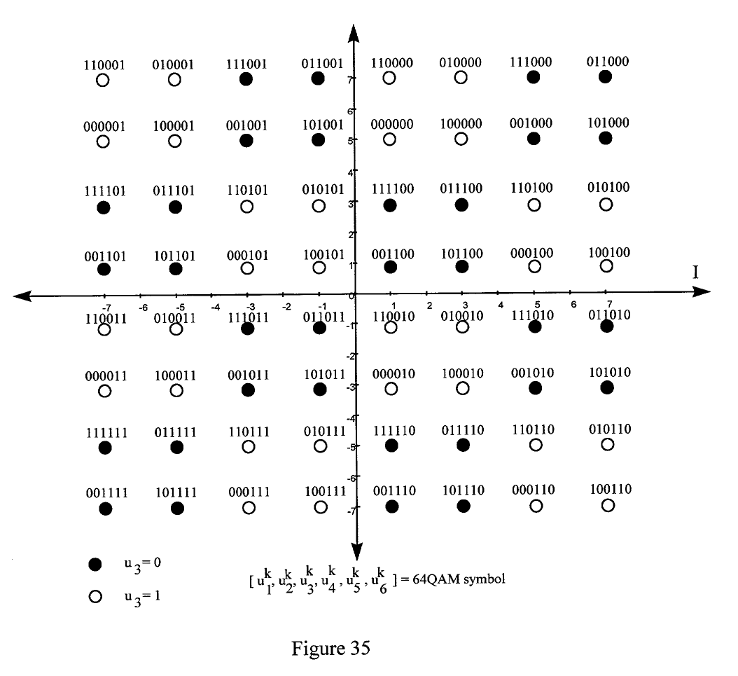

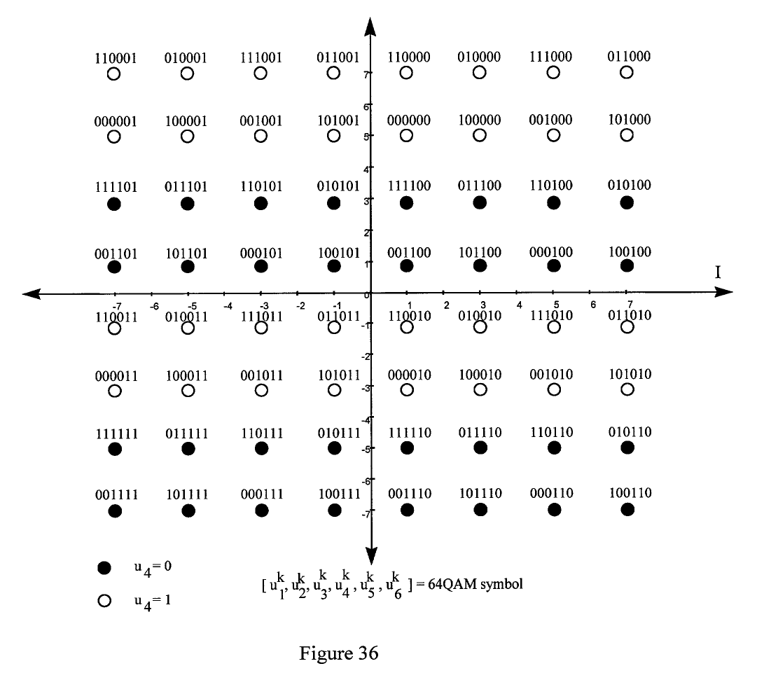

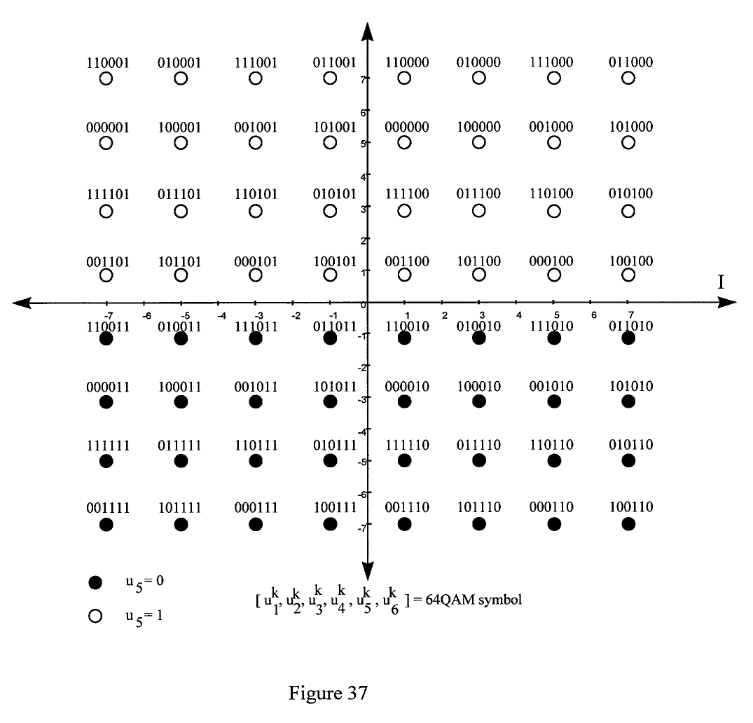

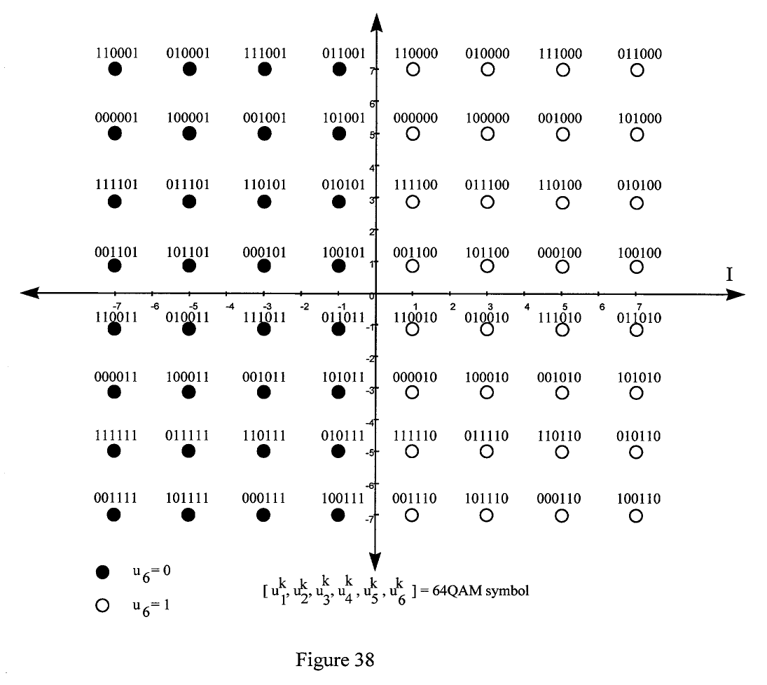

The ∥R^{k}-Pᵢ∥ represents the squared Euclidian distance between the received point R^{k} at the time k and a constellation point Pᵢ. The actual set in which uᵢ is 0 or 1 are shown in FIGS. 33-38.

7.3.5 Simulation Results

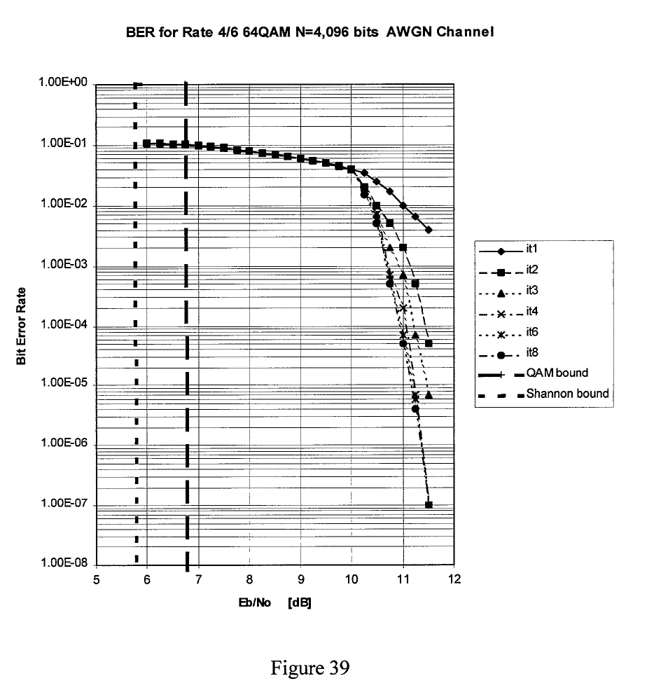

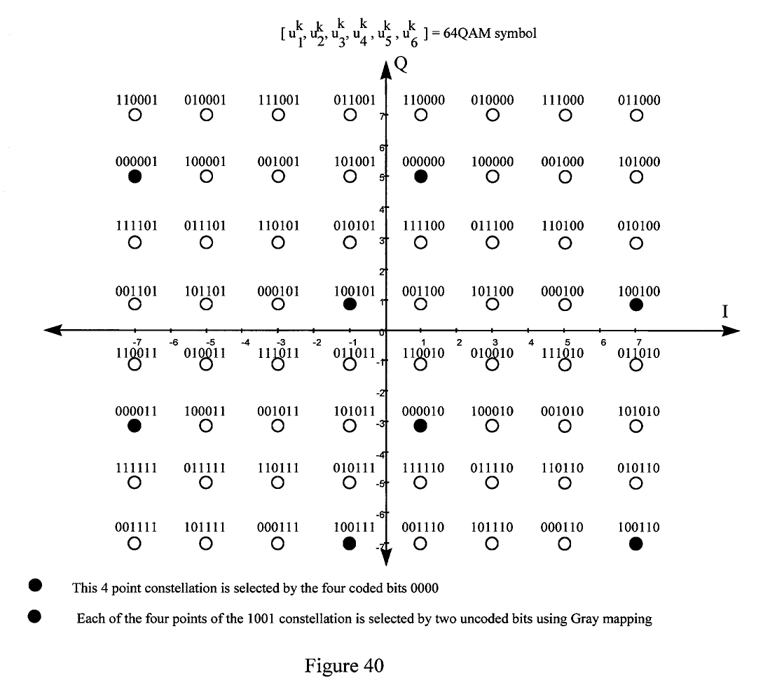

This scheme required much higher computational effort than previous options and would be difficult to implement in hardware. FIG. 39 shows the simulation results for 4,096 information bits using S-type interleaver.

A BER of 10⁻⁷ can be achieved after 8 iterations at E_{b}/N_{O}=11.5 dB.

7.4 Option 4—Trellis Coded Modulation with 2 bits Coded.

7.4.1 Coding

In this scheme, only two information bits are coded by a rate 2/4 code. The other two information bits are sent uncoded. The four coded bits (two information bits plus two parity bits) selects a four point constellation (16 constellations in total) and the two uncoded bits select a point in the constellation (four points in each constellation). The coding scheme is shown in FIG. 3. The two systematic recursive codes (SRC) used are identical and are defined in FIG. 4. The code is described by the generating polynomials 35o and 23o.

7.4.2 Puncturing

In accordance with an embodiment of the invention, in order to obtain a rate 1/2 code, every other parity bit is punctured as shown in Table 15.

TABLE 15
Puncturing and Mapping for Rate 1/2 64 QAM Option 4

| | | | | |
|---|---|---|---|---|
| Information bit (d) | d₁ | d₂ | d₃ | d₄ |
| parity bit (p) | p1 | — | — | — |
| parity bit (q) | — | q2 | — | — |

| | |
|---|---|
| 64 QAM symbol (I, Q) | (I, Q) = (d₁, p1, d₃, d₂, q2, d₄) |

7.4.3 Modulation

A trellis coded modulation scheme is employed. The four coded bits divide the 64 QAM constellation based on increased Euclidean distance.

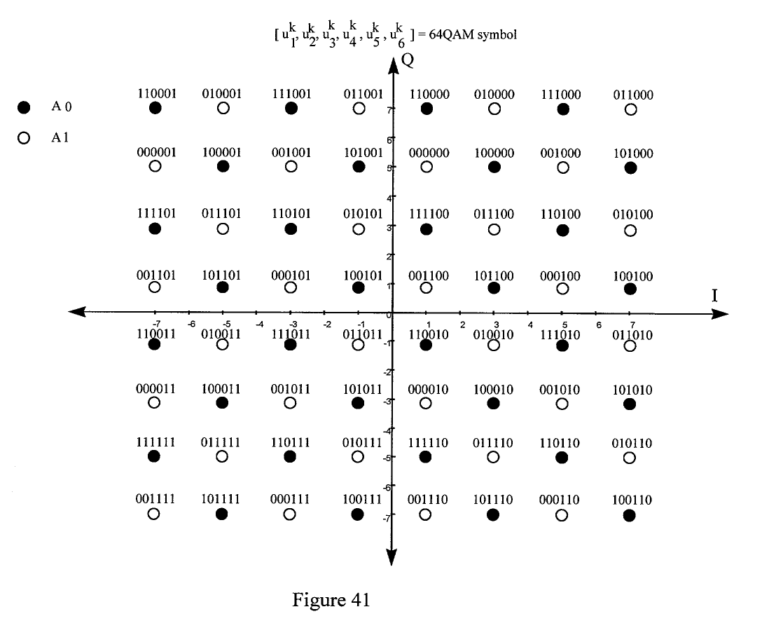

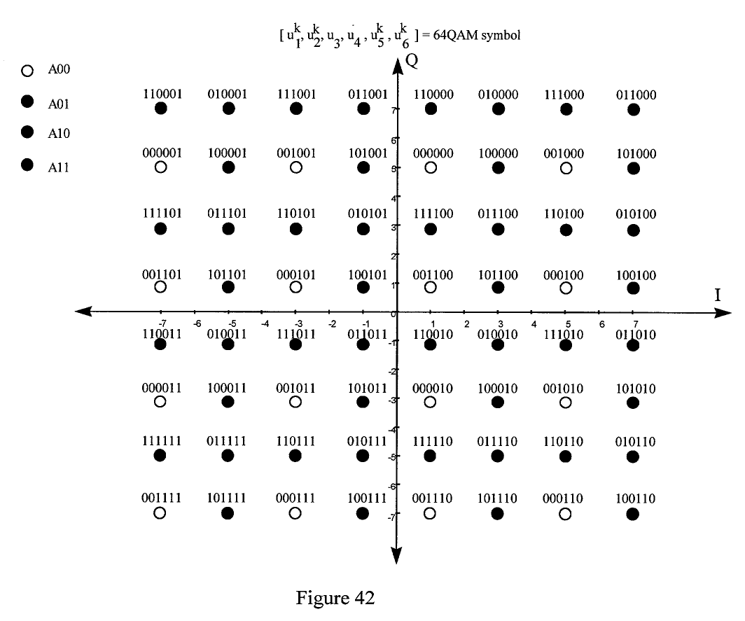

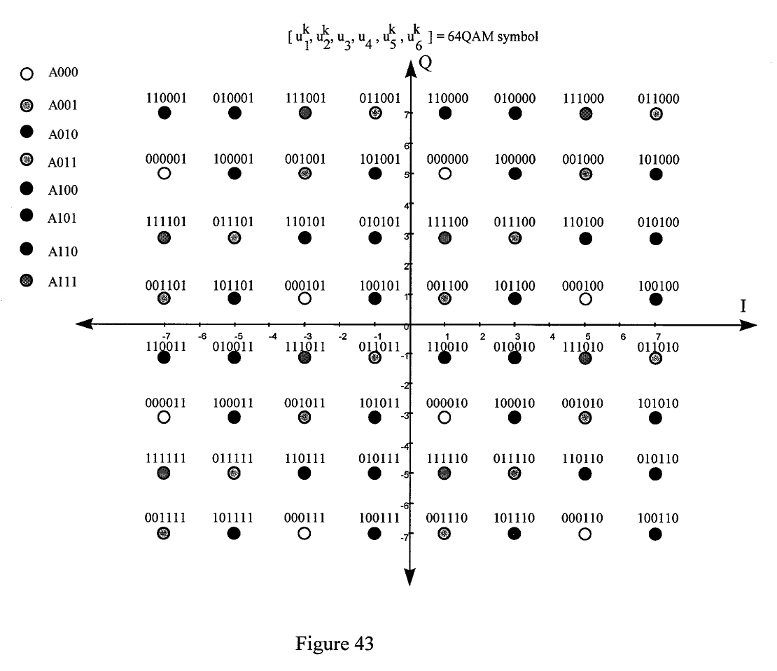

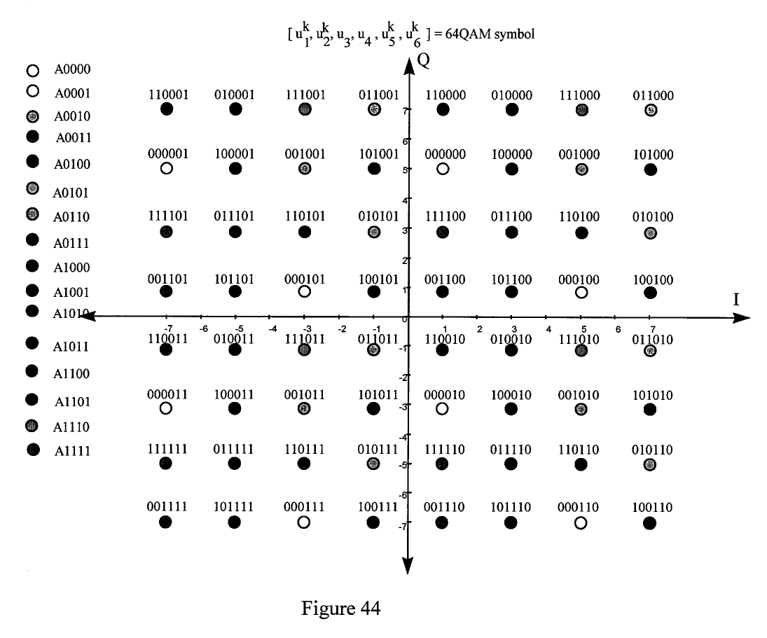

The 64 QM constellation shown in FIG. 39 is partitioned by the four coded bits in 16 subsets with four point each. The two uncoded bits will select one of the four points of the subset. FIGS. 41 to 44 show the four steps of the partitioning process. Each 16 points constellation subset can now be further partitioned as show in FIGS. 41 to 44.

The puncturing and mapping scheme is shown in Table 15 for 4 consecutive information bits that are encoded into 6 coded bits, therefore one 64 QAM symbol.

7.4.4 Bit Probabilities

For an AWGN channel, the following expressions need to be evaluated for each received symbol before the turbo decoding process can start.

$$\begin{matrix}LLR {(}_{{u}_{1}}^{k} ) = log ( \frac{{\sum }_{{u}_{1}^{k} = 1} exp ( - \frac{1}{2 {σ}_{N}^{2}} ‖ {R}^{k} - {P}_{i} ‖ )}{{\sum }_{{u}_{1}^{k} = 0} exp ( - \frac{1}{2 {σ}_{N}^{2}} ‖ {R}^{k} - {P}_{j} ‖ )} ) & ( 64 ) \\ LLR {(}_{{u}_{2}}^{k} ) = log ( \frac{{\sum }_{{u}_{2}^{k} = 1} exp ( - \frac{1}{2 {σ}_{N}^{2}} ‖ {R}^{k} - {P}_{i} ‖ )}{{\sum }_{{u}_{2}^{k} = 0} exp ( - \frac{1}{2 {σ}_{N}^{2}} ‖ {R}^{k} - {P}_{j} ‖ )} ) & ( 65 ) \\ LLR {(}_{{u}_{3}}^{k} ) = log ( \frac{{\sum }_{{u}_{3}^{k} = 1} exp ( - \frac{1}{2 {σ}_{N}^{2}} ‖ {R}^{k} - {P}_{i} ‖ )}{{\sum }_{{u}_{3}^{k} = 0} exp ( - \frac{1}{2 {σ}_{N}^{2}} ‖ {R}^{k} - {P}_{j} ‖ )} ) & ( 66 ) \\ LLR {(}_{{u}_{4}}^{k} ) = log ( \frac{{\sum }_{{u}_{4}^{k} = 1} exp ( - \frac{1}{2 {σ}_{N}^{2}} ‖ {R}^{k} - {P}_{i} ‖ )}{{\sum }_{{u}_{4}^{k} = 0} exp ( - \frac{1}{2 {σ}_{N}^{2}} ‖ {R}^{k} - {P}_{j} ‖ )} ) & ( 67 )\end{matrix}$$

Each summation in equations (64) (65) (66) and (67) is over 32 points

The ∥R^{k}-Pᵢ∥ represents the squared Euclidian distance between the received point R^{k} at the time k and a constellation point Pᵢ. The actual set in which uᵢ is 0 or 1 are shown in FIGS. 41-44.

7.4.5 Simulation Results

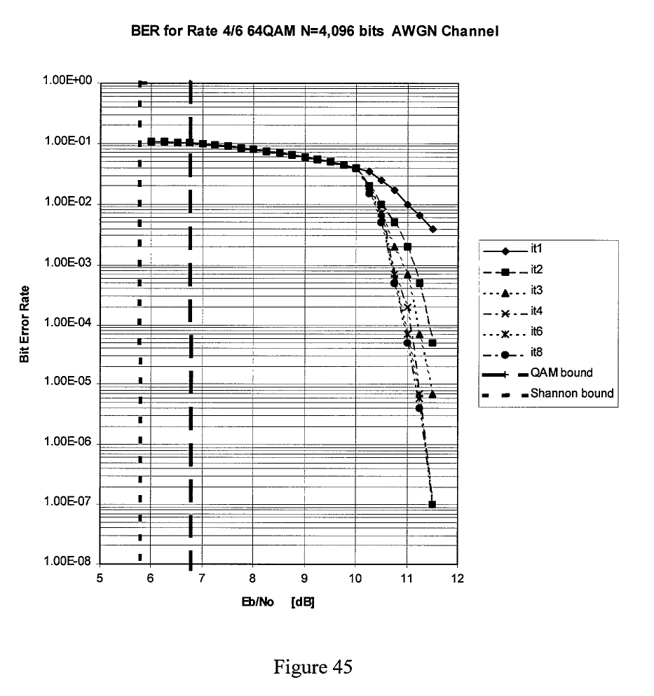

FIG. 45 shows the simulation results for 4,096 bit blocks with 2,048 bit S-type interleaver.

A BER of 10⁻⁷ can be achieved after 8 iterations at E_{b}/N_{O}=11.5 dB.

7.5 Recommended Solution

Comparing the complexity of each scheme and their performance, the recommended solution for 4 bit/s/Hz spectral efficiency is Option 1, the rate 4/6 turbo code 64 QAM scheme independent I and Q with gray mapping in each dimension. This achieves the target BER at E_{b}/N_{O}=8.3 dB. For N=4096 information bits.

8. Coding and Modulation for 5 bit/s/Hz Spectral Efficiency.

This section investigated three schemes all use independent I and Q modulation. The first scheme combines a rate 5/6 coding scheme with 64 QAM. The second scheme combines a rate 5/7 coding scheme with 128 QAM. The third scheme combines a rate 5/8 coding scheme with 256 QAM.

8.1 Option I—Rate 5/6 Turbo Code and 64 QAM.

8.1.1 Coding

The coding scheme is shown in FIG. 3. The two systematic recursive codes (SRC) used are identical and are defined in FIG. 4. The code is described by the generating polynomials 35o and 23o.

8.1.2 Puncturing

In accordance with an embodiment of the invention, in order to obtain a rate 5/6 code, the puncturing pattern used is shown in Table 16.

TABLE 16
Puncturing and Mapping for Rate 5/6 64 QAM Option 1

| | | | | | | | | | | |
|---|---|---|---|---|---|---|---|---|---|---|
| Information bit (d) | d₁ | d₂ | d₃ | d₄ | d₅ | d₆ | d₇ | d₈ | d₉ | d₁₀ |
| parity bit (p) | p1 | — | — | — | — | — | — | — | — | — |
| parity bit (q) | — | — | — | — | — | q6 | — | — | — | — |

| | | |
|---|---|---|
| 8 AM symbol (I) | (d₁, d₂, P1) | (d₆, d₇, q6) |
| 8 AM symbol (Q) | (d₃, d₄, d₅) | (d₈, d₉, d₁₀) |
| 64 QAM symbol (I, Q) | (I, Q) = | (I, Q) = |
| | (d₁, d₂, p1, d₃, d₄, d₅) | (d₆, d₇, q6, d₈, d₉, d₁₀) |

8.1.3 Modulation

A 64 QAM scheme is shown in FIG. 23.

Five information bits are required to be sent using a 64 QAM constellation. This is equivalent to a rate 5/6 coding scheme.

For a rate 5/6 code, the noise variance in each dimension is

$${σ}_{N}^{2} = {{E}_{av} ( \frac{2 η {E}_{b}}{{N}_{0}} )}^{- 1} = 42 {{A}^{2} ( \frac{2 \times 5 \times {E}_{b}}{{N}_{0}} )}^{- 1} = 4.2 {{A}^{2} ( \frac{{E}_{b}}{{N}_{0}} )}^{- 1} \qquad ( 68 )$$

The puncturing and mapping scheme is shown in Table 16 for 10 consecutive information bits that are encoded into 12 coded bits, therefore two 64 QAM symbols. The turbo encoder with the puncturing presented in Table 16 is a rate 5/6 turbo code which in conjunction with 64 QAM gives a spectral efficiency of 5 bits/s/Hz.

Considering two independent Gaussian noises with identical variance σ²_{N}, the LLR can be determined independently for each I and Q.

It is assumed that at time k u₁^{k}, u₂^{k} and u₃^{k} modulates the I component and u₄^{k}, u₅^{k} and u₆^{k} modulates the Q component of the 64 QAM scheme.

At the receiver, the I and Q signals are treated independently in order to take advantage of the simpler formulae for the LLR values.

8.1.4 Bit Probabilities

From each received symbol, the bit probabilities are computed as described in equations (54) (55) and (56) for I dimension. An identical computation effort is required for the Q dimension, the I^{k} being replaced with the Q^{k} demodulated value in order to evaluate LLR(u₄^{k}), LLR(u₅^{k}) and LLR(u₆^{k}).

8.1.5 Simulation Results

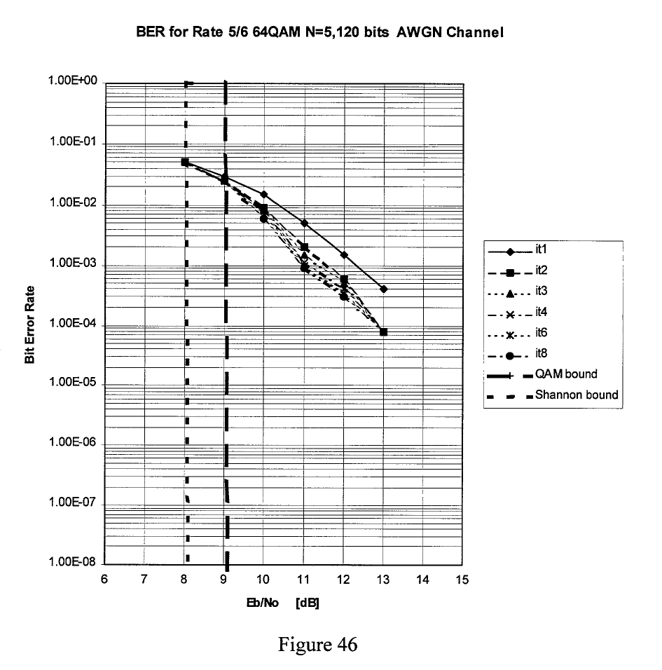

FIG. 46 shows the simulation results for 5,120 information bits (1,204 QAM symbols) with S-type interleaver.

The high puncturing rate makes the iterative decoding process to converge very slowly, showing a flattening of the BER curve. Therefore this option is not considered acceptable.

8.2 Option 2—Rate 5/7 Turbo Code and 128 QAM.

8.2.1 Coding

The coding scheme is shown in FIG. 3. The two systematic recursive codes (SRC) used are identical and are defined in FIG. 4. The code is described by the generating polynomials 35o and 23o.

8.2.2 Puncturing

In accordance with an embodiment of the invention, in order to obtain a rate 5/7 code, the puncturing pattern used is shown in Table 17.

TABLE 17
Puncturing and Mapping for Rate 5/7 128 QAM Option 2

| | | | | | |
|---|---|---|---|---|---|
| Information bit (d) | d₁ | d₂ | d₃ | d₄ | d₅ |
| parity bit (p) | p1 | — | — | — | |
| parity bit (q) | — | — | q3 | — | |

| | |
|---|---|
| 16 AM symbol (I) | (d₃, d₄, d₅, q3) |
| 8 AM symbol (Q) | (d₁, d₂, p1) |
| 128 QAM symbol (I, Q) | (I, Q) = (d₃, d₄, d₅, q3, d₁, d₂, p1) |

8.2.3 Modulation

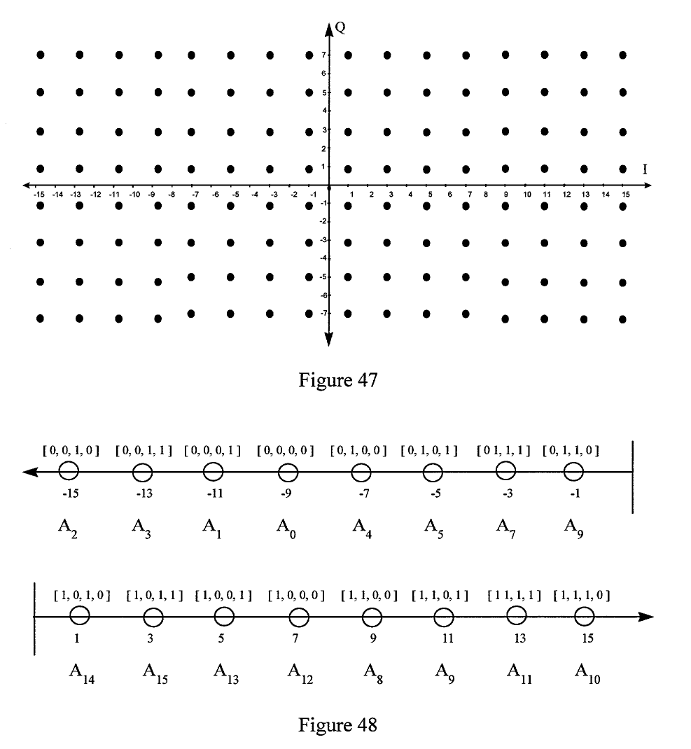

Let us consider the 128 QAM scheme as shown in FIG. 47. It is assumed that at time k the symbol u^{k}=(u₁^{k}, u₂^{k}, u₃^{k}, u₄^{k}, u₅^{k}, u₆^{k}) is sent though the channel. It is assumed that at time k the symbol u₁^{k}, u₂^{k}, u₃^{k}, and u₄^{k} modulate the I component and u5^{k}u₆^{k}and u₇^{k} modulate the Q component of a 128 QAM scheme.

In the I dimension, three information bits and one parity bits are transmitted using Gray mapping and 16 QAM as show in FIG. 48.

The average energy The Eₐᵥ_{_{—}}_{I} for the 16 QAM shown in FIG. 48 is:

$$\begin{matrix}The {E}_{av\_I} is \text{:} \\ {E}_{av\_I} = \frac{\begin{matrix}( 1 + 9 + 25 + 49 + 81 + \\ 121 + 169 + 225 ) {A}^{2}\end{matrix}}{8} = 85 {A}^{2} & ( 69 ) \\ The {E}_{av\_Q} is \text{:} {E}_{av\_Q} = \frac{( 1 + 9 + 25 + 49 ) {A}^{2}}{4} = 21 {A}^{2} & ( 70 )\end{matrix}$$

Because the noise has to be spherical, the total value of Eₐᵥ will be the addition of these two values, so:

Eₐᵥ=Eₐᵥ_{_{—}}_{I}+Eₐᵥ_{_{—}}_{Q}=106A² (71)

The value of the noise variance has to be the same in both dimensions and its value is:

$${σ}_{N}^{2} = {E}_{av} ( \frac{2 η {E}_{b}}{{N}_{0}} ) = 106 {{A}^{2} ( \frac{2 \times 5 \times {E}_{b}}{{N}_{0}} )}^{- 1} = 10.6 {{A}^{2} ( \frac{{E}_{b}}{{N}_{0}} )}^{- 1} \qquad ( 72 )$$

The puncturing and mapping scheme shown in Table 17 is for 5 consecutive information bits that are coded into 7 coded bits, therefore, one 128 QAM symbol. The turbo encoder is a rate 5/7 turbo code, which in conjunction with 128 QAM, gives a spectral efficiency of 5 bits/s/Hz.

8.2.4 Bit Probabilities

The 16 QAM symbol is defined as u^{k}=(u₁^{k}, u₂^{k}, u₃^{k}, u₄^{k}), where u₁^{k} is the most significant bit and u₄^{k} is the least significant bit. The following set can be defined. 1. bit-1-is-0={A₀, A₁, A₂, A₃, A₄, A₅, A₆, A₇}2. bit-1-is-1={A₈, A₉, A₁₀, A₁₁, A₁₂, A₁₃, A₁₄, A₁₅}3. bit-2-is-0={A₀, A₁, A₂, A₃, A₈, A₉, A₁₀, A₁₁}4. bit-2-is-1 ={A₄,A₅, A₆, A₇ , A₁₂, A₁₃ , A₁₄, A₁₅}5. bit-3-is-0={A₀,A₁, A₄ , A₅ , A₈, A₉, A₁₂ , A₁₃ }6. bit-3-is-1={A₂, A₃, A₆, A₇, A₁₀, A₁₁, A₁₄, A₁₅}7. bit-4-is-0={A₀, A₂, A₄, A₆, A₈, A₁₀,A₁₂, A₁₄}8. bit-4-is-1={A₁, A₃ , A₅, A₇ , A₉, A₁₁, A₁₃, A₁₅}

From each received symbol, R^{k}, the bit probabilities are computed as follows:

$$\begin{matrix}LLR {(}_{{u}_{1}}^{k} ) = log ( \frac{{\sum }_{{A}_{i} ∈ bit - 1 - is - 1} exp ( - \frac{1}{2 {σ}_{N}^{2}} ‖ {R}^{k} - {A}_{i} ‖ )}{{\sum }_{{A}_{j} ∈ bit - 1 - is - 0} exp ( - \frac{1}{2 {σ}_{N}^{2}} ‖ {R}^{k} - {A}_{j} ‖ )} ) & ( 73 ) \\ LLR {(}_{{u}_{2}}^{k} ) = log ( \frac{{\sum }_{{A}_{i} ∈ bit - 2 - is - 1} exp ( - \frac{1}{2 {σ}_{N}^{2}} ‖ {R}^{k} - {A}_{i} ‖ )}{{\sum }_{{A}_{j} ∈ bit - 2 - is - 0} exp ( - \frac{1}{2 {σ}_{N}^{2}} ‖ {R}^{k} - {A}_{j} ‖ )} ) & ( 74 ) \\ LLR {(}_{{u}_{3}}^{k} ) = log ( \frac{{\sum }_{{A}_{i} ∈ bit - 3 - is - 1} exp ( - \frac{1}{2 {σ}_{N}^{2}} ‖ {R}^{k} - {A}_{i} ‖ )}{{\sum }_{{A}_{j} ∈ bit - 3 - is - 0} exp ( - \frac{1}{2 {σ}_{N}^{2}} ‖ {R}^{k} - {A}_{j} ‖ )} ) & ( 75 ) \\ LLR {(}_{{u}_{4}}^{k} ) = log ( \frac{{\sum }_{{A}_{i} ∈ bit - 4 - is - 1} exp ( - \frac{1}{2 {σ}_{N}^{2}} ‖ {R}^{k} - {A}_{i} ‖ )}{{\sum }_{{A}_{j} ∈ bit - 4 - is - 0} exp ( - \frac{1}{2 {σ}_{N}^{2}} ‖ {R}^{k} - {A}_{j} ‖ )} ) & ( 76 )\end{matrix}$$

Similar formulae apply for the 8 AM symbol defined as u^{k}=(u₅^{k}, u₆^{k}, u₇^{k}), where u₅^{k} is the most significant bit and u₇^{k} is the least significant bit.

8.2.5 Simulation Results

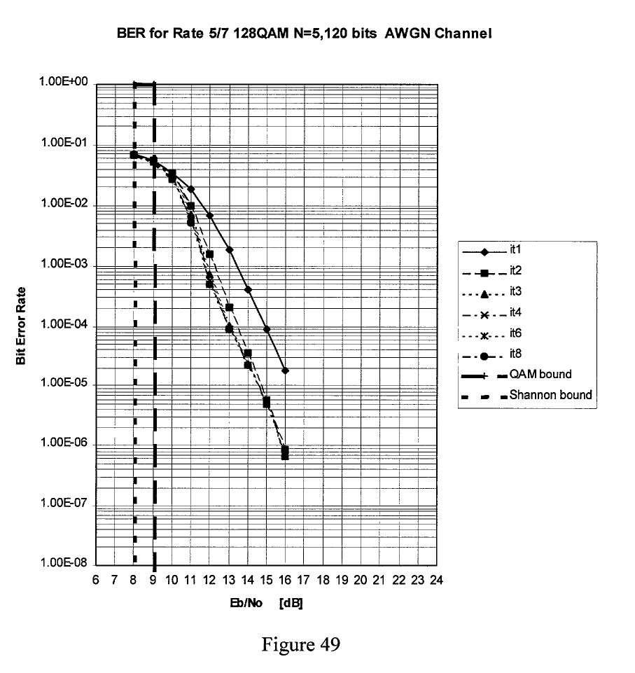

FIG. 49 shows the simulation results for 5,120 information bits (1,204 QAM symbols) with S-type interleaver.

The high puncturing rate makes the iterative decoding process to converge very slowly, showing a flattening of the BER curve.

8.3 Option 3—Rate 5/8 Turbo Code and 256 QAM

8.3.1 Coding

The coding scheme is shown in FIG. 3. The two systematic recursive codes (SRC) used are identical and are defined in FIG. 4. The code is described by the generating polynomials 35o and 23o.

8.3.2 Puncturing

In accordance with an embodiment of the invention, in order to obtain a rate 5/8 code, the puncturing pattern used is shown in Table 18.

TABLE 18
Puncturing and Mapping for Rate 5/8 256 QAM Option 3

| | | | | | | | | | | |
|---|---|---|---|---|---|---|---|---|---|---|
| Information bit (d) | d₁ | d₂ | d₃ | d₄ | d₅ | d₆ | d₇ | d₈ | d₉ | d₁₀ |
| parity bit (p) | p1 | — | — | — | p5 | — | — | p8 | — | — |
| parity bit (q) | — | — | q3 | — | | q6 | — | — | — | q10 |

| | | |
|---|---|---|
| 16 AM symbol (I) | (d₁, d₂, d₃, p1) | (d₆, d₇, d₈, q6) |
| 16 AM symbol (Q) | (d₄, d₅, q3, p5) | (d₉, d₁₀, p8, q10) |
| 256 QAM symbol | (I, Q) = (d₁,d₂, d₃, p1, | (I, Q) = (d₆, d₇, d₈, q6, |
| (I, Q) | d₄, d₅, q3, p5) | d₉, d₁₀, p8, q10) |

8.3.3 Modulation

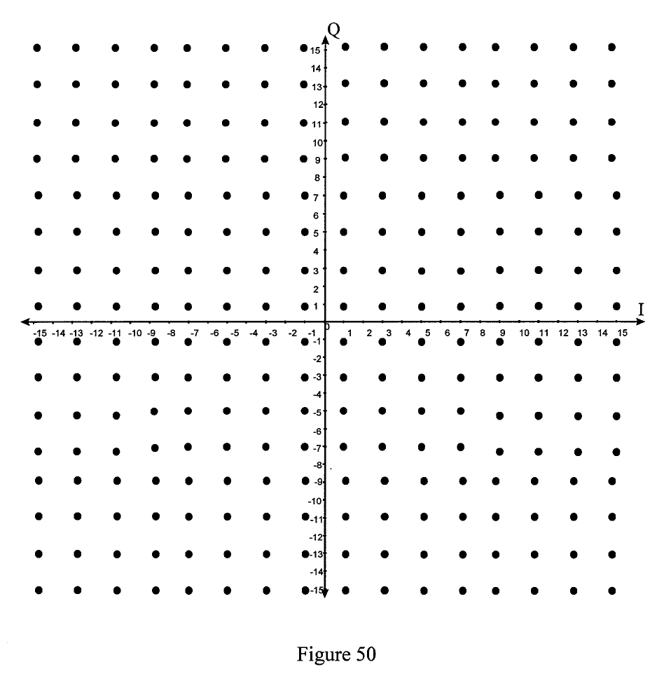

Let us consider the 256 QAM scheme as shown in FIG. 50

For a 256 QAM constellation with points at −15A, −13A, −11A, −9A, −7A, −5A, −3A, −A, A, 3A, 5A 7A, 9A, 11A, 13A, 15A. Eₐᵥ is:

Eₐᵥ=(8(225+169+121+81+49+25+9+1)+8(225+169+225+121+225+81+225+49+225+25+225+9+225+1)+8(169+121+169+81+169+49+169+25+169+9+169+1) +8(121+81+121+49+121+25+121+9+121+1)+8(81+49+25+81+9+81+1) +8(49+25+49+9+49+1)+8(25+9+25+1)+8(9+1)) A²/256=170A² (77)

It is assumed that at time k the symbol u^{k}=(u₁^{k}, u₂^{k}, u₃^{k}, u₄^{k}, u₅^{k}, u₆^{k}, u₇^{k}, u₈^{k}) is sent though the channel.

It is assumed that at time k the symbol u₁^{k}, u₂^{k}, u₃^{k} and u₄^{k} modulate the I component and u₅^{k}, u₆^{k}, u₇^{k} and u₈^{k} modulate the Q component of a 256 QAM scheme.

For a rate 5/8 code and 256 QAM, the noise variance is:

$${σ}_{N}^{2} = {{E}_{av} ( \frac{2 η {E}_{b}}{{N}_{0}} )}^{- 1} = 170 {{A}^{2} ( \frac{2 \times 5 \times {E}_{b}}{{N}_{0}} )}^{- 1} = 17 {{A}^{2} ( \frac{{E}_{b}}{{N}_{0}} )}^{- 1} \qquad ( 78 )$$

In order to study the performance of this scheme, a rate 5/8 turbo code and a 16 AM is used as describe in FIG. 50. The 256 QAM scheme will achieve a similar performance in terms of bit error rate (BER) at twice the spectral efficiency, assuming an ideal demodulator.

The Eₐᵥ for the 16 QAM shown in FIG. 48 is:

Eₐᵥ_{_{—}}_{I}=(1+9+25+49+81+121+169+225)A²/8=85A² (79)

The noise variance is:

$${σ}_{N}^{2} = {{E}_{av} ( \frac{2 η {E}_{b}}{{N}_{0}} )}^{- 1} = 85 {{A}^{2} ( \frac{2 \times 2.5 \times {E}_{b}}{{N}_{0}} )}^{- 1} = 17 {{A}^{2} ( \frac{{E}_{b}}{{N}_{0}} )}^{- 1} \qquad ( 80 )$$

This is identical to the variance for 256 QAM scheme.

The puncturing and mapping scheme shown in Table 18 is for 10 consecutive information bits that are coded into 16 encoded bits, therefore, one 256 QAM symbol.

The turbo encoder is a rate 5/8 turbo code, which in conjunction with 256 QAM, gives a spectral efficiency of 5 bits/s/Hz.

8.3.4 Bit Probabilities

The 16 AM symbol is defined as u^{k}=(u₁^{k}, u₂^{k}, u₃^{k}, u₄^{k}), where u₁^{k} is the most significant bit and u₄^{k} is the least significant bit . The following set can be defined.

From each received symbol, R^{k}, the bit probabilities are computed as follows:

$$\begin{matrix}LLR {(}_{{u}_{1}}^{k} ) = log ( \frac{{\sum }_{{A}_{i} ∈ bit - 1 - is - 1} exp ( - \frac{1}{2 {σ}_{N}^{2}} ‖ {R}^{k} - {A}_{i} ‖ )}{{\sum }_{{A}_{j} ∈ bit - 1 - is - 0} exp ( - \frac{1}{2 {σ}_{N}^{2}} ‖ {R}^{k} - {A}_{j} ‖ )} ) & ( 81 ) \\ LLR {(}_{{u}_{2}}^{k} ) = log ( \frac{{\sum }_{{A}_{i} ∈ bit - 2 - is - 1} exp ( - \frac{1}{2 {σ}_{N}^{2}} ‖ {R}^{k} - {A}_{i} ‖ )}{{\sum }_{{A}_{j} ∈ bit - 2 - is - 0} exp ( - \frac{1}{2 {σ}_{N}^{2}} ‖ {R}^{k} - {A}_{j} ‖ )} ) & ( 82 ) \\ LLR {(}_{{u}_{3}}^{k} ) = log ( \frac{{\sum }_{{A}_{i} ∈ bit - 3 - is - 1} exp ( - \frac{1}{2 {σ}_{N}^{2}} ‖ {R}^{k} - {A}_{i} ‖ )}{{\sum }_{{A}_{j} ∈ bit - 3 - is - 0} exp ( - \frac{1}{2 {σ}_{N}^{2}} ‖ {R}^{k} - {A}_{j} ‖ )} ) & ( 83 ) \\ LLR {(}_{{u}_{4}}^{k} ) = log ( \frac{{\sum }_{{A}_{i} ∈ bit - 4 - is - 1} exp ( - \frac{1}{2 {σ}_{N}^{2}} ‖ {R}^{k} - {A}_{i} ‖ )}{{\sum }_{{A}_{j} ∈ bit - 4 - is - 0} exp ( - \frac{1}{2 {σ}_{N}^{2}} ‖ {R}^{k} - {A}_{j} ‖ )} ) & ( 84 )\end{matrix}$$

8.3.5 Simulation Results

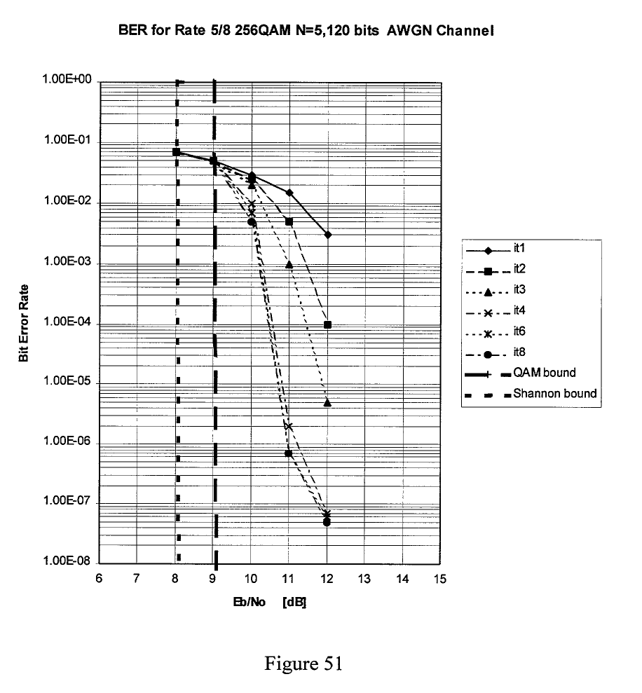

FIG. 51 shows the simulation results for 5,120 information bits (1,204 QAM symbols) with S-type interleaver.

A search for the best S-type interleaver was performed. For each interleaver size, the maximum S-factor was found and four different interleavers were generated using a random seed. Four simulations were generated for a target BER of 10⁻⁵. The best result decided the preferred interleaver. Using the preferred interleaver, complete simulations were started for BER down to 10⁻⁷. A BER of 10⁻⁷ can be achieved after 8 iterations at E_{b}/N_{O}=11.8 dB.

8.4 Recommended Solution

The recommended solution for 5 bit/s/Hz spectral efficiency is the rate 5/8 turbo code 256 QAM scheme independent I and Q with gray mapping in each dimension. This achieves the target BER at E_{b}/N_{O}=11.8 dB. For N=5,120 information bits.

9. Coding and Modulation for 6 bit/Hz Spectral Efficiency

This section investigated two schemes all use independent I and Q modulation. The first scheme combines a rate 6/8 coding scheme with 256 QAM. The second scheme combines a rate 6/9 coding scheme with 512 QAM.

9.1 Option 1—Rate 6/8 Turbo Code and 256 OAM

9.1.1 Coding

The coding scheme is shown in FIG. 3. The two systematic recursive codes (SRC) used are identical and are defined in FIG. 4. The code is described by the generating polynomials 35o and 23o.

9.1.2 Puncturing

In accordance with an embodiment of the invention, in order to obtain a rate 6/8 code, the puncturing pattern used is shown in Table 19.

TABLE 19
Puncturing and Mapping for Rate 6/8 256 QAM Option 1

| | | | | | | |
|---|---|---|---|---|---|---|
| Information bit (d) | d₁ | d₂ | d₃ | d₄ | d₅ | d₆ |
| parity bit (p) | p1 | — | — | — | — | — |
| parity bit (q) | — | — | — | q4 | — | — |

| | |
|---|---|
| 16 AM symbol (I) | (d₁, d₂, d₃, p1) |
| 16 AM symbol (Q) | (d₄, d₅, d₆, q4) |
| 256 QAM symbol | (I, Q) = (d₁, d₂, d₃, p1, d₄, d₅, d₆, q4) |
| (I, Q) | |

9.1.3 Modulation

Let us consider a 256 QAM scheme as shown in FIG. 50. It is assumed that at time k the symbol u^{k}=(u₁^{k}, u₂^{k}, u₃^{k}, u₄^{k}, u₅^{k}, u₆^{k}, u₇^{k}, u₈^{k}) is sent though the channel. It is assumed that at time k the symbol u₁^{k}, u₂^{k}, u₃^{k} and u₄^{k} modulate the I component and u₅^{k}, u₆^{k}, u₇^{k} and u₈^{k} modulate the Q component of a 256 QAM scheme.

For a rate 6/8 code and 256 QAM, the noise variance is:

$${σ}_{N}^{2} = {{E}_{av} ( \frac{2 η {E}_{b}}{{N}_{0}} )}^{- 1} = 170 {{A}^{2} ( \frac{2 \times 6 \times {E}_{b}}{{N}_{0}} )}^{- 1} = 14.16 {{A}^{2} ( \frac{{E}_{b}}{{N}_{0}} )}^{- 1} \qquad ( 85 )$$

The Eₐᵥ in the I and Q dimension is the 16 QAM shown in FIG. 47 is:

Eₐᵥ_{_{—}}_{I}=(1+9+25+49+81+121+169+225)A²/8=85A² (86)

The noise variance is:

$$\begin{matrix}{σ}_{N}^{2} = {{E}_{av} ( \frac{2 η {E}_{b}}{{N}_{0}} )}^{- 1} = 85 {{A}^{2} ( \frac{2 \times 3 \times {E}_{b}}{{N}_{0}} )}^{- 1} \\ = 14.16 {{A}^{2} ( \frac{{E}_{b}}{{N}_{0}} )}^{- 1}\end{matrix} \qquad ( 87 )$$

This is identical to the variance for 256 QAM scheme.

The puncturing and mapping scheme shown in Table 19 is for 6 consecutive information bits that are coded into 8 coded bits, therefore, one 256 QAM symbol. The turbo encoder is a rate 6/8 turbo code, which in conjunction with 256 QAM, gives a spectral efficiency of 6 bits/s/Hz.

9.1.4 Bit Probabilities

The 16 AM symbol is defined as u^{k}=(u₁^{k}, u₂^{k}, u₃^{k}, u₄^{k}), where u₁^{k} is the most significant bit and u₄^{k} is the least significant bit. The following set can be defined.

1. bit-1-is-0={A₀, A₁, A₂, A₃, A₄, A₅, A₆, A₇}

2. bit-1-is-1={A₈, A₉, A₁₀, A₁₁, A₁₂, A₁₃, A₁₄, A₁₅}

3. bit-2-is-0={A₀, A₁, A₂, A₃, A₈, A₉, A₁₀, A₁₁}

4. bit-2-is-1={A₄, A₅, A₆, A₇, A₁₂, A₁₃, A₁₄, A₁₅}

5. bit-3-is-0={A₀, A₁, A₄, A₅, A₈, A₉, A₁₂, A₁₃}

6. bit-3-is-1={A₂, A₃, A₆, A₇, A₁₀, A₁₁, A₁₄, A₁₅}

7. bit-4-is-0={A₀, A₂, A₄, A₆, A₈, A₁₀, A₁₂, A₁₄}

8. bit-4-is-1={A₁, A₃, A₅, A₇, A₉, A₁₁, A₁₃, A₁₅}

From each received symbol, R^{k}, the bit probabilities are computed as follows:

$$\begin{matrix}LLR ( {u}_{1}^{k} ) = log ( \frac{{\sum }_{{A}_{i} ∈ bit - 1 - is - 1} exp ( - \frac{1}{2 {σ}_{N}^{2}} ‖ {R}^{k} - {A}_{i} ‖ )}{{\sum }_{{A}_{i} ∈ bit - 1 - is - 0} exp ( - \frac{1}{2 {σ}_{N}^{2}} ‖ {R}^{k} - {A}_{j} ‖ )} ) & ( 88 ) \\ LLR ( {u}_{2}^{k} ) = log ( \frac{{\sum }_{{A}_{i} ∈ bit - 2 - is - 1} exp ( - \frac{1}{2 {σ}_{N}^{2}} ‖ {R}^{k} - {A}_{i} ‖ )}{{\sum }_{{A}_{i} ∈ bit - 2 - is - 0} exp ( - \frac{1}{2 {σ}_{N}^{2}} ‖ {R}^{k} - {A}_{j} ‖ )} ) & ( 89 ) \\ LLR ( {u}_{3}^{k} ) = log ( \frac{{\sum }_{{A}_{i} ∈ bit - 3 - is - 1} exp ( - \frac{1}{2 {σ}_{N}^{2}} ‖ {R}^{k} - {A}_{i} ‖ )}{{\sum }_{{A}_{i} ∈ bit - 3 - is - 0} exp ( - \frac{1}{2 {σ}_{N}^{2}} ‖ {R}^{k} - {A}_{j} ‖ )} ) & ( 90 ) \\ LLR ( {u}_{4}^{k} ) = log ( \frac{{\sum }_{{A}_{i} ∈ bit - 4 - is - 1} exp ( - \frac{1}{2 {σ}_{N}^{2}} ‖ {R}^{k} - {A}_{i} ‖ )}{{\sum }_{{A}_{i} ∈ bit - 4 - is - 0} exp ( - \frac{1}{2 {σ}_{N}^{2}} ‖ {R}^{k} - {A}_{j} ‖ )} ) & ( 91 )\end{matrix}$$

9.1.5 Simulation Results

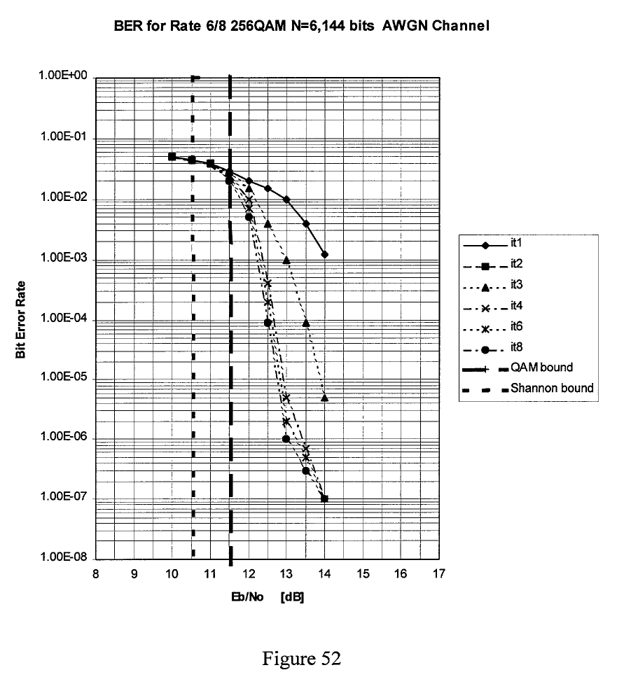

FIG. 52 shows the simulation results for 6,144 information bits (1,024 QAM symbols) with S-type interleaver.

A search for the best S-type interleaver was performed. For each interleaver size, the maximum S-factor was found and four different interleavers were generated using a random seed. Four simulations were generated for a target BER of 10⁻⁵. The best result decided the preferred interleaver. Using the preferred interleaver, complete simulations were started for BER down to 10⁻⁷.

A BER of 10⁻⁷ can be achieved after 8 iterations at E_{b}/N_{O}=14.2 dB.

9.2 Option 2—Rate 6/9 Turbo Code and 512 QAM

9.2.1 Coding

The coding scheme is shown in FIG. 3. The two systematic recursive codes (SRC) used are identical and are defined in FIG. 4. The code is described by the generating polynomials 35o and 23o.

9.2.2 Puncturing

In accordance with an embodiment of the invention, in order to obtain a rate 6/9 code, the puncturing pattern used is shown in Table 20.

TABLE 20
Puncturing and Mapping for Rate 6/9 512 QAM Option 2

| | | | | | | | | | | | | |
|---|---|---|---|---|---|---|---|---|---|---|---|---|
| Infor- | d₁ | d₂ | d₃ | d₄ | d₅ | d₆ | d₇ | d₈ | d₉ | d₁₀ | d₁₁ | d₁₂ |
| mation | | | | | | | | | | | | |
| bit (d) | | | | | | | | | | | | |
| parity | p1 | — | — | — | p5 | — | — | — | p9 | — | — | — |
| bit (p) | | | | | | | | | | | | |
| parity | — | — | q3 | — | — | — | q7 | — | — | — | q11 | — |
| bit (q) | | | | | | | | | | | | |

| | | |
|---|---|---|
| 32 AM | (d₁, d₂, d₃, d₄, p1) | (d₇, d₈, d₉, d₁₀, q7) |
| symbol | | |
| (I) | | |
| 16 AM | (d₅, d₆, p5, q3) | (d₁₁, d₁₂, Q11, p9) |
| symbol | | |
| (Q) | | |
| 512 | (I, Q) = (d₁, d₂, d₃, d₄, p1, | (I, Q) = (d₇, d₈, d₉, d₁₀, q7, d₁₁, |
| QAM | d₅, d₆, p5, q3) | d₁₂, q11, P9) |
| symbol | | |
| (I, Q) | | |

9.2.3 Modulation

Let us consider a 512 QAM scheme as shown in FIG. 52. It is assumed that at time k the symbol u^{k}=(u₁^{k}, u₂^{k}, u₃^{k}, u₄^{k, u}₅^{k}, u₆^{k}, u₇^{k}, u₈^{k}, u₉^{k}) is sent though the channel. It is assumed that at time k the symbol u₁^{k}, u₂^{k}, u₃^{k}, u₄^{k} and u₅^{k} modulates the I component and u₆^{k}, u₇^{k}, u₈^{k} and u₉^{k} modulates the the Q component of a 512 QAM scheme.

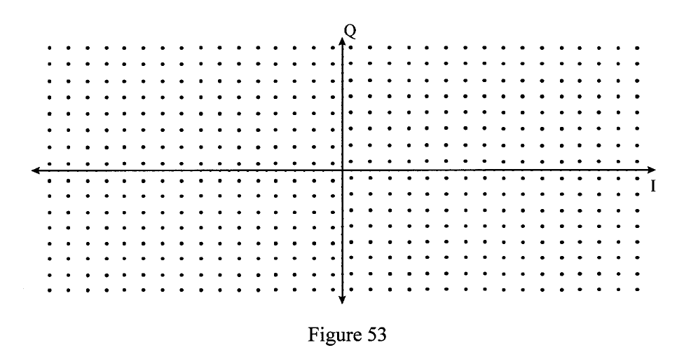

In the I dimension, four information bits and one parity bit are transmitted using Gray mapping and 32 AM as shown in FIG. 53.

The 32 constellation points have amplitudes: −31A, −29A, −27A, −25A, −23A, −21A, −19A, −17A, −15A, −13A, −11A, −9A, −7A, −5A, −3A, −A, A, 3A, 5A, 7A, 9A, 11A, 13A, 15A, 17A, 19A, 21A, 23A, 25A, 27A, 29A, 31A. The Eₐᵥ_{_{—}}_{I} is:

$${E}_{av\_Q} = \frac{( 1 + 9 + 25 + 49 + 81 + 121 + 169 + 225 ) {A}^{2}}{8} = {85}_{{A}^{2}} \qquad ( 93 )$$

Because the noise has to be spherical, the total value of Eₐᵥ will be the addition of these two values, so:

Eₐᵥ=Eₐᵥ_{_{—}}_{I}+Eₐᵥ_{_{—}}_{Q}=426 A² (94)

The value of the noise variance has to be the same in both dimensions and its value is:

$${σ}_{N\_ 1}^{2} = {{E}_{av} ( \frac{2 {ηE}_{b}}{{N}_{0}} )}^{- 1} = 341 {A}^{2} ( \frac{2 \times 6 \times {E}_{b}}{{N}_{0}} ) = \frac{341}{12} {{A}^{2} ( \frac{{E}_{b}}{{N}_{0}} )}^{- 1} \qquad ( 95 )$$

The puncturing and mapping scheme shown in Table 20 is for 12 consecutive information bits that are coded into 18 coded bits, therefore, one 512 QAM symbol. The turbo encoder is a rate 6/9 turbo code, which in conjunction with 512 QAM, gives a spectral efficiency of 6 bits/s/Hz.

9.2.4 Bit Probabilities

From each received symbol, R^{k}, the bit probabilities are computed as follows:

$$\begin{matrix}LLR ( {u}_{1}^{k} ) = log ( \frac{{\sum }_{{A}_{i} ∈ bit - 1 - is - 1} exp ( - \frac{1}{2 {σ}_{N}^{2}} ‖ {R}^{k} - {A}_{i} ‖ )}{{\sum }_{{A}_{i} ∈ bit - 1 - is - 0} exp ( - \frac{1}{2 {σ}_{N}^{2}} ‖ {R}^{k} - {A}_{j} ‖ )} ) & ( 96 ) \\ LLR ( {u}_{2}^{k} ) = log ( \frac{{\sum }_{{A}_{i} ∈ bit - 2 - is - 1} exp ( - \frac{1}{2 {σ}_{N}^{2}} ‖ {R}^{k} - {A}_{i} ‖ )}{{\sum }_{{A}_{i} ∈ bit - 2 - is - 0} exp ( - \frac{1}{2 {σ}_{N}^{2}} ‖ {R}^{k} - {A}_{j} ‖ )} ) & ( 97 ) \\ LLR ( {u}_{3}^{k} ) = log ( \frac{{\sum }_{{A}_{i} ∈ bit - 3 - is - 1} exp ( - \frac{1}{2 {σ}_{N}^{2}} ‖ {R}^{k} - {A}_{i} ‖ )}{{\sum }_{{A}_{i} ∈ bit - 3 - is - 0} exp ( - \frac{1}{2 {σ}_{N}^{2}} ‖ {R}^{k} - {A}_{j} ‖ )} ) & ( 98 ) \\ LLR ( {u}_{4}^{k} ) = log ( \frac{{\sum }_{{A}_{i} ∈ bit - 4 - is - 1} exp ( - \frac{1}{2 {σ}_{N}^{2}} ‖ {R}^{k} - {A}_{i} ‖ )}{{\sum }_{{A}_{i} ∈ bit - 4 - is - 0} exp ( - \frac{1}{2 {σ}_{N}^{2}} ‖ {R}^{k} - {A}_{j} ‖ )} ) & ( 99 ) \\ LLR ( {u}_{5}^{k} ) = log ( \frac{{\sum }_{{A}_{i} ∈ bit - 5 - is - 1} exp ( - \frac{1}{2 {σ}_{N}^{2}} ‖ {R}^{k} - {A}_{i} ‖ )}{{\sum }_{{A}_{i} ∈ bit - 5 - is - 0} exp ( - \frac{1}{2 {σ}_{N}^{2}} ‖ {R}^{k} - {A}_{j} ‖ )} ) & ( 99 )\end{matrix}$$

9.2.5 Simulation Results

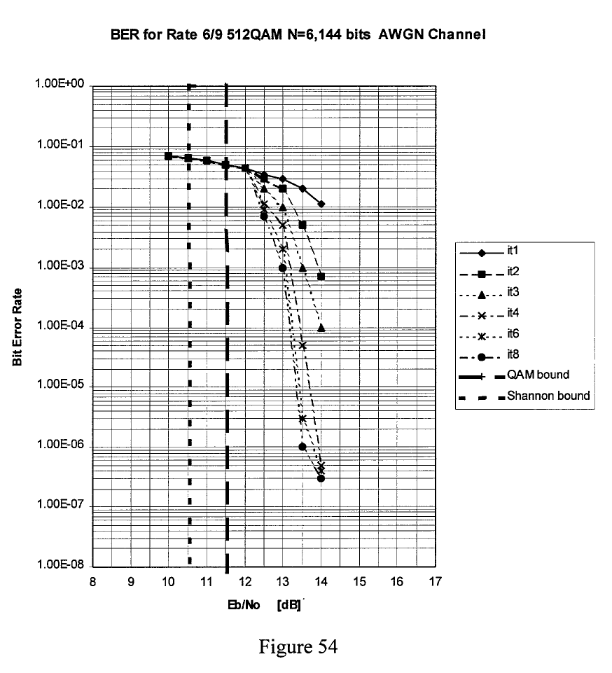

FIG. 54 shows the simulation results for 6,144 information bits (1,204 QAM symbols) with S-type interleaver.

A BER of 10⁻⁶ I can be achieved after 8 iterations at E_{b}/N_{O}=13.5 dB. A BER of 10⁻⁷ can be achieved after 8 iterations at E_{b}/N_{O}=14.5 dB.

9.3 Recommended Solution

The recommended solution for 6 bit/s/Hz spectral efficiency is the rate 6/8 turbo code 256 QAM scheme. This scheme achieves a BER of 10⁻⁷ at E_{b}/N_{O}=14.2 dB.

10. Coding and Modulation for 7 bit/Hz Spectral Efficiency

This section investigated one scheme that use independent I and Q modulation. The scheme combines a rate 7/10 coding scheme with 1024 QAM.

10.1 Coding

The coding scheme is shown in FIG. 3. The two systematic recursive codes (SRC) used are identical and are defined in FIG. 4. The code is described by the generating polynomials 35o and 23o.

10.2 Puncturing

In accordance with an embodiment of the invention, in order to obtain a rate 7/10 code, the puncturing pattern used is shown in Table 21.

TABLE 21
Puncturing and Mapping for Rate 7/10 1024 QAM

| | | | | | | | | | | | | | | |
|---|---|---|---|---|---|---|---|---|---|---|---|---|---|---|
| Information bit (d) | d₁ | d₂ | d₃ | d₄ | d₅ | d₆ | d₇ | d₈ | d₉ | d₁₀ | d₁₁ | d₁₂ | d₁₃ | d₁₄ |
| parity bit (p) | p1 | — | — | — | — | p6 | — | — | — | — | p11 | — | — | — |
| parity bit (q) | — | — | q3 | — | — | — | — | q8 | — | — | — | — | q13 | — |

| | | |
|---|---|---|
| 32 AM symbol (I) | (d₁, d₂, d₃, p1, q3) | (d₈, d₉, d₁₀, d₁₁, q8) |
| 32 AM symbol (Q) | (d₄, d₅, d₆, d₇, p6) | d₁₂, d₁₃, d₁₄, p11, q13) |
| 1024 QAM symbol (I, Q) | (I, Q) = (d₁, d₂, d₃, p1, q3, | (I, Q) = (d₈, d₉, d₁₀, d₁₁, q8, |
| | d₄, d₅, d₆, d₇, p6) | d₁₂, d₁₃, d₁₄, p11, q13) |

10.3 Modulation

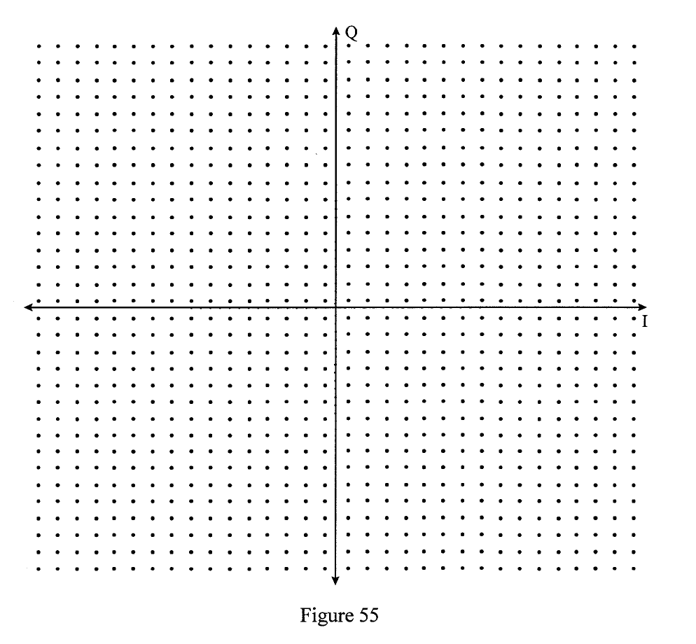

Let us consider a 1024 QAM scheme as shown in FIG. 55. It is assumed that at time k the symbol u^{k}=(u₁^{k}, u₂^{k}, u₃^{k}, u₄^{k}, u₅^{k}, u₆^{k}, u₇^{k}, u₈^{k}, u₉^{k}, u₁₀^{k}) is sent though the channel. It is assumed that at time k the symbol u₁^{k}, u₂^{k}, u₃^{k}, u₄^{k} and u₅^{k} modulates the I component and u₆^{k}, u₇^{k}, u₈^{k}, u₉^{k} and u₁₀^{k} modulates the Q component of a 1024 QAM scheme.

For a 1024 QAM constellation with points at −31A, −29A, −27A, −25A, −23A, −21A, −19A, −17A, −15A, −13A, −11A, −9A, −7A, −5A, −3A, −A, A, 3A, 5A, 7A, 9A, 11A, 13A, 15A, 17A, 19A, 21A, 23A, 25A, 27A, 29A, 31A. Eₐᵥ is:

Eₐᵥ=8(961+841+729+625+529+441+361+289+225+169+121+81+49+25+9+1) +8(961+841+961+729+961+625+961+529+961+441+961+361+961+289+961+225+961+169+961+121+961+81+961 +49+961+25+961+9+961+1)+8(841+729+841+625+841+529+841+441+841+361+841+289+841+225+841+169+841+121+841+81+841+49+841+25+841+9+841+1)8(729+625+729+529+729+441+729+361+729+289+729+225+729+169+729+121+729+81+729+49+729+25+729+9+729+1)8(625+529+625+441+625+361+625+289+625+225+625+169+625+121+625+81+625+49+625+25+625+9+625+1)+8(529+441+529+361+529+289+529+225+529+169+529+121+529+81+529+49+529+25+529+9+529+1)+8(441+361+441+289+441+225+441+169+441+121+441+81+441+49+441+25+441+9+441+1)8(361+289+361+225+361+169+361+121+361+529+9+529+1)+8(441+361+441+289+441+225+441+169+441+121+441+81+441+49+441+25+441+9+441+1)8(361+289+361+225+361+169+361+121+361+81+361+49+361+25+361+9+361+1)+8(289+225+289+169+289+121+289+81+289+49+289+25+289+9+289+1) 8(225+169+225+121+225+81+225+49+225+25+225+9+225+1)8(169+121+169+81+169+49+169+25+169+9+169+1)+8(121+81+121+49+121+25+121+9+121+1) +8(81+49+81+25+81+9+81+1)+8(49+25+49+9+49+1)+8(25+9+25+1)+8(9+1)A²/1024=682A² (100)

For a rate 7/10 code and 512 QAM, the noise variance is:

$$\begin{matrix}{σ}_{N}^{2} = {{E}_{av} ( \frac{2 η {E}_{b}}{{N}_{0}} )}^{- 1} = 682 {{A}^{2} ( \frac{2 \times 7 \times {E}_{b}}{{N}_{0}} )}^{- 1} \\ = 48.7 {{A}^{2} ( \frac{{E}_{b}}{{N}_{0}} )}^{- 1}\end{matrix} \qquad ( 101 )$$

The 1024 QAM constellation is a product of two 32 constellation with points at: −31A, −29A, −27A, −25A, −23A, −21A, −19A, −17A, −15A, −13A, −11A, −9A, −9A, −7A, −5A, −3A, −A, A, 3A, 5A, 7A, 9A, 11A, 13A, 15A, 17A, 19A, 21A, 23A, 25A, 27A, 29A, 31A. The 32 QAM Eₐᵥ_{_{—}}_{I}is:

Eₐᵥ=(1+9+25+49+81+121+169+225+289+361+441+529+625+729+841+961) A²/16=341A² (102)

For a rate 7/10 code and 1024 QAM, the noise variance is:

$$\begin{matrix}{σ}_{N}^{2} = {{E}_{av} ( \frac{2 η {E}_{b}}{{N}_{0}} )}^{- 1} = 341 {{A}^{2} ( \frac{2 \times 3.5 \times {E}_{b}}{{N}_{0}} )}^{- 1} \\ = 48.7 {{A}^{2} ( \frac{{E}_{b}}{{N}_{0}} )}^{- 1}\end{matrix} \qquad ( 103 )$$

This is identical to the variance for 1024 QAM scheme.

The puncturing and mapping scheme shown in Table 21 is for 14 consecutive information bits that are coded into 20 coded bits, therefore, two 1024 QAM symbols. The turbo encoder is a rate 7/10 turbo code, which in conjunction with 1024 QAM, gives a spectral efficiency of 7 bits/s/Hz.

10.4 Bit Probabilities

The 32 AM symbol is defined as u^{k}=(u₁^{k}, u₂^{k}, u₃^{k}, u₄^{k}, u₅^{k}), where u₁^{k} is the most significant bit and u₅^{k} is the least significant bit. The following set can be defined.

1. bit-1-is-0={A₀, A₂, A₃, A₄, A₅, A₆, A₇, A₈, A₉, A₁₀, A₁₁, A₁₂, A₁₃, A₁₄, A₁₅}

2. bit-1-is-1={A₁₆, A₁₇, A₁₈, A₁₉, A₂₀, A₂₁, A₂₂, A₂₃, A₂₄, A₂₅, A₂₆, A₂₇, A₂₈, A₂₉, A₃₀, A₃₁}

3. bit-2-is-0={A₀,A₁, A₂, A₃, A₄, A₅, A₆, A₇, A₁₆, A₁₇, A₁₈, A₁₉, A₂₀, A₂₁, A₂₂, A₂₃}

4. bit-2-is-1={A₈, A₉, A₁₀, A₁₁, A₁₂, A₁₃, A₁₄, A₁₅, A₂₄, A₂₅, A₂₆, A₂₇, A₂₈, A₂₉, A₃₀, A₃₁}

5. bit-3-is-0={A₀, A₁, A₂, A₃, A₈, A₉, A₁₀, A₁₁, A₁₆, A₁₇, A₁₈, A₁₉, A₂₄, A₂₅, A₂₆, A₂₇}

6. bit-3-is-1={A₄, A₅, A₆, A₇, A₁₂, A₁₃, A₁₄, A₁₅, A₂₀, A₂₁, A₂₂, A₂₃, A₂₈, A₂₉, A₃₀, A₃₁}

7. bit-4-is-0={A₀, A₁, A₄, A₅, A₈, A₉, A₁₂, A₁₃, A₁₆, A₁₇, A₂₀, A₂₁, A₂₄, A₂₅, A₂₈, A₂₉}

8. bit-4-is-1={A₂, A₃, A₆, A₇, A₁₀, A₁₁, A₁₄, A₁₅, A₁₈, A₁₉, A₂₂, A₂₃, A₂₆, A_{27, A}₃₀, A₃₁}

9. bit-5-is-0={A₀, A₂, A₄, A₆, A₈, A₁₀, A₁₂, A₁₄, A₁₆, A₁₈, A₂₀, A₂₂, A₂₄, A₂₆, A₂₈, A₃₀}

10. bit-5-is-1={A₁, A₃, A₅, A₇, A₉, A₁₁, A₁₃, A₁₅, A₁₇, A₁₉, A₂₁, A₂₃, A₂₅, A₂₇, A₂₉, A₃₁}

From each received symbol, R^{k}, the bit probabilities are computed as follows:

$$\begin{matrix}LLR ( {u}_{1}^{k} ) = log ( \frac{{\sum }_{{A}_{i} ∈ bit - 1 - is - 1} exp ( - \frac{1}{2 {σ}_{N}^{2}} ‖ {R}^{k} - {A}_{i} ‖ )}{{\sum }_{{A}_{i} ∈ bit - 1 - is - 0} exp ( - \frac{1}{2 {σ}_{N}^{2}} ‖ {R}^{k} - {A}_{j} ‖ )} ) & ( 104 ) \\ LLR ( {u}_{2}^{k} ) = log ( \frac{{\sum }_{{A}_{i} ∈ bit - 2 - is - 1} exp ( - \frac{1}{2 {σ}_{N}^{2}} ‖ {R}^{k} - {A}_{i} ‖ )}{{\sum }_{{A}_{i} ∈ bit - 2 - is - 0} exp ( - \frac{1}{2 {σ}_{N}^{2}} ‖ {R}^{k} - {A}_{j} ‖ )} ) & ( 105 ) \\ LLR ( {u}_{3}^{k} ) = log ( \frac{{\sum }_{{A}_{i} ∈ bit - 3 - is - 1} exp ( - \frac{1}{2 {σ}_{N}^{2}} ‖ {R}^{k} - {A}_{i} ‖ )}{{\sum }_{{A}_{i} ∈ bit - 3 - is - 0} exp ( - \frac{1}{2 {σ}_{N}^{2}} ‖ {R}^{k} - {A}_{j} ‖ )} ) & ( 106 ) \\ LLR ( {u}_{4}^{k} ) = log ( \frac{{\sum }_{{A}_{i} ∈ bit - 4 - is - 1} exp ( - \frac{1}{2 {σ}_{N}^{2}} ‖ {R}^{k} - {A}_{i} ‖ )}{{\sum }_{{A}_{i} ∈ bit - 4 - is - 0} exp ( - \frac{1}{2 {σ}_{N}^{2}} ‖ {R}^{k} - {A}_{j} ‖ )} ) & ( 107 ) \\ LLR ( {u}_{5}^{k} ) = log ( \frac{{\sum }_{{A}_{i} ∈ bit - 5 - is - 1} exp ( - \frac{1}{2 {σ}_{N}^{2}} ‖ {R}^{k} - {A}_{i} ‖ )}{{\sum }_{{A}_{i} ∈ bit - 5 - is - 0} exp ( - \frac{1}{2 {σ}_{N}^{2}} ‖ {R}^{k} - {A}_{j} ‖ )} ) & ( 108 )\end{matrix}$$

10.5 Simulation Results

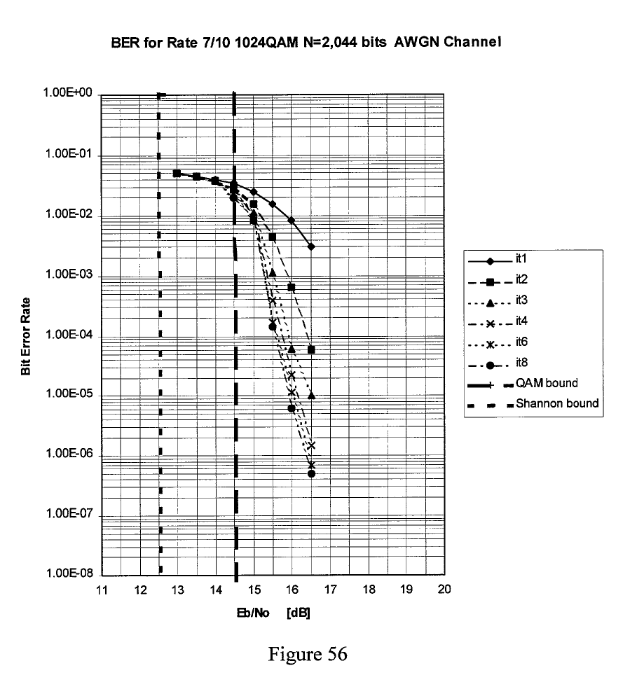

FIG. 56 shows the simulation results for 2,044 information bits with S-type interleaver.

A search for the best S-type interleaver was performed. For each interleaver size, the maximum S-factor was found and four different interleavers were generated using a random seed. Four simulations were generated for a target BER of 10⁻⁵. The best result decided the preferred interleaver. Using the preferred interleaver, complete simulations were started for BER down to 10⁻⁷.

A BER of 10⁻⁷ can be achieved after 8 iterations at E_{b}/N_{O}=17 dB.

10.6 Recommended Solution

The recommended solution for 7 bit/s/Hz spectral efficiency is the rate 7/10 turbo code 1024 QAM scheme. This scheme achieves a BER of 10⁻⁷ at E_{b}/N_{O}=17 dB for N=2044 information bits.

11. Coding and Modulation for 12 bit/Hz Spectral Efficiency

This section investigated one scheme that use independent I and Q modulation. The scheme combines a rate 12/14 coding scheme with 16384 QAM.

11.1 Coding

The coding scheme is shown in FIG. 3. The two systematic recursive codes (SRC) used are identical and are defined in FIG. 4. The code is described by the generating polynomials 35o and 23o.

11.2 Puncturing

In accordance with an embodiment of the invention, in order to obtain a rate 12/14 code, the puncturing pattern used is shown in Table 22.

TABLE 22
Puncturing and Mapping for Rate 12/14 16384 QAM

| | | | | | | | | | | | | |
|---|---|---|---|---|---|---|---|---|---|---|---|---|
| Information bit | d₁ | d₂ | d₃ | d₄ | d₅ | d₆ | d₇ | d₈ | d₉ | d₁₀ | d₁₁ | d₁₂ |
| (d) | | | | | | | | | | | | |
| parity bit (p) | p1 | — | — | — | — | — | — | — | — | — | — | — |
| parity bit (q) | — | — | — | — | — | — | q7 | — | — | — | — | — |

| | |
|---|---|
| 128 AM | (d₁, d₂, d₃, d₄ d₅, d₆, p1) |
| symbol (I) | |
| 128 AM | (d₇, d₈, d₉, d₁₀, d₁₁, d₁₂, q7) |
| symbol (Q) | |
| 16384 QAM | (d₁, d₂, d₃, d₄ d₅, d₆, p1, |
| symbol (I, Q) | d₇, d₈, d₉, d₁₀, d₁₁, d₁₂, q7) |

11.3 Modulation

For a 16384 QAM constellation with points at −127A, −125A, −123A, −121A, −119A, −117A, −115A, −113A, −111A, −109A, −107A, −105A, −103A, −101A, −99A, −97A, −95A, −93A, −91A, −89A, −87A, −85A, −83A, −81A, −79A, −77A, −75A, −73A, −71A, −69A, −67A, −65A, −63A, −61A, −59A, −57A, −55A, −53A, −51A, −49A, −47A, −45A, −43A, −41A, −39A, −37A, −35A, −33A, −31A, −29A, −27A, −25A, −23A, −21A, −19A, −17A, −15A, −13A, −11A, −9A, −7A, −5A, −3A, −A, A, 3A, 5A, 7A, 9A, 11A, 13A, 15A, 17A, 19A, 21A, 23A, 25A, 27A, 29A, 31A, 33A, 35A, 37A, 39A, 41A, 43A, 45A, 47A, 49A, 51A, 53A, 55A, 57A, 59A, 61A, 63A, 65A, 67A, 69A, 71A, 73A, 75A, 77A, 79A, 81A, 83A, 95A, 87A, 89A, 91A, 93A, 95A, 97A, 99A, 101A, 103A, 105A, 107A, 109A, 111A, 113A, 115A, 117A, 119A, 121A, 123A, 125A, 127A. Eₐᵥ is:

Eₐᵥ=5461A² (109)

It is assumed that at time k the symbol u^{k}=(u₁^{k}, u₂^{k}, u₃^{k}, u₄^{k}, u₅^{k}, u₆^{k}, u₇^{k, u}₈^{k}, u₉^{k}, u₁₀^{k}, u₁₁^{k}, u₁₂^{k}, u₁₃^{k}, u₁₄^{k}) is sent though the channel. It is assumed that at time k the symbol u₁^{k}, u₂^{k}, u₃^{k}, u₄^{k}, u₅^{k}, u₆^{k} and u₇^{k} modulates the I component and u₈^{k}, u₉^{k}, u₁₀^{k}, u₁₁^{k}, u₁₂^{k}, u₁₃^{k}, u₁₄^{k}, modulates the Q component of a 16384 QAM scheme.

For a rate 12/14 code and 16384 QAM, the noise variance is:

$$\begin{matrix}{σ}_{N}^{2} = {{E}_{av} ( \frac{2 η {E}_{b}}{{N}_{0}} )}^{- 1} = 5461 {{A}^{2} ( \frac{2 \times 6 \times {E}_{b}}{{N}_{0}} )}^{- 1} \\ = 455.08 {{A}^{2} ( \frac{{E}_{b}}{{N}_{0}} )}^{- 1}\end{matrix} \qquad ( 110 )$$

In order to study the performance of this scheme, a rate 6/7 turbo code and a 128AM is used. The 16384 QAM scheme will achieve a similar performance in terms of bit error rate (BER) at twice the spectral efficiency, assuming an ideal demodulator. The puncturing and mapping scheme shown in Table 22 is for 12 consecutive information bits that are coded into 14 encoded bits, therefore, one 16384 QAM symbol. The turbo encoder is a rate 12/14 turbo code, which in conjunction with 16384 QAM, gives a spectral efficiency of 12 bits/s/Hz.

11.4 Bit Probabilities

The 128AM symbol is defined as u^{k}=(u₁^{k}, u₂^{k}, u₃^{k}, u₄^{k}, u₅^{k}, u₆^{k}, u₇^{k}), where u₁^{k} is the most significant bit and u₇^{k} is the least significant bit. The following set can be defined.

1. bit-1-is-1={A₆₄, A₆₅, A₆₆, A₆₇, A₆₈, A₆₉, A₇₀, A₇₁, A₇₂, A₇₃, A₇₄, A₇₅, A₇₆, A₇₇, A₇₈, A₇₉, A₈₀, A₈₁, A₈₂, A₈₃, A₈₄, A₈₅, A₈₆, A₈₇, A₈₈, A₈₉, A₉₀, A₉₁, A₉₂, A₉₃, A₉₄, A₉₅, A₉₆, A₉₇, A₉₈, A₉₉, A₁₀₀, A₁₀₁, A₁₀₂, A₁₀₃, A₁₀₄, A₁₀₅, A₁₀₆, A₁₀₇, A₁₀₈, A₁₀₉, A₁₁₀, A₁₁₁, A₁₁₂, A₁₁₃, A₁₁₄, A₁₁₅, A₁₁₆, A₁₁₇, A₁₁₈, A₁₁₉, A₁₂₀, A₁₂₁, A₁₂₂, A₁₂₃, A₁₂₄, A₁₂₅, A₁₂₆, A₁₂₇,}

2. bit-2-is-1={A₃₂, A₃₃, A₃₄, A₃₅, A₃₆, A₃₇, A₃₈, A₃₉, A₄₀, A₄₁, A₄₂, A₄₃, A₄₄, A₄₅, A₄₆, A₄₇, A₄₈, A₄₉, A₅₀, A₅₁, A₅₂, A₅₃, A₅₄, A₅₅, A₅₆, A₅₇, A₅₈, A₅₉, A₆₀, A₆₁, A₆₂, A₆₃, A₆₄, A₆₅, A₆₆, A₆₇, A₆₈, A₆₉, A₇₀, A₇₁, A₇₂, A₇₃, A₇₄, A₇₅, A₇₆, A₇₇, A₇₈, A₇₉, A₈₀, A₈₁, A₈₂, A₈₃, A₈₄, A₈₅, A₈₆, A₈₇, A₈₈, A₈₉, A₉₀, A₉₁, A₉₂, A₉₃, A₉₄, A₉₅,}

3. bit-3-is-1={A₁₆, A₁₇, A₁₈, A₁₉, A₂₀, A₂₁, A₂₂, A₂₃, A₂₄, A₂₅, A₂₆, A₂₇, A₂₈, A₂₉, A₃₀, A₃₁, A₃₂, A₃₃, A₃₄, A₃₅, A₃₆, A₃₇, A₃₈, A₃₉, A₄₀, A₄₁, A₄₂, A₄₃, A₄₄, A₄₅, A₄₆, A₄₇, A₈₀, A₈₁, A₈₂, A₈₃, A₈₄, A₈₅, A₈₆, A₈₇, A₈₈, A₈₉, A₉₀, A₉₁, A₉₂, A₉₃, A₉₄, A₉₅, A₉₆, A₉₇, A₉₈, A₉₉, A₁₀₀, A₁₀₁, A₁₀₂, A₁₀₃, A₁₀₄, A₁₀₅, A₁₀₆, A₁₀₇, A₁₀₈, A₁₀₉, A₁₁₀, A₁₁₁,}

4. bit-4-is-1={A₈, A₉, A₁₀, A₁₁, A₁₂, A₁₃, A₁₄, A₁₅, A₁₆, A₁₇, A₁₈, A₁₉, A₂₀, A₂₁, A₂₂, A₂₃, A₄₀, A₄₁, A₄₂, A₄₃, A₄₄, A₄₅, A₄₆, A₄₇, A₄₈, A₄₉, A₅₀, A₅₁, A₅₂, A₅₃, A₅₄, A₅₅, A₇₂, A₇₃, A₇₄, A₇₅, A₇₆, A₇₇, A₇₈, A₇₉, A₈₀, A₈₁, A₈₂, A₈₃, A₈₅, A₈₆, A₈₇, A₁₀₄, A₁₀₅, A₁₀₆, A₁₀₇, A₁₀₈, A₁₀₉, A₁₁₀, A₁₁₁, A₁₁₂, A₁₁₃, A₁₁₄, A₁₁₅, A₁₁₆, A₁₁₇, A₁₁₈, A₁₁₉,}

5. bit-5-is-1={A₄, A₅, A₆, A₇, A₈, A₉, A₁₀, A₁₁, A₂₀, A₂₁, A₂₂, A₂₃, A₂₄, A₂₅, A₂₆, A₂₇, A₃₆, A₃₇, A₃₈, A₃₉, A₄₀, A₄₁, A₄₂, A₄₃, A₅₂, A₅₃, A₅₄, A₅₅, A₅₆, A₅₇, A₅₈, A₅₉, A₆₈, A₆₉, A₇₀, A₇₁, A₇₂, A₇₃, A₇₄, A₇₅, A₈₄, A₈₅, A₈₆, A₈₇, A₈₈, A₈₉, A₉₀, A₉₁, A₁₀₀, A₁₀₁, A₁₀₂, A₁₀₃, A₁₀₄, A₁₀₅, A₁₀₆, A₁₀₇, A₁₁₆, A₁₁₇, A₁₁₈, A₁₁₉, A₁₂₀, A₁₂₁, A₁₂₂, A₁₂₃,}

6. bit-6-is-1={A₀, A₁, A₆, A₇, A₈, A₉, A₁₄, A₁₅, A₁₆, A₁₇, A₂₂, A₂₃, A₂₄, A₂₅, A₃₀, A₃₁, A₃₂, A₃₃, A₃₈, A₃₉, A₄₀, A₄₁, A₄₆, A₄₇, A₄₈, A₄₉, A₅₄, A₅₅, A₅₆, A₅₇, A₆₂, A₆₃, A₆₄, A₆₅, A₇₀, A₇₁, A₇₂, A₇₃, A₇₈, A₇₉, A₈₀, A₈₁, A₈₆, A₈₇, A₈₈, A₈₉, A₉₄, A₉₅, A₉₆, A₉₇, A₁₀₂, A₁₀₃, A₁₀₄, A₁₀₅, A₁₁₀, A₁₁₁, A₁₁₂, A₁₁₃, A₁₁₈, A₁₁₉, A₁₂₀, A₁₂₁, A₁₂₆, A₁₂₇,}

7. bit-7-is-1={A₁, A₂, A₅, A₆, A₉, A₁₀, A₁₃, A₁₄, A₁₇, A₁₈, A₂₁, A₂₂, A₂₅, A₂₆, A₂₉, A₃₀, A₃₃, A₃₄, A₃₇, A₃₈, A₄₂, A₄₅, A₄₆, A₄₉, A₅₀, A₅₃, A₅₄, A₅₇, A₅₈, A₆₁, A₆₂, A₆₅, A₆₆, A₆₉, A₇₀, A₇₃, A₇₄, A₇₇, A₇₈, A₈₁, A₈₂, A₈₅, A₈₆, A₈₉, A₉₀, A₉₃, A₉₄, A₉₇, A₉₈, A₁₀₁, A₁₀₂, A₁₀₅, A₁₀₆, A₁₀₉, A₁₁₀, A₁₁₃, A₁₁₄, A₁₁₇, A₁₁₈, A₁₂₁, A₁₂₂, A₁₂₅, A₁₂₆,}

From each received symbol, R^{k}, the bit probabilities are computed as follows:

$$LLR ( {u}_{n}^{k} ) = log ( \frac{{\sum }_{{A}_{i} ∈ bit - n - is - 1} exp ( - \frac{1}{2 {σ}_{N}^{2}} ‖ {R}^{k} - {A}_{i} ‖ )}{{\sum }_{{A}_{i} ∈ bit - n - is - 0} exp ( - \frac{1}{2 {σ}_{N}^{2}} ‖ {R}^{k} - {A}_{j} ‖ )} ) \qquad ( 111 )$$

11.5 Simulation Results

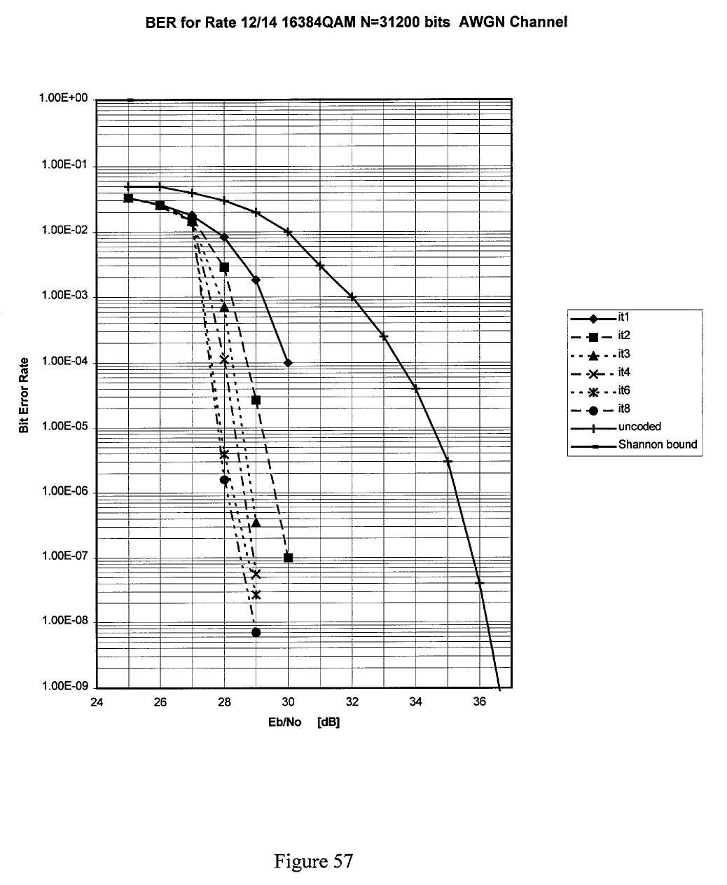

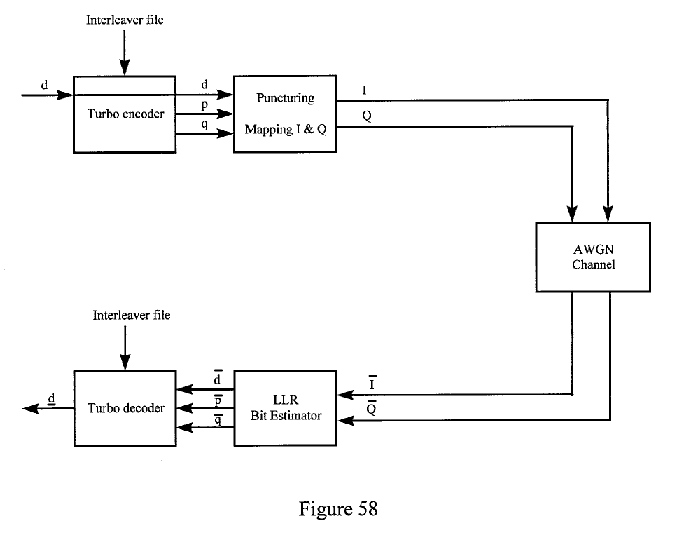

FIG. 57 shows the simulation results for 31200 information bits. A BER of 10⁻⁷ can be achieved after 8 iterations at E_{b}/N_{O}=28.25 dB.

12. Power vs. Bandwidth in an AWGN Channel

This section gives an estimate of the trade off which can be achieved between minimum required E_{b}/N_{O} and bandwidth efficiency. An information data rate of 2,044 Mbit/s and a maximum transmitter delay of 1 ms is considered. The corresponding interleaver size is 2,044 bits.

12.1 Channel Model

All the simulations assumed the additive white Gaussian noise (AWGN) channel model, with independent I and Q signal. A block diagram of the system is shown in FIG. 57.

12.2 Simulation Results

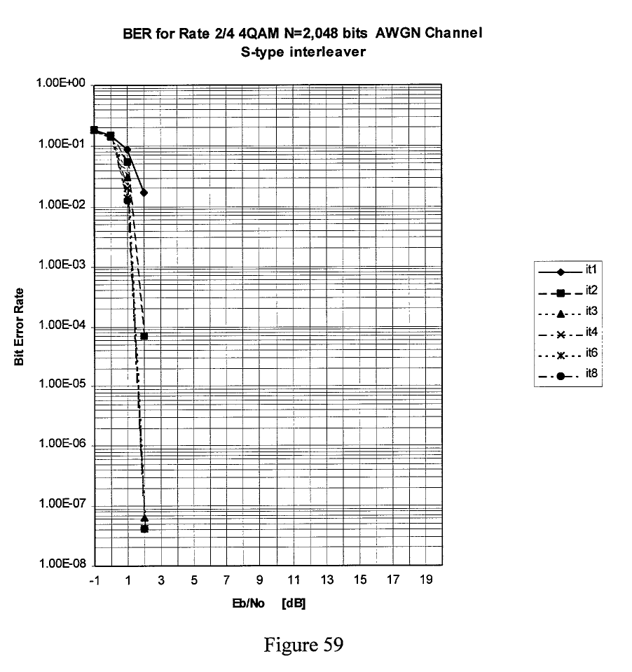

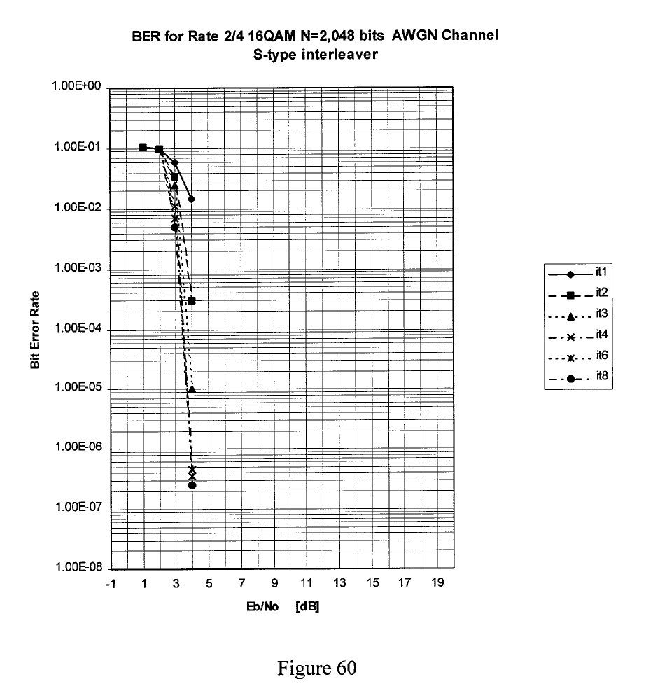

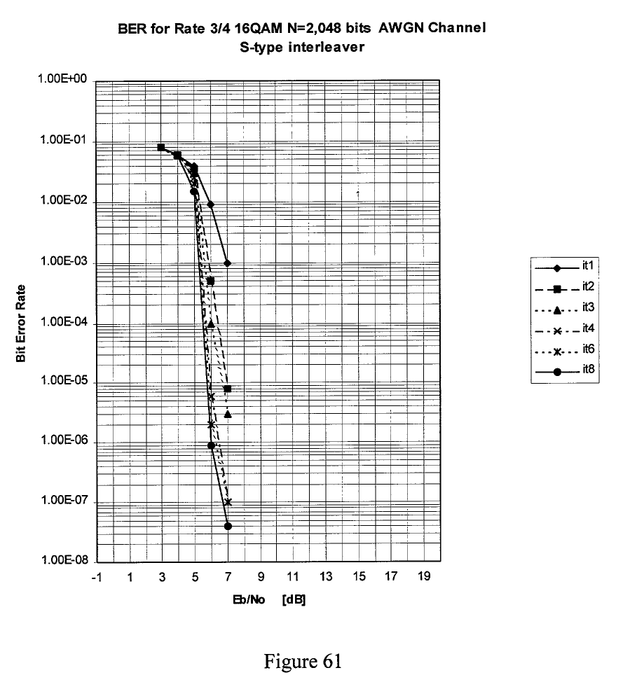

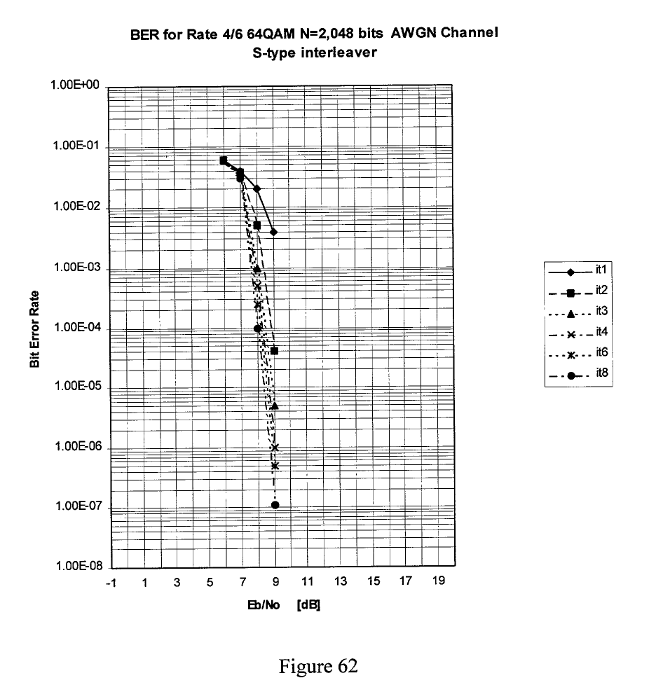

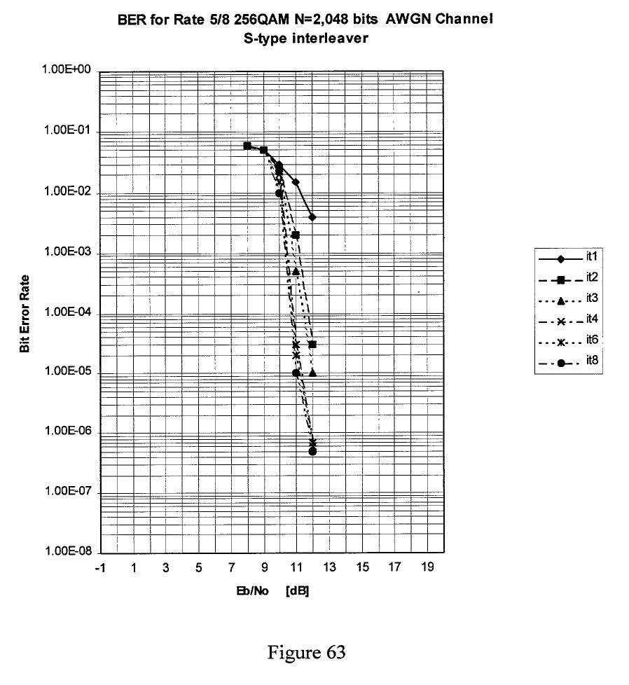

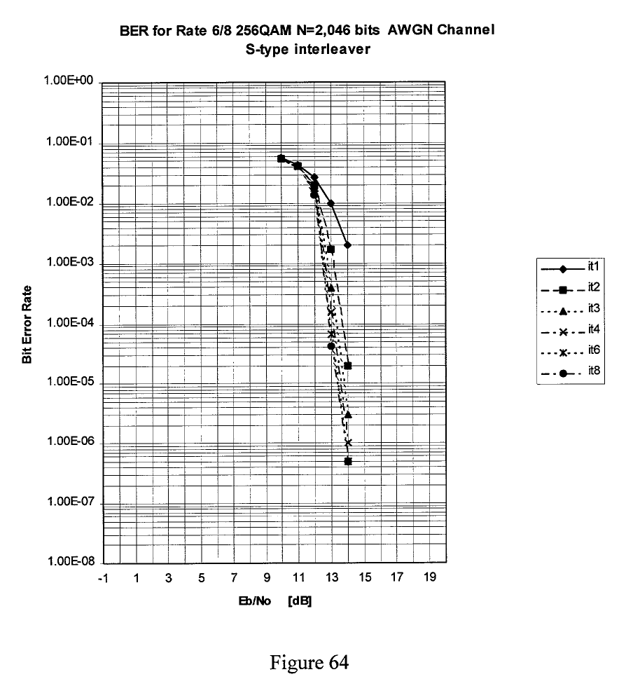

Simulations were run for bandwidth efficiencies from 1 to 7 bit/symbol using the recommended coding and modulation schemes. The results are shown in FIGS. 58 to 64.

12.3 Conclusions

Table 23 summarizes the minimum E_{b}/N_{O} required to achieve a BER of 10⁻⁷.

TABLE 23
Minimum E_{b}/N₀ required to achieve a BER of 10⁻⁷

| Spectral | Coding Rate | | E_{b}/N₀ |
|---|---|---|---|
| efficiency η | and | Symbol Rate | For BER = 10⁻⁷ |
| [bits/s/Hz] | Modulation | [ksym/s] | [dB] |
| 1 | 2/4 and 4 QAM | 2048 | 2.2 |
| 2 | 2/4 and 16 QAM | 1024 | 4.2 |
| 3 | 3/4 and 16 QAM | 682 | 6.5 |
| 4 | 4/6 and 64 QAM | 512 | 9.1 |
| 5 | 5/8 and 256 QAM | 408 | 12.3 |
| 6 | 6/8 and 256 QAM | 342 | 14.5 |
| 7 | 7/10 and 1024 QAM | 292 | 17.0 |

The results show the potential reduction in bandwidth for a given signal-to-noise ration for a particular channel. If an E_{b}/N_{O} of 17 dB or more is available, the symbol rate can be reduced from 2048 ksym/s to 292 ksym/s.

13. Channel Simulation

In this paragraph we show numerical results of the simulations for the AWGN and Impulsive nose using or not and outer Reed-Solomon encoder.

13.1 Without outer Reed-Solomon Encoder

13.1.1 Net Coding Gain

The net coding gain of the spectral efficiency of 4 bit/tone and 12 bits per tone, protecting more the information bits than the parity bits is as shown in Table 24. The case that the parity bits are more protected than the information bits is shown in table 25. for a BER greater than 10⁻⁸ the net coding gain is 0.5 dB worse. For BER below 10⁻⁸ the coding gain improves respect the case that the information bits are more protected.

TABLE 24
Net Coding Gain Information bits more protected

| | | | | Latency | | | |
|---|---|---|---|---|---|---|---|
| | | Inter- | | (Tx + Rx) | | | |
| Bit/ | | leaver | # of DMT | ms | | | 10⁻⁹ |
| Tone | Tones | Size | symbols | < | 10⁻³ | 10⁻⁷ | extrap. |
| 4 | 100 | 5,200 | 13 | 10.0 | 4.60 | 7.42 | 7.94 |
| | | 800 | 2 | 1.5 | 3.70 | 4.92 | 4.84 |
| | | 400 | 1 | 0.7 | 3.30 | 3.62 | 3.84 |
| | 200 | 10,400 | 13 | 10.0 | 4.60 | 7.52 | 8.14 |
| | | 1,600 | 2 | 1.5 | 4.10 | 6.42 | 6.64 |
| | | 800 | 1 | 0.7 | 3.70 | 4.92 | 4.84 |
| 12 | 100 | 15,600 | 13 | 10.0 | 4.10 | 5.91 | 6.03 |
| | | 2,400 | 2 | 1.5 | 3.60 | 5.51 | 5.63 |
| | | 1,200 | 1 | 0.7 | 3.00 | 3.91 | 4.03 |
| | 200 | 31,200 | 13 | 10.0 | 4.10 | 6.81 | 7.53 |
| | | 4,800 | 2 | 1.5 | 3.60 | 5.91 | 6.43 |
| | | 2,400 | 1 | 0.7 | 3.60 | 5.51 | 5.63 |

TABLE 25
Net Coding Gain parity more protected

| | | | | Latency | | | |
|---|---|---|---|---|---|---|---|
| | | Inter- | | (Tx + Rx) | | | |
| Bit/ | | leaver | # of DMT | ms | | | 10⁻⁹ |
| Tone | Tones | Size | symbols | < | 10⁻³ | 10⁻⁷ | extrap. |
| 4 | 100 | 5,200 | 13 | 10.0 | 4.10 | 7.22 | 8.04 |
| | | 800 | 2 | 1.5 | 3.20 | 4.72 | 5.04 |
| | | 400 | 1 | 0.7 | 2.80 | 3.42 | 4.04 |
| | 200 | 10,400 | 13 | 10.0 | 4.10 | 7.32 | 8.24 |
| | | 1,600 | 2 | 1.5 | 3.60 | 6.22 | 6.84 |
| | | 800 | 1 | 0.7 | 3.20 | 4.72 | 5.04 |
| 12 | 100 | 15,600 | 13 | 10.0 | 3.60 | 5.71 | 6.23 |
| | | 2,400 | 2 | 1.5 | 3.10 | 5.31 | 5.83 |
| | | 1,200 | 1 | 0.7 | 2.50 | 3.71 | 4.23 |
| | 200 | 31,200 | 13 | 10.0 | 3.60 | 6.61 | 7.73 |
| | | 4,800 | 2 | 1.5 | 3.10 | 5.71 | 6.63 |
| | | 2,400 | 1 | 0.7 | 3.10 | 5.31 | 5.83 |

13.1.2 Errors due to Impulse noise (IN)

The impulse noise is defined as 2 consecutive DMT symbols with an increase AWGN respect to the reference noise level 10⁻⁷ a carrier-to-noise ratio of 21.5 dB (spectral efficiency of 4 bit/tone) and 45.5 dB (spectral efficiency of 12 bit/tone).

Table 26 shows the numerical results in the case that the information bits are more protected than the parity bits. Table 27 shows the numerical results in the case that the parity bits are more protected than the information bits.

TABLE 26
Error due to Impulse Noise. Information bits more protected

| Bit/ | | Interleaver | RL + | RL + | RL + | RL + | RL + | RL + | RL + | RL + |
|---|---|---|---|---|---|---|---|---|---|---|
| Tone | Tones | Size | 2.5 dB | 5 dB | 7.5 dB | 10 dB | 12.5 dB | 15 dB | 17.5 dB | 20d B |
| 4 | 100 | 5,200 | 0 | 0 | 0 | 0 | 0 | 0 | 0 | 4 |
| | | 800 | 0 | 0 | 39 | 65 | 104 | 140 | 188 | 243 |
| | | 400 | 0 | 0 | 10 | 50 | 89 | 127 | 161 | 214 |
| | 200 | 10,400 | 0 | 0 | 0 | 0 | 0 | 0 | 0 | 7 |
| | | 1,600 | 0 | 0 | 0 | 127 | 189 | 267 | 363 | 448 |
| | | 800 | 0 | 0 | 40 | 116 | 187 | 252 | 346 | 440 |
| 12 | 100 | 15,600 | 0 | 0 | 0 | 0 | 10 | 58 | 130 | 207 |
| | | 2,400 | 0 | 0 | 40 | 78 | 121 | 171 | 21 | 295 |
| | | 1,200 | 0 | 0 | 43 | 98 | 129 | 188 | 255 | 329 |
| | 200 | 31,200 | 0 | 0 | 0 | 0 | 90 | 175 | 313 | 482 |
| | | 4,800 | 0 | 0 | 75 | 177 | 254 | 341 | 462 | 608 |
| | | 2,400 | 0 | 0 | 80 | 166 | 244 | 345 | 457 | 598 |

TABLE 27
Error due to Impulse Noise. Parity bits more protected

| Bit/ | | Interleaver | RL + | RL + | RL + | RL + | RL + | RL + | RL + | RL + |
|---|---|---|---|---|---|---|---|---|---|---|
| Tone | Tones | Size | 10 dB | 15 dB | 20 dB | 25 dB | 30 dB | 35 dB | 40 dB | 45 dB |
| 4 | 100 | 5,200 | 0 | 0 | 0 | 0 | 0 | 0 | 0 | 2 |
| | | 800 | 0 | 0 | 0 | 45 | 84 | 100 | 118 | 143 |
| | | 400 | 0 | 0 | 0 | 20 | 69 | 87 | 101 | 114 |
| | 200 | 10,400 | 0 | 0 | 0 | 0 | 0 | 0 | 0 | 3 |
| | | 1,600 | 0 | 0 | 0 | 27 | 49 | 67 | 83 | 118 |
| | | 800 | 0 | 0 | 0 | 16 | 37 | 52 | 86 | 120 |
| 12 | 100 | 15,600 | 0 | 0 | 0 | 0 | 0 | 8 | 10 | 15 |
| | | 2,400 | 0 | 0 | 0 | 18 | 31 | 51 | 60 | 125 |
| | | 1,200 | 0 | 0 | 0 | 18 | 29 | 38 | 55 | 89 |
| | 200 | 31,200 | 0 | 0 | 0 | 0 | 0 | 15 | 33 | 43 |
| | | 4,800 | 0 | 0 | 0 | 0 | 24 | 41 | 52 | 68 |
| | | 2,400 | 0 | 0 | 0 | 16 | 24 | 34 | 45 | 59 |

13.1.3 Error Statistics

13.1.3.1 For AWGN

10 Table 28 shows the statistics of the errors for the case of protecting more the information bits, for a AWGN channel.

TABLE 28
Error Statistics for AWGN. Information bits more protected

| | | Interleaver | 1 consec. | 2 consec | 3 consec | 4 consec | 5 consec | 6 consec |
|---|---|---|---|---|---|---|---|---|
| Bit/Tone | Tones | Size | error | errors | errors | errors | errors | errors |
| 4 | 100 | 5,20 | 87.30% | 10.81% | 1.47% | 0.29% | 0.03% | 0.10% |
| | | 80 | 94.35% | 5.64% | 0.00% | 0.00% | 0.00% | 0.00% |
| | | 40 | 90.28% | 9.72% | 0.01% | 0.00% | 0.00% | 0.00% |
| | 200 | 10,40 | 89.90% | 8.63% | 1.21% | 0.20% | 0.06% | 0.00% |
| | | 1,60 | 97.94% | 2.06% | 0.00% | 0.00% | 0.00% | 0.00% |
| | | 80 | 90.28% | 9.72% | 0.01% | 0.00% | 0.00% | 0.00% |
| 12 | 100 | 15,60 | 99.79% | 0.21% | 0.00% | 0.00% | 0.00% | 0.00% |
| | | 2,40 | 98.72% | 1.28% | 0.00% | 0.00% | 0.00% | 0.00% |
| | | 1,20 | 97.94% | 2.06% | 0.00% | 0.00% | 0.00% | 0.00% |
| | 200 | 31,20 | 99.86% | 0.14% | 0.00% | 0.00% | 0.00% | 0.00% |
| | | 4,80 | 100.00% | 0.00% | 0.00% | 0.00% | 0.00% | 0.00% |
| | | 2,40 | 98.72% | 1.28% | 0.00% | 0.00% | 0.00% | 0.00% |

13.1.3.2 Impulse Noise

Table 29 shows the statistics of the errors for the case of protecting more the information bits for a Impulse noise channel.

TABLE 29
Error Statistics for Impulse noise. Information bits more protected

| | | Interleaver | 1 consec. | 2 consec | 3 consec | 4 consec | 5 consec | 6 consec |
|---|---|---|---|---|---|---|---|---|
| Bit/Tone | Tones | Size | error | errors | errors | errors | errors | errors |
| 4 | 100 | 5,20 | 100.00% | 0.00% | 0.00% | 0.00% | 0.00% | 0.00% |
| | | 80 | 75.97% | 18.99% | 18.99% | 3.36% | 0.84% | 0.84% |
| | | 40 | 79.89% | 17.24% | 1.72% | 1.15% | 0.00% | 0.00% |
| | 200 | 10,40 | 100.00% | 0.00% | 0.00% | 0.00% | 0.00% | 0.00% |
| | | 1,60 | 80.24% | 13.05% | 4.47% | 1.68% | 0.47% | 0.00% |
| | | 80 | 79.03% | 17.50% | 2.46% | 0.46% | 0.46% | 0.00% |
| 12 | 100 | 15,60 | 95.19% | 4.81% | 0.00% | 0.00% | 0.00% | 0.00% |
| | | 2,40 | 94.61% | 5.28% | 0.11% | 0.00% | 0.00% | 0.00% |
| | | 1,20 | 93.63% | 5.95% | 93.63% | 0.00% | 0.00% | 0.00% |
| | 200 | 31,20 | 93.25% | 6.65% | 0.00% | 0.00% | 0.00% | 0.00% |
| | | 4,80 | 94.89% | 4.95% | 0.16% | 0.00% | 0.00% | 0.00% |
| | | 2,40 | 94.59% | 5.36% | 0.06% | 0.00% | 0.00% | 0.00% |

It is interesting that for the large turbo decoders the impulse errors still tends to stay within the 2 DMT symbols. This implies a moderately large turbo coder of 5 ms follow by a convolutional interleaver/Reed Solomon of 10 ms should create both robust performance and good impulse resistance.

13.2 With Reed-Solomon

13.2.1 Net Coding Gain

The coding gain of the spectral efficiency of 4 bit/tone and 12 bits per tone, protecting more the information bits than the parity bits is as shown in Table 30. The net coding gain is shown in table 31.

TABLE 30
Coding Gain with Reed-Solomon and information bits more protected

| | | | | Latency | | | |
|---|---|---|---|---|---|---|---|
| | | Inter- | | (Tx + Rx) | | | |
| Bit/ | | leaver | # of DMT | ms | | | 10⁻⁹ |
| Tone | Tones | Size | symbols | < | 10⁻³ | 10⁻⁷ | extrap. |
| 4 | 100 | 5,200 | 13 | 10.0 | 5.00 | 8.62 | 9.64 |
| | | 800 | 2 | 1.5 | 3.50 | 7.12 | 8.44 |
| | | 400 | 1 | 0.7 | 3.50 | 6.42 | 7.44 |
| | 200 | 10,400 | 13 | 10.0 | 5.30 | 8.82 | 9.84 |
| | | 1,600 | 2 | 1.5 | 4.60 | 7.72 | 8.74 |
| | | 800 | 1 | 0.7 | 3.50 | 7.12 | 8.44 |
| 12 | 100 | 15,600 | 13 | 10.0 | 4.40 | 7.71 | 8.53 |
| | | 2,400 | 2 | 1.5 | 4.60 | 7.41 | 8.33 |
| | | 1,200 | 1 | 0.7 | 4.10 | 6.81 | 7.63 |
| | 200 | 31,200 | 13 | 10.0 | 4.40 | 7.71 | 8.53 |
| | | 4,800 | 2 | 1.5 | 4.40 | 7.21 | 8.13 |
| | | 2,400 | 1 | 0.7 | 4.60 | 7.41 | 8.33 |

TABLE 31
Coding Gain with Reed-Solomon and information bits more protected

| | | | | Latency | | | |
|---|---|---|---|---|---|---|---|
| | | Inter- | | (Tx + Rx) | | | |
| Bit/ | | leaver | # of DMT | ms | | | 10⁻⁹ |
| Tone | Tones | Size | symbols | < | 10⁻³ | 10⁻⁷ | extrap. |
| 4 | 100 | 5,200 | 13 | 10.0 | 3.42 | 7.04 | 8.06 |
| | | 800 | 2 | 1.5 | 1.78 | 5.40 | 6.72 |
| | | 400 | 1 | 0.7 | 1.94 | 4.86 | 5.88 |
| | 200 | 10,400 | 13 | 10.0 | 3.72 | 7.24 | 8.26 |
| | | 1,600 | 2 | 1.5 | 2.88 | 6.00 | 7.02 |
| | | 800 | 1 | 0.7 | 1.94 | 5.56 | 6.88 |
| 12 | 100 | 15,600 | 13 | 10.0 | 0.20 | 3.51 | 4.33 |
| | | 2,400 | 2 | 1.5 | 0.02 | 2.83 | 3.75 |
| | | 1,200 | 1 | 0.7 | −0.24 | 2.47 | 3.29 |
| | 200 | 31,200 | 13 | 10.0 | 1.06 | 4.37 | 5.19 |
| | | 4,800 | 2 | 1.5 | 0.76 | 3.57 | 4.49 |
| | | 2,400 | 1 | 0.7 | 0.26 | 3.07 | 3.99 |

13.2.2 Errors due to Impulse noise

The impulse noise is defined as 2 consecutive DMT symbols with an increase AWGN respect to the reference noise level 10⁻⁷ of a carrier-to-noise ratio of 21.5 dB (spectral efficiency of 4 bit/tone) and 45.5 dB (spectral efficiency of 12 bit/tone).

Table 32 shows the numerical results in the case that the information bits are more protected than the parity. Table 33 shows the numerical results in the case that the parity bits are more protected than the information bits.

TABLE 32
Error due to Impulse Noise. Information more protected

| Bit/ | | Interleaver | RL + | RL + | RL + | RL + | RL + | RL + | RL + | RL + |
|---|---|---|---|---|---|---|---|---|---|---|
| Tone | Tones | Size | 2.5 dB | 5 dB | 7.5 dB | 10 dB | 12.5 dB | 15 dB | 17.5 dB | 20 dB |
| 4 | 100 | 5,200 | 0 | 0 | 0 | 0 | 0 | 0 | 0 | 0 |
| | | 800 | 0 | 0 | 0 | 0 | 0 | 0 | 0 | 0 |
| | | 400 | 0 | 0 | 0 | 0 | 0 | 0 | 0 | 0 |
| | 200 | 10,400 | 0 | 0 | 0 | 0 | 0 | 0 | 0 | 0 |
| | | 1,600 | 0 | 0 | 0 | 0 | 0 | 0 | 0 | 0 |
| | | 800 | 0 | 0 | 0 | 0 | 0 | 0 | 0 | 0 |
| 12 | 100 | 15,600 | 0 | 0 | 0 | 0 | 10 | 58 | 130 | 207 |
| | | 2,400 | 0 | 0 | 0 | 0 | 0 | 0 | 0 | 0 |
| | | 1,200 | 0 | 0 | 0 | 0 | 0 | 0 | 0 | 0 |
| | 200 | 31,200 | 0 | 0 | 0 | 0 | 90 | 175 | 313 | 482 |
| | | 4,800 | 0 | 0 | 0 | 0 | 0 | 10 | 11 | 65 |
| | | 2,400 | 0 | 0 | 0 | 0 | 9 | 10 | 24 | 115 |

TABLE 33
Error due to Impulse Noise. Parity more protected

| Bit/ | | Interleaver | RL + | RL + | RL + | RL + | RL + | RL + | RL + | RL + |
|---|---|---|---|---|---|---|---|---|---|---|
| Tone | Tones | Size | 2.5 dB | 5 dB | 7.5 dB | 10 dB | 12.5 dB | 15 dB | 17.5 dB | 20 dB |
| 4 | 100 | 5,200 | 0 | 0 | 0 | 0 | 0 | 0 | 0 | 0 |
| | | 800 | 0 | 0 | 0 | 0 | 0 | 0 | 0 | 0 |
| | | 400 | 0 | 0 | 0 | 0 | 0 | 0 | 0 | 0 |
| | 200 | 10,400 | 0 | 0 | 0 | 0 | 0 | 0 | 0 | 0 |
| | | 1,600 | 0 | 0 | 0 | 0 | 0 | 0 | 0 | 0 |
| | | 800 | 0 | 0 | 0 | 0 | 0 | 0 | 0 | 0 |
| 12 | 100 | 15,600 | 0 | 0 | 0 | 0 | 0 | 0 | 0 | 0 |
| | | 2,400 | 0 | 0 | 0 | 0 | 0 | 0 | 0 | 0 |
| | | 1,200 | 0 | 0 | 0 | 0 | 0 | 0 | 0 | 0 |
| | 200 | 31,200 | 0 | 0 | 0 | 0 | 0 | 0 | 0 | 0 |
| | | 4,800 | 0 | 0 | 0 | 0 | 0 | 0 | 0 | 0 |
| | | 2,400 | 0 | 0 | 0 | 0 | 0 | 0 | 0 | 0 |

13.2.3 Error Statistics.

The statistics results obtained are practically the same than for the non Reed-Solomon case

14 Simulation using an analytical interleaver

In this section we present the same simulation of the previous section, but using an analytical interleaver.

The analytical interleaver proposed here is a helical odd-even smile interleaver.

This section gives an estimate of the trade off which can be achieved between minimum required E_{b}/N_{O} and bandwidth efficiency. An information data rate of 2,100 kbps and a maximum transmitter delay of 1 ms is considered. The corresponding interleaver size is 2,100 bits (multiple of 2, 4, 6, 10, 14).

14.1 Channel model

All the simulations assumed the additive white Gaussian noise (AWGN) channel model, with independent I and Q signals. A block diagram of the system is shown in FIG. 57.

14.2 Simulation Results

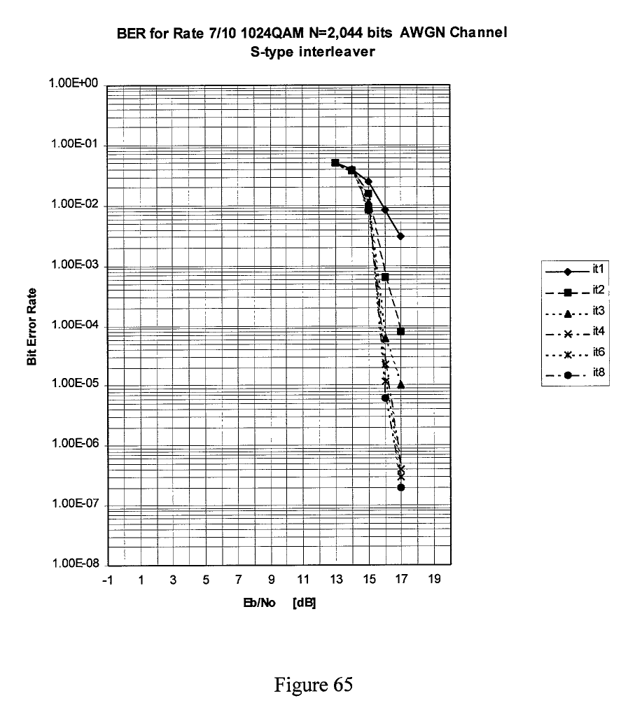

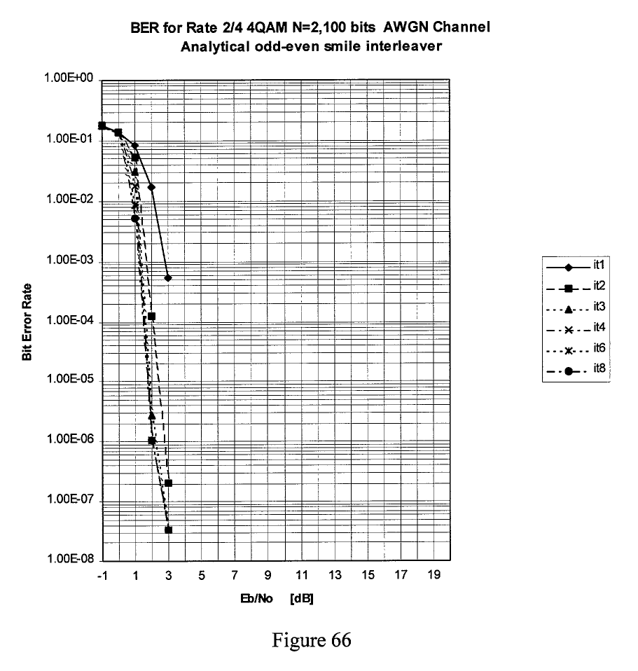

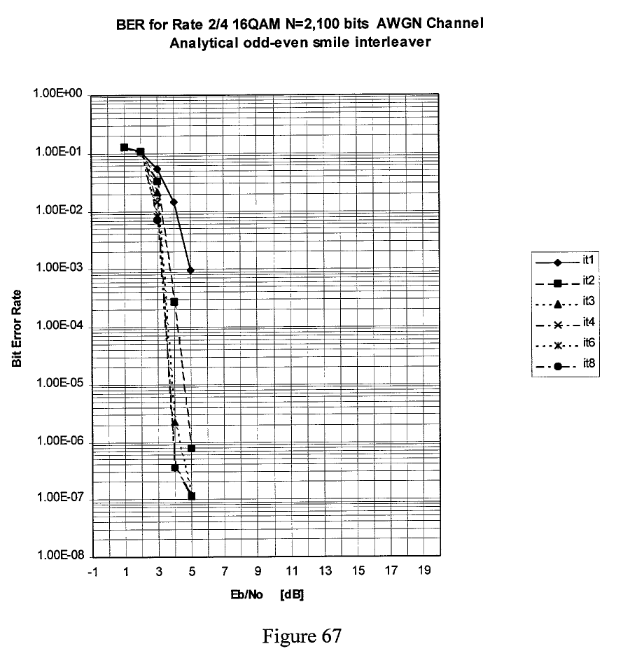

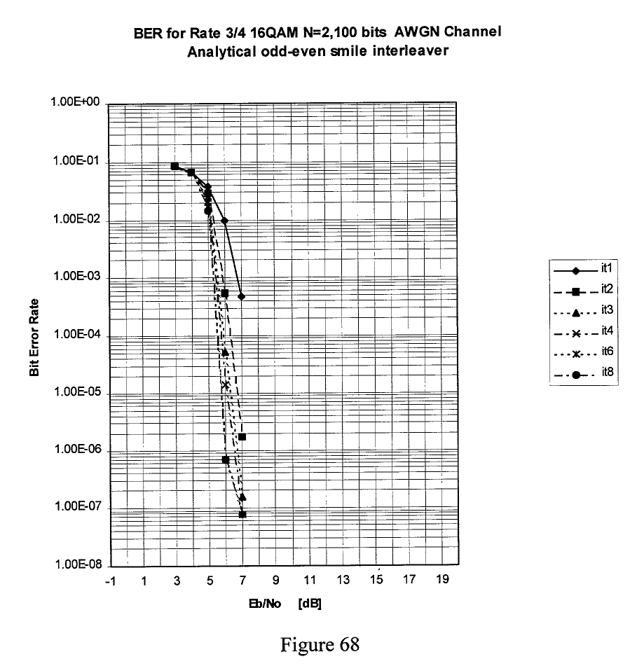

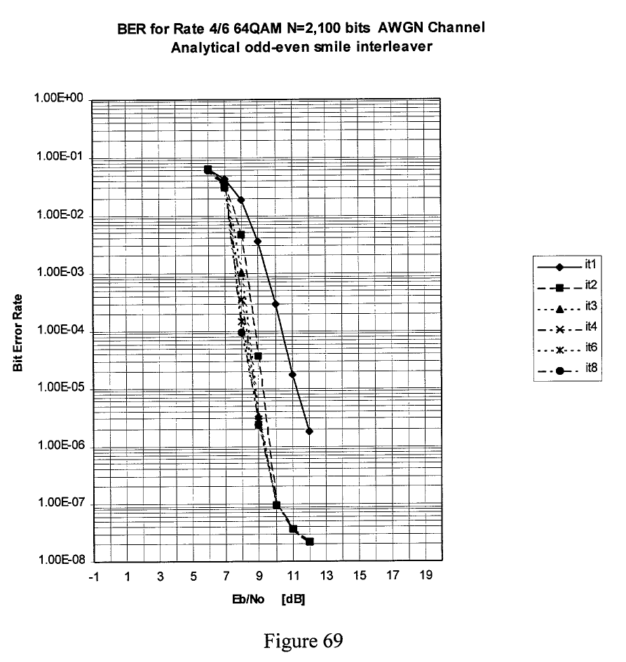

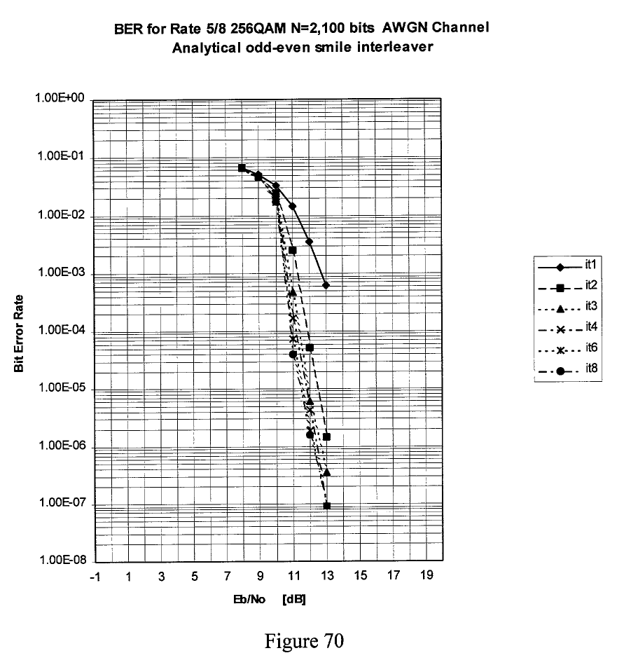

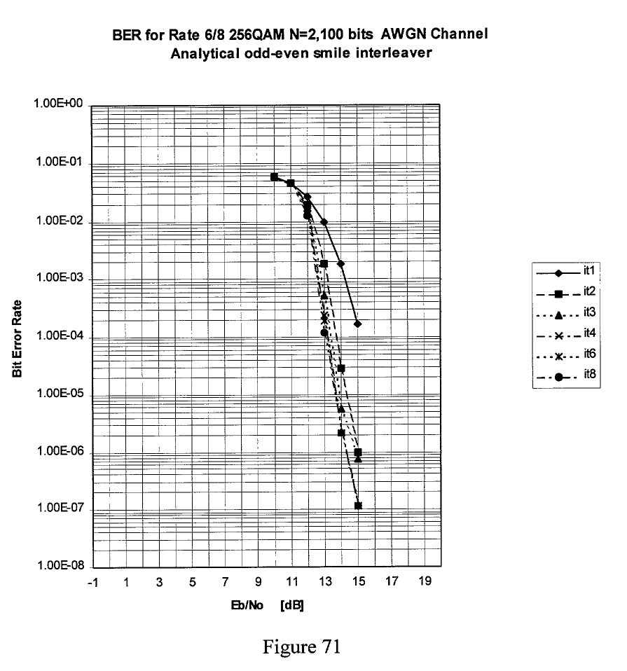

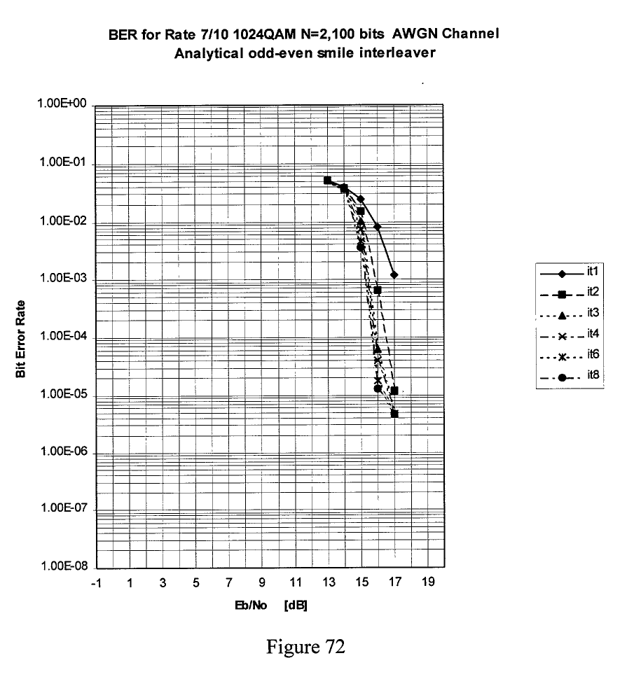

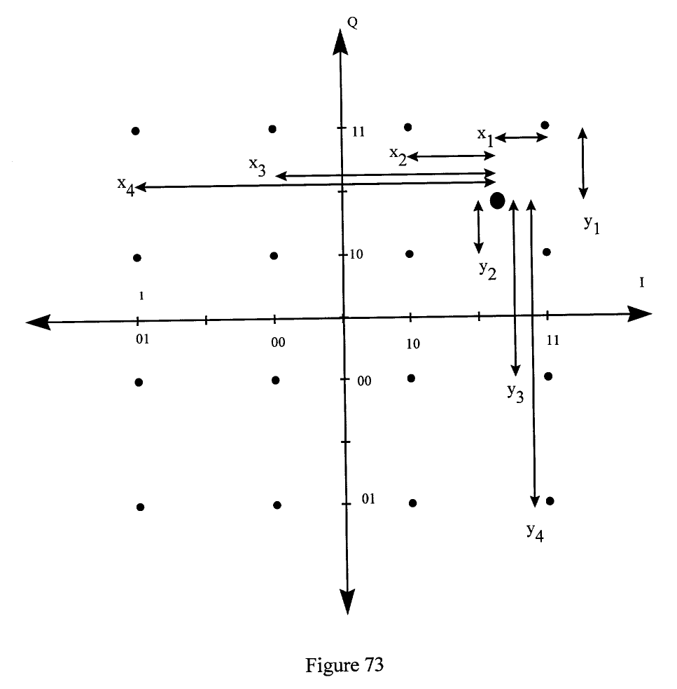

Simulations were run for bandwidth efficiencies from 1 to 7 bit/symbol using the recommended coding and modulation schemes. The results are shown in FIGS. 65 to 71.

14.3 Conclusions

Table 24 summarizes the minimum E_{b}/N_{O} required to achieve a BER of 10⁻⁷.

TABLE 24
Minimum E_{b}/N₀ required to achieve a BER of 10⁻⁷

| Spectral | Coding Rate | | E_{b}/N₀ |
|---|---|---|---|
| efficiency η | and | Symbol Rate | For BER = 10^{31 7} |
| [bits/s/Hz] | Modulation | [ksym/s] | [dB] |
| 1 | 2/4 and 4 QAM | 2048 | 2.7 |
| 2 | 2/4 and 16 QAM | 1024 | 4.7 |
| 3 | 3/4 and 16 QAM | 682 | 6.75 |
| 4 | 4/6 and 64 QAM | 512 | 9.6 |
| 5 | 5/8 and 256 QAM | 408 | 12.8 |
| 6 | 6/8 and 256 QAM | 342 | 15.0 |
| 7 | 7/10 and 1024 QAM | 292 | 17.5 |
| 12 | 12/14 and 16384 QAM | 170 | 28.5 |

The results show the potential reduction in bandwidth for a given signal-to-noise ration for a particular channel. If an E_{b}/N_{O} of 17 dB or more is available, the symbol rate can be reduced from 2048 ksym/s to 292 ksym/s.

Due to the savings in memory and the low degradation in this kind of interleaver for a BER of 10⁻⁶ below 0.5 dB, we recommend the use of this helical smile odd-even interleaver for these kind of applications.

1.5 Conclusions

TABLE 25
Summary of Simulation Results

| Spectral | | | Interleaver | Required | Required |
|---|---|---|---|---|---|
| efficiency | | | size In- | E_{b}/N₀ [dB] | E_{b}/N₀ [dB] |
| η | Coding | | formation | S-type | Analytical |
| [bits/s/Hz] | Rate | Modulation | bits | interleaver | interleaver |
| 2/3 | 2/6 | 4 QAM | 1,024 | 1.2 | 1.7 |
| 1 | 2/4 | 4 QAM | 1,024 | 2.1 | 2.6 |
| 2 | 4/6 | 8 QAM | 1,024 | 5.5 | 6.1 |
| 2 | 1/2 | 16 QAM | 256 | 6.8 | 7.2 |
| 2 | 1/2 | 16 QAM | 272 | 7.0 | 7.5 |
| 2 | 1/2 | 16 QAM | 512 | 5.3 | 5.8 |
| 2 | 1/2 | 16 QAM | 768 | 4.9 | 5.3 |
| 2 | 1/2 | 16 QAM | 1,024 | 4.5 | 5.0 |
| 2 | 1/2 | 16 QAM | 2,048 | 4.2 | 4.7 |
| 2 | 1/2 | 16 QAM | 32,728 | 2.9 | 3.3 |
| 3 | 3/4 | 16 QAM | 2,048 | 6.5 | 7.0 |
| 3 | 3/4 | 16 QAM | 6,144 | 5.6 | 6.1 |
| 3 | 3/5 | 32 QAM | 6,144 | 6.0 | 6.5 |
| 3 | 3/6 | 64 QAM | 6,144 | 6.1 | 6.6 |
| 4 | 4/6 | 64 QAM | 2,048 | 9.1 | 9.6 |
| 4 | 4/6 | 64 QAM-1 | 4,096 | 8.3 | 8.8 |
| 4 | 4/6 | 64 QAM-2 | 4,096 | 10.5 | 11.0 |
| 4 | 4/6 | 64 QAM-3 | 4,096 | 11.5 | 12.0 |
| 4 | 4/6 | 64 QAM-4 | 4,096 | 11.5 | 12.0 |
| 5 | 5/6 | 64 QAM | 5,120 | 13.0 | 13.5 |
| 5 | 5/7 | 128 QAM | 5,120 | 13.0 | 13.5 |
| 5 | 5/8 | 256 QAM | 2,048 | 12.3 | 12.8 |
| 5 | 5/8 | 256 QAM | 5,120 | 11.8 | 12.3 |
| 6 | 6/8 | 256 QAM | 2,048 | 14.5 | 15.0 |
| 6 | 6/8 | 256 QAM | 6,144 | 14.2 | 14.7 |
| 6 | 6/9 | 512 QAM | 6,144 | 14.5 | 15.0 |
| 7 | 7/10 | 1024 QAM | 2,044 | 17.0 | — |
| 12 | 12/14 | 16384 QAM | 31,200 | 28.0 | 28.5 |

16. Computational Complexity saving

To fix ideas lets use the 16 QAM case.

Using independent I and Q with the Gray mapping, the constellation will looks like the one shown in FIG. 13.

The conventional technique for extraction LLR soft-decision information from the channel is create a value representing the probability of the received symbol being a one as:

$$\frac{\begin{matrix}\sum of the measures \\ with the transmit symbol was 0\end{matrix}}{\begin{matrix}\sum of the measures \\ with the transmit symbol was 1\end{matrix}} \qquad ( 112 )$$

where the measure is defined as:

e^{(-n*metric)} (113)

where:

metric=Euclidian distance (or square of the Euclidian distance) from the possible transmit symbol to the received symbol.

In Figure Receiving the point x if we do not use an independent I and Q technique, we have to compute the 8 exponentials (4 in each dimension) that is the distance of the point x to the four point in the I dimension and to the 4 points in the Q dimension as shown (x1, x2, x3, x4, y1, y2, y3, y4). To compute the 4 LLR probabilities we need 4*14 adds and 4*16 multiplications and 4 divisions. The total number of operations is 132.

$$\begin{matrix}\frac{{\sum }_{bit = 1}}{{\sum }_{bit = 0}} = \frac{\begin{matrix}{e}^{( {x}_{1}^{2} + {y}_{1}^{2} )} + {e}^{( {x}_{1}^{2} + {y}_{2}^{2} )} + {e}^{( {x}_{1}^{2} + {y}_{3}^{2} )} + {e}^{( {x}_{1}^{2} + {y}_{4}^{2} )} + \\ {e}^{( {x}_{4}^{2} + {y}_{1}^{2} )} + {e}^{( {x}_{4}^{2} + {y}_{2}^{2} )} + {e}^{( {x}_{4}^{2} + {y}_{3}^{2} )} + {e}^{( {x}_{4}^{2} + {y}_{4}^{2} )}\end{matrix}}{\begin{matrix}{e}^{( {x}_{2}^{2} + {y}_{1}^{2} )} + {e}^{( {x}_{2}^{2} + {y}_{2}^{2} )} + {e}^{( {x}_{2}^{2} + {y}_{3}^{2} )} + {e}^{( {x}_{2}^{2} + {y}_{4}^{2} )} + \\ {e}^{( {x}_{3}^{2} + {y}_{1}^{2} )} + {e}^{( {x}_{3}^{2} + {y}_{2}^{2} )} + {e}^{( {x}_{3}^{2} + {y}_{3}^{2} )} + {e}^{( {x}_{3}^{2} + {y}_{4}^{2} )}\end{matrix}} \\ = \frac{( {e}^{{x}_{1}^{2}} + {e}^{{x}_{4}^{2}} ) {e}^{( {y}_{1}^{2} + {y}_{2}^{2} + {y}_{3}^{2} + {y}_{4}^{2} )}}{( {e}^{{x}_{2}^{2}} + {e}^{{x}_{3}^{2}} ) {e}^{( {y}_{1}^{2} + {y}_{2}^{2} + {y}_{3}^{2} + {y}_{4}^{2} )}} \\ = \frac{{e}^{{x}_{1}^{2}} + {e}^{{x}_{4}^{2}}}{{e}^{{x}_{2}^{2}} + {e}^{{x}_{3}^{2}}}\end{matrix} \qquad ( 114 )$$

With the independent I and Q if we want to compute the LLR of the least significant bit,

With the independent I and Q if we want to compute the LLR of the second-least significant bit,

$$\begin{matrix}\frac{{\sum }_{bit = 1}}{{\sum }_{bit = 0}} = \frac{( {e}^{{x}_{1}^{2}} + {e}^{{x}_{2}^{2}} ) {e}^{( {y}_{1}^{2} + {y}_{2}^{2} + {y}_{3}^{2} + {y}_{4}^{2} )}}{( {e}^{{x}_{3}^{2}} + {e}^{{x}_{4}^{2}} ) {e}^{( {y}_{1}^{2} + {y}_{2}^{2} + {y}_{3}^{2} + {y}_{4}^{2} )}} \\ = \frac{{e}^{{x}_{1}^{2}} + {e}^{{x}_{2}^{2}}}{{e}^{{x}_{3}^{2}} + {e}^{{x}_{4}^{2}}}\end{matrix} \qquad ( 115 )$$

$$\begin{matrix}\frac{{\sum }_{bit = 1}}{{\sum }_{bit = 0}} = \frac{( {e}^{{y}_{1}^{2}} + {e}^{{y}_{2}^{2}} ) {e}^{( {x}_{1}^{2} + {x}_{2}^{2} + {x}_{3}^{2} + {x}_{4}^{2} )}}{( {e}^{{y}_{2}^{2}} + {e}^{{y}_{3}^{2}} ) {e}^{( {x}_{1}^{2} + {x}_{2}^{2} + {x}_{3}^{2} + {x}_{4}^{2} )}} \\ = \frac{{e}^{{y}_{1}^{2}} + {e}^{{y}_{4}^{2}}}{{e}^{{y}_{2}^{2}} + {e}^{{y}_{3}^{2}}}\end{matrix} \qquad ( 116 )$$

With the independent I and Q if we want to compute the LLR of the most significant bit,

$$\begin{matrix}\frac{{\sum }_{bit = 1}}{{\sum }_{bit = 0}} = \frac{( {e}^{{y}_{1}^{2}} + {e}^{{y}_{2}^{2}} ) {e}^{( {x}_{1}^{2} + {x}_{2}^{2} + {x}_{3}^{2} + {x}_{4}^{2} )}}{( {e}^{{y}_{3}^{2}} + {e}^{{y}_{4}^{2}} ) {e}^{( {x}_{1}^{2} + {x}_{2}^{2} + {x}_{3}^{2} + {x}_{4}^{2} )}} \\ = \frac{{e}^{{y}_{1}^{2}} + {e}^{{y}_{2}^{2}}}{{e}^{{y}_{3}^{2}} + {e}^{{y}_{4}^{2}}}\end{matrix} \qquad ( 117 )$$

The same reduction of calculations occurs for all bits.

The number of exponentials to compute is the same, 8, the number of additions is 4*2=8, the number of multiplications is 0 and the number of divisions is 4. The total number of operations is 20.

When the constellation size increase the saving in computations also increase considerably.

For the case of 16 QAM, 64 QAM, 256 QAM and 16384 QAM the comparison is as follows:

| | #exp | #add | #mul | #div | TOTAL |
|---|---|---|---|---|---|
| 16 QAM | | | | | |
| Full | 8 | 4*14 | 16 | 4 | 84 |
| Independent I & Q | 8 | 4*2 | 0 | 4 | 20 |
| 64 QAM | | | | | |
| Full | 16 | 6*62 | 64 | 6 | 458 |
| Independent I & Q | 16 | 6*6 | 0 | 6 | 58 |
| 128 QAM | | | | | |
| Full | 32 | 7*126 | 121 | 7 | 1,042 |
| Independent I & Q | 32 | 7*14 + 2*14 | 14 | 14 | 186 |
| 256 QAM | | | | | |
| Full | 32 | 8*254 | 256 | 8 | 2,328 |
| Independent I & Q | 32 | 8*14 | 0 | 8 | 152 |
| 16384 QAM | | | | | |
| Full | 256 | 14*16382 | 16384 | 14 | 246,002 |
| Independent I & Q | 256 | 14*126 | 0 | 14 | 2,034 |

N odd

| | | | | | |
|---|---|---|---|---|---|
| N = 2ⁿ QAM | | | | | |
| Full | 2(2N)^{1/2} | n(N − 2) | N − n | n | 2(2N)^{1/2} + (n + 1)N − |
| | | | | | 2n |
| Independent I & Q | 2(2N)^{1/2} | 2n² + 4n | 2n | 2n | 2(2N)^{1/2} + 2n² + 8n |

N even

| | | | | | |
|---|---|---|---|---|---|
| N = 2ⁿ QAM | | | | | |
| Full | 2N^{1/2} | n(N − 2) | N | n | 2N^{1/2 + (n + 1)N - n} |
| Independent I & Q | 2N^{1/2} | n(N^{1/2} − 2) | 0 | n | (n + 2)N^{1/2} + n |

The increase complexity for this type of constellation can be shown to be of O((N)^{½}) where N is the number of constellation points. For the odd constellation the procedure defined in Provisional Patent Application Serial No. 60/248,099 has been used.

17. Use of Puncturing Patterns and Protection on Parity/Information Bits

In conventional Turbo Codes, when no comment about puncturing is made, it is understood that the puncturing pattern used selects one parity bit from the first encoder as one encoded bit and parity bit from the second encoder as the next encoded bit in an alternating fashion. Thus in the conventional Turbo Code using a four bit constellation, two parity bits are selected for every two information bits, and as such the number of parity bits represented in each symbol is equal to the number of information bits represented in the symbol.

In accordance with embodiments of the invention, for the constellations selected, one or two parity bits are sent in each dimension, providing, for this reason, the possibility to protect the parity bit(s) more than the information bit(s), or less than the information bit(s), because of the Gray mapping. The number of parity bits represented in each symbol is less than the number of information bits represented in the symbol.

In an AWGN channel, if the information bits are more protected, for BER higher than 10⁻⁷, the performance is 0.5 dB better. This means that for the same BER, the E_{b}/N_{O} in the case that the information bits are more protected, is 0.5 dB lower than the E_{b}/Nₒ if the parity bits are more protected. For BER below 10⁻⁷, this statement is reversed. For the same BER, the E_{b}/Nₒ, in the case that the information bits are more protected, is 0.5 dB higher that the E_{b}/Nₒ if the parity bits are more protected.

In an Impulse Noise environment, the greater protection of the parity bits provides more immunization against impulses (around 5 to 10 dB more). Once the impulse affects the more protected parity, they are more harmful than the case where the parity is less protected and the information is more protected.

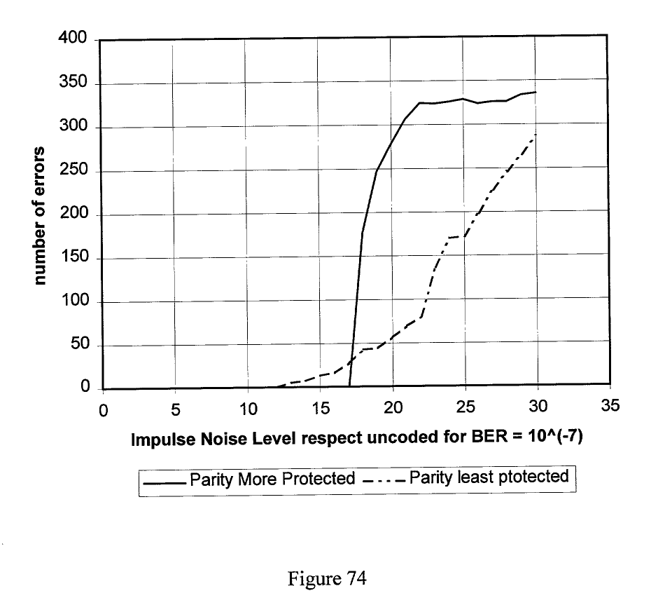

FIG. 74 shows the performance of the 6/4 rate 64 QAM for the case that the parity bits are most protected and for the case that the parity bits are least protected.

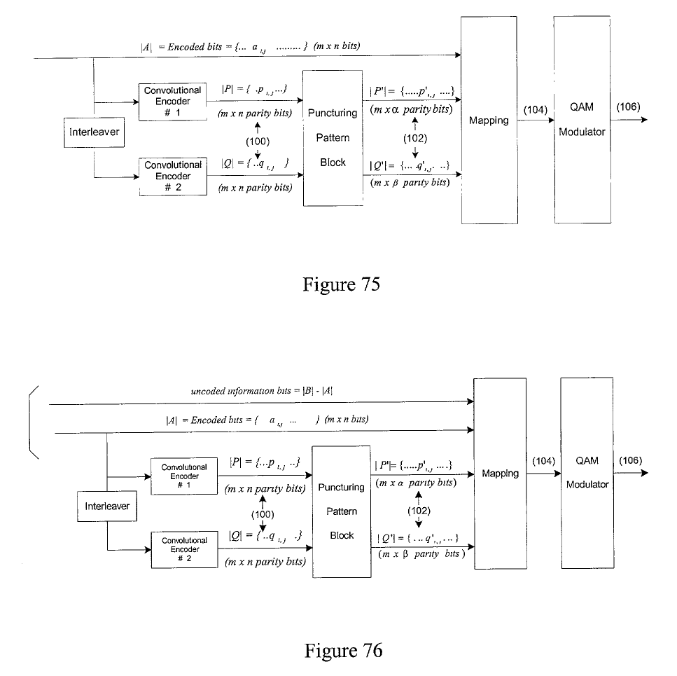

A detail explanation of the encoding and puncturing procedures is shown in FIG. 75, where matrix |A|, is the total set of bits that are encoded. The number of rows of this matrix is the number of input symbols to be transmitted, “m”. The number of rows of this matrix is the number of bits encoded in each symbol, “n”.

$$\vert A \vert = ( \begin{matrix}{a}_{1 , 1} & {a}_{1 , 2} & … & {a}_{1 , n} \\ ⋮ & ⋮ & ⋮ & ⋮ \\ {a}_{m , 1} & {a}_{m , 2} & … & {a}_{m , n}\end{matrix} ) ; {A}_{j} = \{ {a}_{j , 1} , {a}_{j , 2} , … , {a}_{j , n} \} \qquad ( 118 )$$

Each row of the matrix |A| is sent to the Turbo Encoder once every symbol time. For symbol j, the input to the turbo encoder is |Aⱼ|={a_{j,1}, a_{j,2}, . . . ,a_{j,n}}. For each symbol, the output of the first convolutional encoder will be |Pᵢ|=p_{i,1}, p_{i,2}, . . . , p_{i,n}, and the output of the second convolutional encoder will be |Qⱼ|=q_{j,1}, q_{j,2}, . . . ,p_{j,n}. Each encoded bit a_{j,i}, produces one parity bit in the first encoder p_{j,i}, and one parity bit in the second encoder, q_{j,i}. Essentially the encoder runs “n”times for each symbol.

$$\begin{matrix}\vert P \vert = ( \begin{matrix}{p}_{1 , 1} & {p}_{1 , 2} & … & {p}_{1 , n} \\ ⋮ & ⋮ & ⋮ & ⋮ \\ {p}_{m , 1} & {p}_{m , 2} & … & {p}_{m , n}\end{matrix} ) ; \\ {P}_{j} = \{ {p}_{j , 1} , {p}_{j , 2} , … , {p}_{j , n} \} & ( 119 ) \\ \vert Q \vert = ( \begin{matrix}{q}_{1 , 1} & {q}_{1 , 2} & … & {q}_{1 , n} \\ ⋮ & ⋮ & ⋮ & ⋮ \\ {q}_{m , 1} & {q}_{m , 2} & … & {q}_{m , n}\end{matrix} ) ; \\ {Q}_{j} = \{ {q}_{j , 1} , {q}_{j , 2} , … , {q}_{j , n} \} & ( 120 )\end{matrix}$$

The output of the first convolutional encoder and the output of the second convolutional encoders go to the puncturing pattern block, as shown in FIG. 75. This puncturing pattern block, selects the parity bits to be transmitted. The first output provides the parity bits to be transmitted from the first encoder |P'ⱼ|=P'_{j,1}P'_{j,2}, . . . , P'_{j,a}. The second output provides the parity bits to be transmitted from the second encoder |Q'ⱼ|=q'_{j,1}, q'_{j,2}, . . . ,q'_{j,β}.

$$\begin{matrix}\vert {P}^{′} \vert = ( \begin{matrix}{p}_{1 , 1}^{′} & {p}_{1 , 2}^{′} & … & {p}_{1 , α}^{′} \\ ⋮ & ⋮ & ⋮ & ⋮ \\ {p}_{m , 1}^{′} & {p}_{m , 2}^{′} & … & {p}_{m , α}^{′}\end{matrix} ) ; \\ {P}_{j}^{′} = \{ {p}_{j , 1}^{′} , {p}_{j , 2}^{′} , … , {p}_{j , α}^{′} \} & ( 121 ) \\ \vert {Q}^{′} \vert = ( \begin{matrix}{q}_{1 , 1}^{′} & {q}_{1 , 2}^{′} & … & {q}_{1 , β}^{′} \\ ⋮ & ⋮ & ⋮ & ⋮ \\ {q}_{m , 1}^{′} & {q}_{m , 2}^{′} & … & {q}_{m , β}^{′}\end{matrix} ) ; \\ {Q}_{j}^{′} = \{ {q}_{j , 1}^{′} , {q}_{j , 2}^{′} , … , {q}_{j , β}^{′} \} & ( 122 )\end{matrix}$$

In accordance with an embodiment of the invention, α+β<n. The total number of parity bits sent in each symbol is α+β. In traditional puncturing, α+β=n/2.

The implementation shown in FIG. 76 includes additional uncoded information bits, where matrix |B| is the total number of information bits. This is the general form for Multi-level Turbo Codes, where not all the information bits are coded. The number of rows of this matrix is the number of input symbols to be transmitted, “m”. The number of rows of this matrix is the number of bits in each symbol, “N”. Matrix |B| has a sub-matrix |A|, which represents the information bits to be encoded. The number of rows of this matrix is the number of input symbols to be transmitted, “m”. The number of rows of this matrix is the number of bits that are encoded in each symbol, “n”.

$$\begin{matrix}\vert B \vert = ( \begin{matrix}{b}_{1 , 1} & {b}_{1 , 2} & … & {b}_{1 , N} \\ ⋮ & ⋮ & ⋮ & ⋮ \\ {b}_{m , 1} & {b}_{m , 2} & … & {b}_{m , N}\end{matrix} ) \\ = ( \begin{matrix}{a}_{1 , 1} & {a}_{1 , 2} & … & {a}_{1 , n} & {b}_{1 , n + 1} … {b}_{1 , N} \\ ⋮ & ⋮ & ⋮ & ⋮ & … \\ {a}_{m , 1} & {a}_{m , 2} & … & {a}_{m , n} & {b}_{m , n + 1} … {b}_{m , N}\end{matrix} )\end{matrix} \qquad ( 123 )$$

18. Puncturing Rate Adaptation

Using the Channel State Information (values of gi and bi for each tone for the case of a G.992.1 or G.992.2 modem), the puncturing and mapping can be adapted to alter the transmitted signal bandwidth, which allows communication at a desired BER.

If there are too many errors (i.e., BER is too high), this can be improved by increasing the constellation size and reducing the puncturing, thereby sending more parity bits. The puncturing of the system is reduced, increasing the values of α and β. If the values of α and β are increased to twice their original values, the redundancy of the communications is also increased to twice its original value.

Alternatively, if there are too many errors (i.e., BER is too high), this can be improved by reducing the information data rate and reducing the puncturing, thereby sending more parity bits. The puncturing of the system is reduced, increasing the values of α and β. If the values of α and β are increased to twice their original values, the redundancy of the communications is also increased to twice its original value.

If the channel is working with a very low number of errors, it is possible to send information with fewer parity bits, by increasing the puncturing which reduces the values of α and β.

In the case that the bandwidth of the system is not a concern (i.e. spread spectrum systems or low data rate situations), reducing the puncturing increases the performance. For this case a and β should use their maximum value, “n”.

The monitoring of the error rate may be performed in the receiver using various techniques. Noise measurements based on the distance between each actual QAM signal point received and its nearest constellation points is a frequently used MSE (Mean-Squared Error)performance metric. Alternatively, the detection of errors in a bit-stream by a forward error-correction protocol, such as Reed Solomon or Turbo Decoder, may be used to determine performance metric. Higher-level protocol detection of errors, such as from an HDLC CRC checker, may also be used to determine a performance metric. Thus the actual error rate need not be measured. Rather, a performance metric may be derived in the receiver using any suitable technique and then characterized to determine when the receiver would benefit from a change in the puncturing pattern. Once the receiver decides to select a different operating puncturing pattern, it communicates this selection to the transmitter using a renegotiation process.

Taking into account these possibilities, it is clear that the system may adapt to different scenarios modifying the puncturing pattern using a “puncturing pattern adaptation” based on the condition of the channel, increasing or reducing the values of α and β. The operation of the channel can be controlled using a α-mask and β-mask. The α-mask and β-mask are “n” bits long; each position can take a “0” value or a “1” value.

The “0” value in the position “i” in the α-mask means that the puncturing pattern will not include the parity bit “p_{j,i}“from the first encoder. The “1” value in the position “i” in the α-mask means that the puncturing pattern will include the parity bit “pⱼ“from the first encoder. The “0” value in the position “i” in the β-mask means that the puncturing pattern will not include the parity bit “q_{j,i}“from the second encoder. The “1” value in the position “i” in the β-mask means that the puncturing pattern will include the parity bit “q_{j,i}“from the second encoder. Equations (124) and (125) shows the values of these masks.

αⱼmask={α_{j,1}, α_{j,2}, . . . , α_{j,n}}α_{j,i}=0,1 i=1 . . . n (124)

βⱼmask={β_{j,1}, β_{j,2}, . . . , β_{j,n}}β_{j,i}=0,1 i=1 . . . n (124)

As seen in the puncturing patterns disclosed in Tables 7-22, the α-mask and β-mask of a puncturing pattern typically utilize the same repetitive bit selection pattern, with the pattern in the β-mask being shifted by one or more bits with respect to the pattern in the α-mask. The patterns of the α-mask and β-mask are typically non-coincidental, in that the two patterns do not select a parity bit at the same time.

19. Summarv of operation of transmitters and receivers in preferred embodiments of the invention

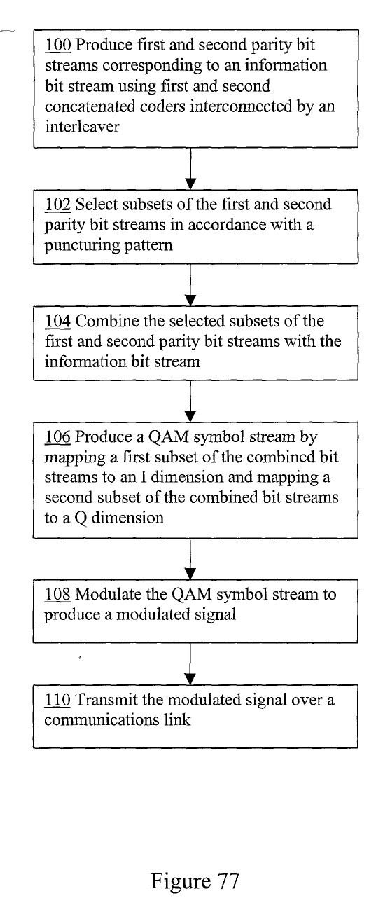

FIG. 77 illustrates a basic process in a transmitter in accordance with an embodiment of the invention. The process produces a modulated signal with forward error correction from an information bit stream in a QAM transmitter. The transmitter produces 100 parity bit streams that correspond to an inputted information bit stream using first and second concatenated coders interconnected by an interleaver. The transmitter selects 102 subsets of the first and second parity bit streams in accordance with a puncturing pattern. The transmitter combines 104 the selected subsets of said first and second parity bit streams with said information bit stream. A QAM symbol stream is produced 106 by mapping a first subset of the combined bit streams to an I dimension and mapping a second subset of the combined bit streams to a Q dimension. The QAM symbol stream is modulated 108 to produce a modulated signal, and the modulated signal is transmitted 110 over a communication link.

As described above, any puncturing pattern may be implemented in accordance with the above process. However, it is preferred to implement one of the novel puncturing patterns disclosed herein. As described above, the novel puncturing patterns disclosed herein are characterized in that, for an c-bit constellation, wherein each symbol represents n information bits and c-n parity bits (also α+β parity bits using the terminology of Section 17 above), the number of parity bits c-n selected by the puncturing pattern is less than n. In other words, the number of parity bits represented in each symbol is less than the number of information bits represented in that symbol. Examples of such puncturing patterns are provided in Tables 7 and 9-22, and those of ordinary skill will recognize a variety of other patterns that may be implemented in accordance with the parameters described herein.

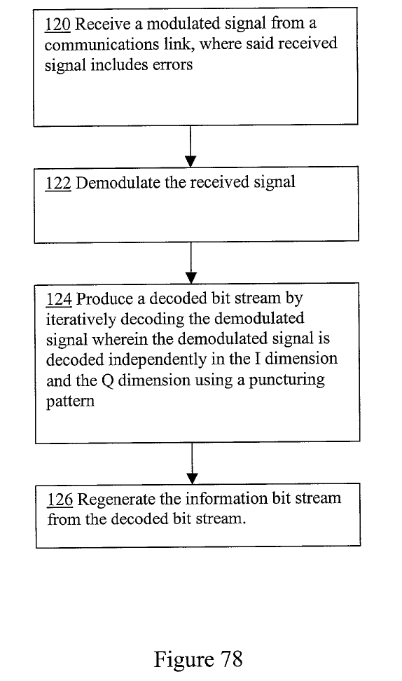

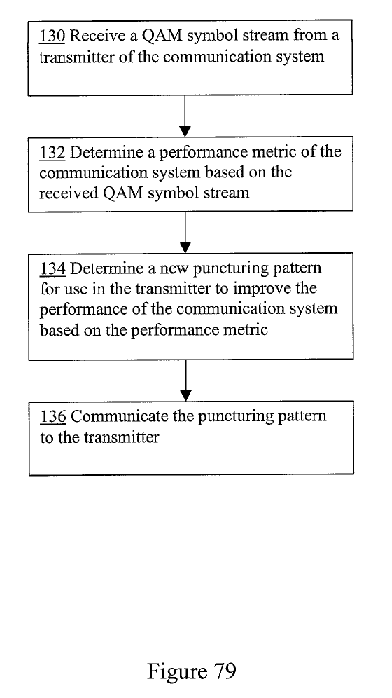

FIG. 78 illustrates a basic process in a receiver that is complementary to a transmitter as described above. The process recovers an information bit stream from a noisy modulated signal with forward error correction in a QAM receiver. The receiver receives 120 a modulated signal from a communications link. The signal includes errors. The received signal is demodulated 122, and a decoded bit stream is produced 124 by iteratively decoding the demodulated signal using first and second concatenated coders connected by an interleaver. The demodulated signal is decoded independently in the I dimension and the Q dimension using a puncturing pattern. The puncturing pattern corresponds to a puncturing pattern implemented in the transmitter that produces the modulated signal. The receiver regenerates 126 the information bit stream from the decoded bit stream.

As noted above, embodiments in accordance with the invention may adapt the puncturing pattern used in the transmitter in accordance with conditions in the communication system. FIG. 79 illustrates a basic process in a receiver for adapting to conditions in the communication system. The receiver receives 130 a QAM symbol stream from a transmitter of the communication system. The receiver determines 132 a performance metric of the communication system based on the received QAM symbol stream. The performance metric may be determined based on detection of errors in the QAM symbol stream in accordance with the error detection techniques discussed above or any other conventional error detection technique. If the performance metric is unsatisfactory, the receiver selects 134 a new puncturing pattern for use in the transmitter to improve the performance of the communication system. The puncturing pattern is selected based on the performance metric. The puncturing pattern is then communicated 136 to the transmitter. This may be accomplished by communicating the actual pattern to the transmitter, or by transmitting an identifier of a predefined puncturing pattern.

While the foregoing disclosure addressed a variety of preferred embodiments of the invention, those having ordinary skill in the art will recognize a variety of further embodiments that may be implemented in accordance with the novel principles disclosed herein.

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

1. A method of producing a modulated signal with forward error correction from an information bit stream in a QAM transmitter comprising:
producing first and second parity bit streams corresponding to an information bit stream using first and second concatenated coders interconnected by an interleaver;
selecting respective subsets of said first and second parity bit streams in accordance with a puncturing pattern;
combining the selected subsets of said first and second parity bit streams with said information bit stream;
producing a QAM symbol stream by mapping a first subset of the combined bit streams to an I dimension and mapping a second subset of the combined bit streams to a Q dimension;
modulating said QAM symbol stream to produce a modulated signal; and, transmitting said modulated signal over a communications link.

2. The method recited in claim 1, wherein said puncturing pattern selects respective subsets of parity bits from said first and second parity bit stream such that the number of parity bits represented in each QAM symbol of said QAM symbol stream is less than the number of information bits represented by said each symbol.

3. The method recited in claim 1, wherein each of said mapping to an I dimension and said mapping to a Q dimension comprises:
placing one or more parity bits in least significant positions of said dimension; and, placing information bits in more significant positions of said dimension.

4. The method recited in claim 1, wherein each of said mapping to an I dimension and said mapping to a Q dimension comprises:
placing an information bit in a least significant position of said dimension;
placing one or more parity bits in a more significant position of said dimension; and,
placing additional information bits in remaining positions of said dimension.

5. The method recited in claim 1, where each of said mapping to an I dimension and said mapping to a Q dimension comprises:
placing one or more parity bits in a most significant position of said dimension; and,
placing additional information bits in less significant positions of said dimension.

6. A method of producing a recovered information bit stream from a noisy modulated signal with forward error correction in a QAM receiver comprising:
receiving a modulated signal representing a QAM symbol stream from a communications link, where said received signal includes errors;
demodulating said received signal;
producing a decoded bit stream by iteratively decoding said demodulated signal wherein said demodulated signal is decoded independently in the I dimension and the Q dimension using a puncturing pattern; and,
regenerating said information bit stream from said decoded bit stream.

7. The method recited in claim 6, wherein said puncturing pattern selects respective subsets of parity bits from first and second parity bit streams such that the number of parity bits represented in each QAM symbol of said QAM symbol stream is less than the number of information bits represented by said each symbol.

8. A method in a QAM receiver for adapting to performance conditions in a communication system, comprising:
receiving a QAM symbol stream from a transmitter;
determining a performance metric of the communication system;
determining, based on the performance metric, a puncturing pattern for use in the transmitter to improve performance of the communication system; and
communicating the puncturing pattern to the transmitter.

9. The method recited in claim 8, wherein said puncturing pattern selects respective subsets of parity bits from first and second parity bit streams such that the number of parity bits represented in each QAM symbol of said QAM symbol stream is less than the number of information bits represented by said each symbol.
